(19) United States
(12) Patent Application Publication
(10) Pub. No.: US 2025/0157854 A1
(43) Pub. Date: May 15, 2025

(54) SEMICONDUCTOR DEVICE AND MANUFACTURING METHOD THEREFOR

(71) Applicant: 3PEAK INC., Suzhou (CN)

(72) Inventors: Yong Wang, Suzhou (CN); Jiangang Wu, Suzhou (CN)

(21) Appl. No.: 18/833,435

(22) PCT Filed: Jan. 29, 2023
(86) PCT No.: PCT/CN2023/073684

§ 371 Date: Jul. 26, 2024

(30) Foreign Application Priority Data
Jan. 28, 2022 (CN) 202210107483.X

(51) Int. Cl. H01L 21/762; H01L 21/225; H01L 21/265; H01L 21/308

(52) U.S. Cl. CPC H01L 21/76283; H01L 21/225; H01L 21/265; H01L 21/308; H01L 21/76229

(57) ABSTRACT

A semiconductor device and a fabricating method. The semiconductor device has a first trench and a second trench, both extending into a substrate; a third trench, extending into a buried layer or to a position in an epitaxial layer and near the buried layer; a first deep trench structure, disposed in a first trench to electrically connect the substrate to a top surface of the epitaxial layer; a second deep trench isolation structure, disposed in a second trench to isolate different component regions in the epitaxial layer; a third deep trench isolation structure, disposed in a third trench to isolate different component regions in the epitaxial layer; and a first doped region, formed in the epitaxial layer and near a sidewall of the third trench for electrically connecting the buried layer to the top surface of the epitaxial layer. The semiconductor device has good electrical and isolation performance.

### CROSS-REFERENCE TO RELATED APPLICATIONS

This application claims priority to Chinese Patent Application No. 202210107483.X, filed with the China National Intellectual Property Administration on Jan. 28, 2022, and entitled “SEMICONDUCTOR DEVICE AND FABRICATING METHOD THEREFOR”, which is incorporated herein by reference in its entirety.

### TECHNICAL FIELD

Embodiments of the present disclosure relate to a semiconductor device and a fabricating method therefor.

### BACKGROUND

The bipolar CMOS DMOS (BCD) technology can integrate an analog component, a digital component, and a high voltage (HV) component into a single chip or integrated circuit (IC) to form an embedded device. Such chip or IC is widely used in automotive and industrial applications. However, as an interference may easily occur between different components, it is difficult to integrate these components of different types into a single die or chip. For example, a latch-up problem may exist in a high voltage component. This may adversely affect the reliability of the entire product during integration. Therefore, components of different types need to be properly isolated from each other during integration. However, for conventional junction isolation technologies for isolating components of different types, a large layout area is consumed and an additional masking step is required, which may complicate the manufacturing processes and increase the manufacturing cost. In addition, the HV component that is integrated with analog and digital components and that is isolated using conventional isolation solutions may not have a high breakdown voltage (BV).

Therefore, it is expected to provide a reliable, high-performance, simple, and cost-effective solution to integrate various suitable isolation structures.

### SUMMARY

An objective of the present disclosure is to provide a semiconductor device and a fabricating method therefor, so as to at least partially resolve the foregoing problems in conventional technologies. For example, various suitable isolation structures are integrated using a reliable, high-performance, simple, and cost-effective solution to effectively isolate HV components from other components in the same IC.

According to a first aspect of the present disclosure, there is provided a method for fabricating a semiconductor device, comprising: Providing a semiconductor body, wherein the semiconductor body comprises a substrate, a buried layer disposed on the substrate, and an epitaxial layer disposed on the buried layer, the substrate has a first doping type, and the buried layer has a second doping type opposite to the first doping type; forming a hard mask layer on a top surface of the epitaxial layer; etching the hard mask layer and the semiconductor body by using a single soft mask layer to simultaneously form a first trench, a second trench, and a third trench in the semiconductor body, wherein the first trench extends from the top surface of the epitaxial layer into the substrate and has a first depth, the second trench extends from the top surface of the epitaxial layer into the substrate and has a second depth, and the third trench extends from the top surface of the epitaxial layer into the buried layer or to a position in the epitaxial layer and near the buried layer and has a third depth less than the second depth; forming, in the epitaxial layer, a first doped region having the second doping type near a sidewall of the third trench, wherein the first doped region extends from the top surface of the epitaxial layer to the buried layer, and is configured to electrically connect the buried layer to the top surface of the epitaxial layer; forming a first deep trench structure in the first trench, wherein the first deep trench structure is configured to electrically connect the substrate to the top surface of the epitaxial layer; forming a second deep trench isolation structure in the second trench, wherein the second deep trench isolation structure is configured to isolate different component regions in the epitaxial layer; and forming a third deep trench isolation structure in the third trench, wherein the third deep trench isolation structure is configured to isolate different component regions in the epitaxial layer.

In some embodiments, forming the hard mask layer comprises: growing a first oxide layer on the top surface of the epitaxial layer; depositing a nitride layer on the first oxide layer; and depositing a second oxide layer on the nitride layer.

In some embodiments, etching the hard mask layer and the semiconductor body by using the single soft mask layer comprises: performing first etching on the hard mask layer by using the single soft mask layer to simultaneously form, in the hard mask layer, a first trench opening, a second trench opening, and a third trench opening that penetrate through the hard mask layer; stripping the single soft mask layer; and performing second etching on the semiconductor body by using the hard mask layer to form, in the semiconductor body, the first trench aligned with the first trench opening, the second trench aligned with the second trench opening, and the third trench aligned with the third trench opening.

In some embodiments, etching the hard mask layer and the semiconductor body by using the single soft mask layer comprises:

performing first etching on the hard mask layer and the epitaxial layer by using the single soft mask layer to simultaneously form, in the hard mask layer, a first trench opening, a second trench opening, and a third trench opening that penetrate through the hard mask layer, and to form, in the epitaxial layer, a first shallow trench aligned with each of the first trench opening, the second trench opening, and the third trench opening; forming a sidewall spacer on a sidewall of each of the first trench opening, the second trench opening, the third trench opening, and the first shallow trench; and performing second etching on the semiconductor body via the first shallow trench to form, in the semiconductor body, the first trench aligned with the first trench opening, the second trench aligned with the second trench opening, and the third trench aligned with the third trench opening.

In some embodiments, the method further comprises removing the sidewall spacer through isotropic etching after the first doped region is formed.

In some embodiments, the sidewall spacer comprises nitride.

In some embodiments, etching the hard mask layer and the semiconductor body by using the single soft mask layer comprises:

performing single etching on the hard mask layer and the semiconductor body by using the single soft mask layer to simultaneously form, in the hard mask layer, a first trench opening, a second trench opening, and a third trench opening that penetrate through the hard mask layer, and to simultaneously form, in the semiconductor body, the first trench aligned with the first trench opening, the second trench aligned with the second trench opening, and the third trench aligned with the third trench opening.

In some embodiments, forming the first deep trench structure in the first trench comprises: forming a pad on a sidewall and a bottom of the first trench; forming a dielectric layer inside the pad in the first trench, wherein the dielectric layer comprises a second opening extending from the top surface of the epitaxial layer toward the bottom of the first trench; performing anisotropic etching on the dielectric layer and the pad in the first trench, so that the second opening extends to the pad at the bottom of the first trench, and a first opening aligned with the second opening is formed in the pad at the bottom of the first trench; and filling the first opening and the second opening with a first conductive material, wherein the first conductive material is configured to electrically connect the substrate to the top surface of the epitaxial layer.

In some embodiments, the first conductive material comprises polysilicon having the first doping type.

In some embodiments, the method further comprises forming a second doped region in the substrate near the bottom of the first trench, wherein the second doped region has the first doping type and has a doping concentration higher than that of the substrate.

In some embodiments, forming the second deep trench isolation structure in the second trench comprises: forming a pad on a sidewall and a bottom of the second trench; and forming a dielectric layer inside the pad in the second trench, wherein the dielectric layer completely or partially fills the second trench.

In some embodiments, forming the third deep trench isolation structure in the third trench comprises: forming a pad on a sidewall and a bottom of the third trench; and forming a dielectric layer inside the pad in the third trench, wherein the dielectric layer completely fills the third trench.

In some embodiments, forming, in the epitaxial layer, the first doped region having the second doping type near the sidewall of the third trench comprises: depositing a diffusion material in the third trench, wherein the diffusion material comprises a dopant of the second doping type; and performing thermal annealing on the diffusion material, so that the dopant is diffused into a region of the epitaxial layer near the sidewall of the third trench to form the first doped region.

In some embodiments, the diffusion material partially fills the third trench, and forming the third deep trench isolation structure in the third trench comprises: continuing to fill the third trench with a dielectric material to seal the diffusion material, wherein the diffusion material and the dielectric material jointly form the third deep trench isolation structure.

In some embodiments, when the first doping type is a p-type, the diffusion material comprises at least one of POCl3 glass and phosphate silicate glass, and the dopant is a phosphorus element; and when the first doping type is an n-type, the diffusion material comprises borosilicate glass, and the dopant is a boron element.

In some embodiments, the first doped region is formed near both sides of the third trench.

In some embodiments, the diffusion material completely or partially fills the third trench.

In some embodiments, an air gap is formed inside the diffusion material.

In some embodiments, the method further comprises etching the diffusion material in the third trench to remove the diffusion material.

In some embodiments, the second depth is less than the first depth, and the formation of the first deep trench structure, the second deep trench isolation structure, and the third deep trench isolation structure comprises: forming a pad on a sidewall and a bottom of each of the first trench, the second trench, and the third trench; and forming a dielectric layer inside the pad in the first trench, the second trench, and the third trench, so that the dielectric layer forms, in the first trench, a second opening that extends from the top surface of the epitaxial layer toward the bottom of the first trench, and the dielectric layer completely fills the second trench and the third trench, wherein the pad and the dielectric layer in the second trench form the second deep trench isolation structure, and the pad and the dielectric layer in the third trench form the third deep trench isolation structure.

In some embodiments, the formation of the first deep trench structure further comprises: performing anisotropic etching on the dielectric layer and the pad, so that the second opening extends to the pad at the bottom of the first trench, and a first opening aligned with the second opening is formed in the pad at the bottom of the first trench; performing ion implantation on the substrate through the second opening and the first opening to form a second doped region in the substrate near the bottom of the first trench, wherein the second doped region has the first doping type and has a doping concentration higher than that of the substrate; and filling the first opening and the second opening with a first conductive material to form the first deep trench structure.

In some embodiments, the method further comprises: forming a third doped region near a bottom of the second trench, wherein the third doped region has the first doping type and has a doping concentration higher than that of the substrate.

In some embodiments, forming, in the epitaxial layer, the first doped region having the second doping type near the sidewall of the third trench comprises: forming the first doped region by implanting, at an oblique angle, a dopant of the second doping type through the sidewall of the third trench.

In some embodiments, the method further comprises forming a shallow trench isolation region in the epitaxial layer.

In some embodiments, the method further comprises forming at least one transistor in the epitaxial layer.

According to a second aspect of the present disclosure, there is provided a method for fabricating a semiconductor device, comprising: providing a semiconductor body, wherein the semiconductor body comprises a substrate, a buried layer disposed on the substrate, and an epitaxial layer disposed on the buried layer, the substrate has a first doping type, and the buried layer has a second doping type opposite to the first doping type; forming a hard mask layer on a top surface of the epitaxial layer; performing first etching on the hard mask layer by using a first soft mask layer to simultaneously form, in the hard mask layer, a first trench opening, a second trench opening, and a third trench opening that penetrate through the hard mask layer; stripping the first soft mask layer; forming a second soft mask layer on the hard mask layer, wherein the second soft mask layer comprises a third opening and the third opening exposes one or more portions of the hard mask layer near the third trench opening; implanting a dopant of the second doping type into the epitaxial layer via the third opening; stripping the second soft mask layer; performing second etching on the semiconductor body by using the hard mask layer to form, in the semiconductor body, a first trench aligned with the first trench opening, a second trench aligned with the second trench opening, and a third trench aligned with the third trench opening; performing thermal annealing on the dopant to form a first doped region in a region of the epitaxial layer near a sidewall of the third trench, wherein the first doped region extends from the top surface of the epitaxial layer to the buried layer, and is configured to electrically connect the buried layer to the top surface of the epitaxial layer; forming a first deep trench structure in the first trench, wherein the first deep trench structure is configured to electrically connect the substrate to the top surface of the epitaxial layer; forming a second deep trench isolation structure in the second trench, wherein the second deep trench isolation structure is configured to isolate different component regions in the epitaxial layer; and forming a third deep trench isolation structure in the third trench, wherein the third deep trench isolation structure is configured to isolate different component regions in the epitaxial layer.

According to a third aspect of the present disclosure, there is provided a semiconductor device, comprising: a semiconductor body, wherein the semiconductor body comprises a substrate, a buried layer disposed on the substrate, and an epitaxial layer disposed on the buried layer, the substrate has a first doping type, and the buried layer has a second doping type opposite to the first doping type; a first trench, extending from a top surface of the epitaxial layer into the substrate and having a first depth; a second trench, extending from the top surface of the epitaxial layer into the substrate and having a second depth; a third trench, extending from the top surface of the epitaxial layer into the buried layer and having a third depth less than the second depth; a first deep trench structure, disposed in the first trench and configured to electrically connect the substrate to the top surface of the epitaxial layer; a second deep trench isolation structure, disposed in the second trench and configured to isolate different component regions in the epitaxial layer; a third deep trench isolation structure, disposed in the third trench and configured to isolate different component regions in the epitaxial layer; and a first doped region, formed in the epitaxial layer near a sidewall of the third trench and having the second doping type, wherein the first doped region extends from the top surface of the epitaxial layer to the buried layer, and is configured to electrically connect the buried layer to the top surface of the epitaxial layer.

In some embodiments, the second depth is less than the first depth.

In some embodiments, the first deep trench structure comprises: a pad, formed on a sidewall and at least a portion of a bottom of the first trench, and comprising a first opening formed at the bottom of the first trench; a dielectric layer, disposed inside the pad in the first trench, and comprising a second opening extending from the top surface of the epitaxial layer to the pad at the bottom of the first trench, wherein the second opening is aligned with the first opening; and a first conductive material, filling the first opening and the second opening, and configured to electrically connect the substrate to the top surface of the epitaxial layer.

In some embodiments, the first conductive material comprises polysilicon having the first doping type.

In some embodiments, the second deep trench isolation structure comprises: a pad, disposed on a sidewall and a bottom of the second trench; and a dielectric layer, disposed inside the pad in the second trench.

In some embodiments, the third deep trench isolation structure comprises: a pad, disposed on a sidewall and a bottom of the third trench; and a dielectric layer, disposed inside the pad in the third trench.

In some embodiments, the third deep trench isolation structure comprises: a diffusion material, partially filling the third trench; and a dielectric material, sealing the diffusion material in the third trench, wherein the diffusion material and the dielectric material jointly form the third deep trench isolation structure.

In some embodiments, the third deep trench isolation structure comprises oxide or undoped polysilicon.

In some embodiments, the first doped region is disposed near both sides of the third trench or only near one side of the third trench.

In some embodiments, the first doped region is formed between the second trench and the third trench.

In some embodiments, the semiconductor device further comprises a second doped region, wherein the second doped region is formed in the substrate near a bottom of the first trench, and the second doped region has the first doping type and has a doping concentration higher than that of the substrate.

In some embodiments, the semiconductor device further comprises a third doped region, wherein the third doped region is formed in the substrate near a bottom of the second trench, and the third doped region has the first doping type and has a doping concentration higher than that of the substrate.

In some embodiments, the semiconductor device further comprises a shallow trench isolation region, formed in the epitaxial layer.

In some embodiments, the semiconductor device further comprises at least one transistor, formed in the epitaxial layer.

According to a fourth aspect of the present disclosure, there is provided a method for fabricating a semiconductor device, comprising: providing a semiconductor body, wherein the semiconductor body comprises a substrate, a buried layer disposed on the substrate, and an epitaxial layer disposed on the buried layer, the substrate has a first doping type, and the buried layer has a second doping type opposite to the first doping type; forming a hard mask layer on a top surface of the epitaxial layer; etching the hard mask layer and the semiconductor body by using a third soft mask layer to form, in the hard mask layer, a third trench opening that penetrates through the hard mask layer and to form, in the semiconductor body, a third trench aligned with the third trench opening, wherein the third trench extends from the top surface of the epitaxial layer into the buried layer or to a position in the epitaxial layer and near the buried layer and has a third depth; stripping the third soft mask layer; filling the third trench opening and the third trench with a second conductive material; etching the hard mask layer and the semiconductor body by using a fourth soft mask layer to form, in the hard mask layer, a first trench opening and a second trench opening that penetrate through the hard mask layer, and to form, in the semiconductor body, a first trench aligned with the first trench opening and a second trench aligned with the second trench opening, wherein the second trench extends from the top surface of the epitaxial layer into the substrate and has a second depth greater than the third depth, and the first trench extends from the top surface of the epitaxial layer into the substrate and has a first depth; forming a first deep trench structure in the first trench, wherein the first deep trench structure is configured to electrically connect the substrate to the top surface of the epitaxial layer; and forming a second deep trench isolation structure in the second trench, wherein the second deep trench isolation structure is configured to isolate different component regions in the epitaxial layer.

According to a fifth aspect of the present disclosure, there is provided a method for fabricating a semiconductor device, comprising: providing a semiconductor body, wherein the semiconductor body comprises a substrate, a buried layer disposed on the substrate, and an epitaxial layer disposed on the buried layer, the substrate has a first doping type, and the buried layer has a second doping type opposite to the first doping type; forming a hard mask layer on a top surface of the epitaxial layer; etching the hard mask layer and the semiconductor body by using a fifth soft mask layer to form, in the hard mask layer, a first trench opening and a second trench opening that penetrate through the hard mask layer, and to form, in the semiconductor body, a first trench aligned with the first trench opening and a second trench aligned with the second trench opening, wherein the first trench extends from the top surface of the epitaxial layer into the substrate and has a first depth, and the second trench extends from the top surface of the epitaxial layer into the substrate and has a second depth; stripping the fifth soft mask layer; forming a first deep trench structure in the first trench, wherein the first deep trench structure is configured to electrically connect the substrate to the top surface of the epitaxial layer; forming a second deep trench isolation structure in the second trench, wherein the second deep trench isolation structure is configured to isolate different component regions in the epitaxial layer; stripping the hard mask layer; etching the semiconductor body by using a sixth soft mask layer to form a third trench in the semiconductor body, wherein the third trench extends from the top surface of the epitaxial layer into the buried layer or to a position in the epitaxial layer and near the buried layer and has a third depth less than the second depth; and filling the third trench with a second conductive material, wherein the second conductive material is configured to electrically connect the buried layer to the top surface of the epitaxial layer.

According to a sixth aspect of the present disclosure, there is provided a method for fabricating a semiconductor device, comprising: providing a semiconductor body, wherein the semiconductor body comprises a substrate, a buried layer disposed on the substrate, and an epitaxial layer disposed on the buried layer, the substrate has a first doping type, and the buried layer has a second doping type opposite to the first doping type; forming a hard mask layer on a top surface of the epitaxial layer; etching the hard mask layer and the semiconductor body by using a seventh soft mask layer to simultaneously form a first trench, a second trench, and a third trench in the semiconductor body, wherein the first trench extends from the top surface of the epitaxial layer into the substrate and has a first depth, the second trench extends from the top surface of the epitaxial layer into the substrate and has a second depth, and the third trench extends from the top surface of the epitaxial layer into the buried layer or to a position in the epitaxial layer and near the buried layer and has a third depth less than the second depth; forming a first deep trench structure in the first trench, wherein the first deep trench structure is configured to electrically connect the substrate to the top surface of the epitaxial layer;

forming a second deep trench isolation structure in the second trench, wherein the second deep trench isolation structure is configured to isolate different component regions in the epitaxial layer; forming a temporary deep trench structure in the third trench; etching the temporary deep trench structure in the third trench by using an eighth soft mask layer to remove the temporary deep trench structure in the third trench; and filling the third trench with a second conductive material, wherein the second conductive material is configured to electrically connect the buried layer to the top surface of the epitaxial layer.

According to a seventh aspect of the present disclosure, there is provided a method for fabricating a semiconductor device, comprising: providing a semiconductor body, wherein the semiconductor body comprises a substrate, a buried layer disposed on the substrate, and an epitaxial layer disposed on the buried layer, the substrate has a first doping type, and the buried layer has a second doping type opposite to the first doping type; forming a hard mask layer on a top surface of the epitaxial layer; etching the hard mask layer and the semiconductor body by using a seventh soft mask layer to simultaneously form a first trench, a second trench, and a third trench in the semiconductor body, wherein the first trench extends from the top surface of the epitaxial layer into the substrate and has a first depth, the second trench extends from the top surface of the epitaxial layer into the substrate and has a second depth, and the third trench extends from the top surface of the epitaxial layer into the buried layer or to a position in the epitaxial layer and near the buried layer and has a third depth less than the second depth; forming a first deep trench structure in the first trench, wherein the first deep trench structure is configured to electrically connect the substrate to the top surface of the epitaxial layer;

forming a second deep trench isolation structure in the second trench, wherein the second deep trench isolation structure is configured to isolate different component regions in the epitaxial layer; forming a temporary deep trench structure in the third trench; etching the temporary deep trench structure in the third trench by using an eighth soft mask layer to remove the temporary deep trench structure in the third trench; obliquely implanting, in the third trench, a dopant of the second doping type into the semiconductor body to form, in the epitaxial layer, a first doped region having the second doping type near a sidewall of the third trench; and filling the third trench with a dielectric material to form a third deep trench isolation structure.

According to an eighth aspect of the present disclosure, there is provided a semiconductor device, comprising: a semiconductor body, wherein the semiconductor body comprises a substrate, a buried layer disposed on the substrate, and an epitaxial layer disposed on the buried layer, the substrate has a first doping type, and the buried layer has a second doping type opposite to the first doping type; a first trench, extending from a top surface of the epitaxial layer into the substrate and having a first depth; a second trench, extending from the top surface of the epitaxial layer into the substrate and having a second depth; a third trench, extending from the top surface of the epitaxial layer into the buried layer and having a third depth less than the second depth; a first deep trench structure, disposed in the first trench and configured to electrically connect the substrate to the top surface of the epitaxial layer; a second deep trench isolation structure, disposed in the second trench and configured to isolate different component regions in the epitaxial layer; and a second conductive material, filling the third trench, and configured to electrically connect the buried layer to the top surface of the epitaxial layer.

In some embodiments, the second depth is less than the first depth.

In some embodiments, the first deep trench structure comprises: a pad, formed on a sidewall and at least a portion of a bottom of the first trench, and comprising a first opening formed at the bottom of the first trench; a dielectric layer, disposed inside the pad in the first trench, and comprising a second opening extending from the top surface of the epitaxial layer to the pad at the bottom of the first trench, wherein the second opening is aligned with the first opening; and a first conductive material, filling the first opening and the second opening, and configured to electrically connect the substrate to the top surface of the epitaxial layer.

In some embodiments, the first conductive material comprises polysilicon having the first doping type.

In some embodiments, the second deep trench isolation structure comprises: a pad, disposed on a sidewall and a bottom of the second trench; and a dielectric layer, disposed inside the pad in the second trench.

In some embodiments, the second conductive material comprises polysilicon having the second doping type.

In some embodiments, the semiconductor device further comprises: a first doped region, formed in the epitaxial layer near a sidewall of the third trench and having the second doping type, wherein the first doped region extends from the top surface of the epitaxial layer to the buried layer, and is configured to electrically connect the buried layer to the top surface of the epitaxial layer together with the second conductive material.

In some embodiments, the semiconductor device further comprises a second doped region, wherein the second doped region is formed in the substrate near a bottom of the first trench, and the second doped region has the first doping type and has a doping concentration higher than that of the substrate.

In some embodiments, the semiconductor device further comprises a shallow trench isolation region, formed in the epitaxial layer.

In some embodiments, the semiconductor device further comprises at least one transistor, formed in the epitaxial layer.

In some embodiments, the semiconductor device further comprises a third doped region, wherein the third doped region is formed in the substrate near a bottom of the second trench, and the third doped region has the first doping type and has a doping concentration higher than that of the substrate.

According to a ninth aspect of the present disclosure, there is provided a method for fabricating a semiconductor device, comprising: providing a semiconductor body, wherein the semiconductor body comprises a substrate, a buried layer disposed on the substrate, and an epitaxial layer disposed on the buried layer, the substrate has a first doping type, and the buried layer has a second doping type opposite to the first doping type; forming a hard mask layer on a top surface of the epitaxial layer; etching the hard mask layer and the semiconductor body by using a single soft mask layer to simultaneously form a first trench and a third trench in the semiconductor body, wherein the first trench extends from the top surface of the epitaxial layer into the substrate and has a first depth, the third trench extends from the top surface of the epitaxial layer into the buried layer or to a position in the epitaxial layer and near the buried layer and has a third depth less than the first depth; forming, in the epitaxial layer, a first doped region having the second doping type near a sidewall of the third trench, wherein the first doped region extends from the top surface of the epitaxial layer to the buried layer, and is configured to electrically connect the buried layer to the top surface of the epitaxial layer; forming a first deep trench structure in the first trench, wherein the first deep trench structure is configured to electrically connect the substrate to the top surface of the epitaxial layer; and forming a third deep trench isolation structure in the third trench, wherein the third deep trench isolation structure is configured to isolate different component regions in the epitaxial layer.

According to a tenth aspect of the present disclosure, there is provided a method for fabricating a semiconductor device, comprising: providing a semiconductor body, wherein the semiconductor body comprises a substrate, a buried layer disposed on the substrate, and an epitaxial layer disposed on the buried layer, the substrate has a first doping type, and the buried layer has a second doping type opposite to the first doping type; forming a hard mask layer on a top surface of the epitaxial layer; performing first etching on the hard mask layer by using a first soft mask layer to simultaneously form, in the hard mask layer, a first trench opening and a third trench opening that penetrate through the hard mask layer; stripping the first soft mask layer; forming a second soft mask layer on the hard mask layer, wherein the second soft mask layer comprises a third opening and the third opening exposes one or more portions of the hard mask layer near the third trench opening; implanting a dopant of the second doping type into the epitaxial layer via the third opening; stripping the second soft mask layer; performing second etching on the semiconductor body by using the hard mask layer to form, in the semiconductor body, a first trench aligned with the first trench opening and a third trench aligned with the third trench opening; performing thermal annealing on the dopant to form a first doped region in a region of the epitaxial layer near a sidewall of the third trench, wherein the first doped region extends from the top surface of the epitaxial layer to the buried layer, and is configured to electrically connect the buried layer to the top surface of the epitaxial layer; forming a first deep trench structure in the first trench, wherein the first deep trench structure is configured to electrically connect the substrate to the top surface of the epitaxial layer; and forming a third deep trench isolation structure in the third trench, wherein the third deep trench isolation structure is configured to isolate different component regions in the epitaxial layer.

According to an eleventh aspect of the present disclosure, there is provided a semiconductor device, comprising: a semiconductor body, wherein the semiconductor body comprises a substrate, a buried layer disposed on the substrate, and an epitaxial layer disposed on the buried layer, the substrate has a first doping type, and the buried layer has a second doping type opposite to the first doping type; a first trench, extending from a top surface of the epitaxial layer into the substrate and having a first depth; a third trench, extending from the top surface of the epitaxial layer into the buried layer and having a third depth less than the first depth; a first deep trench structure, disposed in the first trench and configured to electrically connect the substrate to the top surface of the epitaxial layer; a third deep trench isolation structure, disposed in the third trench and configured to isolate different component regions in the epitaxial layer; and a first doped region, formed in the epitaxial layer near a sidewall of the third trench and having the second doping type, wherein the first doped region extends from the top surface of the epitaxial layer to the buried layer, and is configured to electrically connect the buried layer to the top surface of the epitaxial layer.

According to a twelfth aspect of the present disclosure, there is provided a method for fabricating a semiconductor device, comprising: providing a semiconductor body, wherein the semiconductor body comprises a substrate, a buried layer disposed on the substrate, and an epitaxial layer disposed on the buried layer, the substrate has a first doping type, and the buried layer has a second doping type opposite to the first doping type; forming a hard mask layer on a top surface of the epitaxial layer; etching the hard mask layer and the semiconductor body by using a third soft mask layer to form, in the hard mask layer, a third trench opening that penetrates through the hard mask layer and to form, in the semiconductor body, a third trench aligned with the third trench opening, wherein the third trench extends from the top surface of the epitaxial layer into the buried layer or to a position in the epitaxial layer and near the buried layer and has a third depth; stripping the third soft mask layer; filling the third trench opening and the third trench with a second conductive material; etching the hard mask layer and the semiconductor body by using a fourth soft mask layer to form, in the hard mask layer, a first trench opening that penetrates through the hard mask layer, and to form, in the semiconductor body, a first trench aligned with the first trench opening, wherein the first trench extends from the top surface of the epitaxial layer into the substrate and has a first depth; and forming a first deep trench structure in the first trench, wherein the first deep trench structure is configured to electrically connect the substrate to the top surface of the epitaxial layer.

According to a thirteenth aspect of the present disclosure, there is provided a method for fabricating a semiconductor device, comprising: providing a semiconductor body, wherein the semiconductor body comprises a substrate, a buried layer disposed on the substrate, and an epitaxial layer disposed on the buried layer, the substrate has a first doping type, and the buried layer has a second doping type opposite to the first doping type; forming a hard mask layer on a top surface of the epitaxial layer; etching the hard mask layer and the semiconductor body by using a fifth soft mask layer to form, in the hard mask layer, a first trench opening that penetrates through the hard mask layer, and to form, in the semiconductor body, a first trench aligned with the first trench opening, wherein the first trench extends from the top surface of the epitaxial layer into the substrate and has a first depth; stripping the fifth soft mask layer; forming a first deep trench structure in the first trench, wherein the first deep trench structure is configured to electrically connect the substrate to the top surface of the epitaxial layer; stripping the hard mask layer;

etching the semiconductor body by using a sixth soft mask layer to form a third trench in the semiconductor body, wherein the third trench extends from the top surface of the epitaxial layer into the buried layer or to a position in the epitaxial layer and near the buried layer and has a third depth less than the first depth; and filling the third trench with a second conductive material, wherein the second conductive material is configured to electrically connect the buried layer to the top surface of the epitaxial layer.

According to a fourteenth aspect of the present disclosure, there is provided a method for fabricating a semiconductor device, comprising: providing a semiconductor body, wherein the semiconductor body comprises a substrate, a buried layer disposed on the substrate, and an epitaxial layer disposed on the buried layer, the substrate has a first doping type, and the buried layer has a second doping type opposite to the first doping type; forming a hard mask layer on a top surface of the epitaxial layer; etching the hard mask layer and the semiconductor body by using a seventh soft mask layer to simultaneously form a first trench and a third trench in the semiconductor body, wherein the first trench extends from the top surface of the epitaxial layer into the substrate and has a first depth, and the third trench extends from the top surface of the epitaxial layer into the buried layer or to a position in the epitaxial layer and near the buried layer and has a third depth less than the first depth; forming a first deep trench structure in the first trench, wherein the first deep trench structure is configured to electrically connect the substrate to the top surface of the epitaxial layer; forming a temporary deep trench structure in the third trench; etching the temporary deep trench structure in the third trench by using an eighth soft mask layer to remove the temporary deep trench structure in the third trench; and filling the third trench with a second conductive material, wherein the second conductive material is configured to electrically connect the buried layer to the top surface of the epitaxial layer.

According to a fifteenth aspect of the present disclosure, there is provided a method for fabricating a semiconductor device, comprising: providing a semiconductor body, wherein the semiconductor body comprises a substrate, a buried layer disposed on the substrate, and an epitaxial layer disposed on the buried layer, the substrate has a first doping type, and the buried layer has a second doping type opposite to the first doping type; forming a hard mask layer on a top surface of the epitaxial layer; etching the hard mask layer and the semiconductor body by using a seventh soft mask layer to simultaneously form a first trench and a third trench in the semiconductor body, wherein the first trench extends from the top surface of the epitaxial layer into the substrate and has a first depth, and the third trench extends from the top surface of the epitaxial layer into the buried layer or to a position in the epitaxial layer and near the buried layer and has a third depth less than the first depth; forming a first deep trench structure in the first trench, wherein the first deep trench structure is configured to electrically connect the substrate to the top surface of the epitaxial layer; forming a temporary deep trench structure in the third trench; etching the temporary deep trench structure in the third trench by using an eighth soft mask layer to remove the temporary deep trench structure in the third trench; obliquely implanting, in the third trench, a dopant of the second doping type into the semiconductor body to form, in the epitaxial layer, a first doped region having the second doping type near a sidewall of the third trench, wherein the first doped region extends from the top surface of the epitaxial layer to the buried layer, and is configured to electrically connect the buried layer to the top surface of the epitaxial layer; and filling the third trench with a dielectric material to form a third deep trench isolation structure.

According to a sixteenth aspect of the present disclosure, there is provided a semiconductor device, comprising: a semiconductor body, wherein the semiconductor body comprises a substrate, a buried layer disposed on the substrate, and an epitaxial layer disposed on the buried layer, the substrate has a first doping type, and the buried layer has a second doping type opposite to the first doping type; a first trench, extending from a top surface of the epitaxial layer into the substrate and having a first depth; a third trench, extending from the top surface of the epitaxial layer into the buried layer and having a third depth less than the first depth; a first deep trench structure, disposed in the first trench and configured to electrically connect the substrate to the top surface of the epitaxial layer; and a second conductive material, filling the third trench, and configured to electrically connect the buried layer to the top surface of the epitaxial layer.

According to a seventeenth aspect of the present disclosure, there is provided a method for fabricating a semiconductor device, comprising: providing a semiconductor body, wherein the semiconductor body comprises a substrate, a buried layer disposed on the substrate, and an epitaxial layer disposed on the buried layer, the substrate has a first doping type, and the buried layer has a second doping type opposite to the first doping type; forming a hard mask layer on a top surface of the epitaxial layer; etching the hard mask layer and the semiconductor body by using a single soft mask layer to simultaneously form a second trench and a third trench in the semiconductor body, wherein the second trench extends from the top surface of the epitaxial layer into the substrate and has a second depth, and the third trench extends from the top surface of the epitaxial layer into the buried layer or to a position in the epitaxial layer and near the buried layer and has a third depth less than the second depth; forming, in the epitaxial layer, a first doped region having the second doping type near a sidewall of the third trench, wherein the first doped region extends from the top surface of the epitaxial layer to the buried layer, and is configured to electrically connect the buried layer to the top surface of the epitaxial layer; forming a second deep trench isolation structure in the second trench, wherein the second deep trench isolation structure is configured to isolate different component regions in the epitaxial layer; and forming a third deep trench isolation structure in the third trench, wherein the third deep trench isolation structure is configured to isolate different component regions in the epitaxial layer.

According to an eighteenth aspect of the present disclosure, there is provided a method for fabricating a semiconductor device, comprising: providing a semiconductor body, wherein the semiconductor body comprises a substrate, a buried layer disposed on the substrate, and an epitaxial layer disposed on the buried layer, the substrate has a first doping type, and the buried layer has a second doping type opposite to the first doping type; forming a hard mask layer on a top surface of the epitaxial layer; performing first etching on the hard mask layer by using a first soft mask layer to simultaneously form, in the hard mask layer, a second trench opening and a third trench opening that penetrate through the hard mask layer; stripping the first soft mask layer; forming a second soft mask layer on the hard mask layer, wherein the second soft mask layer comprises a third opening and the third opening exposes one or more portions of the hard mask layer near the third trench opening; implanting a dopant of the second doping type into the epitaxial layer via the third opening; stripping the second soft mask layer; performing second etching on the semiconductor body by using the hard mask layer to form, in the semiconductor body, a second trench aligned with the second trench opening and a third trench aligned with the third trench opening; performing thermal annealing on the dopant to form a first doped region in a region of the epitaxial layer near a sidewall of the third trench, wherein the first doped region extends from the top surface of the epitaxial layer to the buried layer, and is configured to electrically connect the buried layer to the top surface of the epitaxial layer; forming a second deep trench isolation structure in the second trench, wherein the second deep trench isolation structure is configured to isolate different component regions in the epitaxial layer; and forming a third deep trench isolation structure in the third trench, wherein the third deep trench isolation structure is configured to isolate different component regions in the epitaxial layer.

According to a nineteenth aspect of the present disclosure, there is provided a semiconductor device, comprising: a semiconductor body, wherein the semiconductor body comprises a substrate, a buried layer disposed on the substrate, and an epitaxial layer disposed on the buried layer, the substrate has a first doping type, and the buried layer has a second doping type opposite to the first doping type; a second trench, extending from the top surface of the epitaxial layer into the substrate and having a second depth; a third trench, extending from the top surface of the epitaxial layer into the buried layer and having a third depth less than the second depth; a second deep trench isolation structure, disposed in the second trench and configured to isolate different component regions in the epitaxial layer; a third deep trench isolation structure, disposed in the third trench and configured to isolate different component regions in the epitaxial layer; and a first doped region, formed in the epitaxial layer near a sidewall of the third trench and having the second doping type, wherein the first doped region extends from the top surface of the epitaxial layer to the buried layer, and is configured to electrically connect the buried layer to the top surface of the epitaxial layer.

According to a twentieth aspect of the present disclosure, there is provided a method for fabricating a semiconductor device, comprising: providing a semiconductor body, wherein the semiconductor body comprises a substrate, a buried layer disposed on the substrate, and an epitaxial layer disposed on the buried layer, the substrate has a first doping type, and the buried layer has a second doping type opposite to the first doping type; forming a hard mask layer on a top surface of the epitaxial layer; etching the hard mask layer and the semiconductor body by using a third soft mask layer to form, in the hard mask layer, a third trench opening that penetrates through the hard mask layer and to form, in the semiconductor body, a third trench aligned with the third trench opening, wherein the third trench extends from the top surface of the epitaxial layer into the buried layer or to a position in the epitaxial layer and near the buried layer and has a third depth; stripping the third soft mask layer; filling the third trench opening and the third trench with a second conductive material; etching the hard mask layer and the semiconductor body by using a fourth soft mask layer to form, in the hard mask layer, a second trench opening that penetrate through the hard mask layer, and to form, in the semiconductor body, a second trench aligned with the second trench opening, wherein the second trench extends from the top surface of the epitaxial layer into the substrate and has a second depth greater than the third depth; and forming a second deep trench isolation structure in the second trench, wherein the second deep trench isolation structure is configured to isolate different component regions in the epitaxial layer.

According to a twenty-first aspect of the present disclosure, there is provided a method for fabricating a semiconductor device, comprising: providing a semiconductor body, wherein the semiconductor body comprises a substrate, a buried layer disposed on the substrate, and an epitaxial layer disposed on the buried layer, the substrate has a first doping type, and the buried layer has a second doping type opposite to the first doping type; forming a hard mask layer on a top surface of the epitaxial layer; etching the hard mask layer and the semiconductor body by using a fifth soft mask layer to form, in the hard mask layer, a second trench opening that penetrates through the hard mask layer, and to form, in the semiconductor body, a second trench aligned with the second trench opening, wherein the second trench extends from the top surface of the epitaxial layer into the substrate and has a second depth; stripping the fifth soft mask layer; forming a second deep trench isolation structure in the second trench, wherein the second deep trench isolation structure is configured to isolate different component regions in the epitaxial layer; stripping the hard mask layer; etching the semiconductor body by using a sixth soft mask layer to form a third trench in the semiconductor body, wherein the third trench extends from the top surface of the epitaxial layer into the buried layer or to a position in the epitaxial layer and near the buried layer and has a third depth less than the second depth; and filling the third trench with a second conductive material, wherein the second conductive material is configured to electrically connect the buried layer to the top surface of the epitaxial layer.

According to a twenty-second aspect of the present disclosure, there is provided a method for fabricating a semiconductor device, comprising: providing a semiconductor body, wherein the semiconductor body comprises a substrate, a buried layer disposed on the substrate, and an epitaxial layer disposed on the buried layer, the substrate has a first doping type, and the buried layer has a second doping type opposite to the first doping type; forming a hard mask layer on a top surface of the epitaxial layer; etching the hard mask layer and the semiconductor body by using a seventh soft mask layer to simultaneously form a second trench and a third trench in the semiconductor body, wherein the second trench extends from the top surface of the epitaxial layer into the substrate and has a second depth, and the third trench extends from the top surface of the epitaxial layer into the buried layer or to a position in the epitaxial layer and near the buried layer and has a third depth less than the second depth; forming a second deep trench isolation structure in the second trench, wherein the second deep trench isolation structure is configured to isolate different component regions in the epitaxial layer; forming a temporary deep trench structure in the third trench; etching the temporary deep trench structure in the third trench by using an eighth soft mask layer to remove the temporary deep trench structure in the third trench; and filling the third trench with a second conductive material, wherein the second conductive material is configured to electrically connect the buried layer to the top surface of the epitaxial layer.

According to a twenty-third aspect of the present disclosure, there is provided a method for fabricating a semiconductor device, comprising: providing a semiconductor body, wherein the semiconductor body comprises a substrate, a buried layer disposed on the substrate, and an epitaxial layer disposed on the buried layer, the substrate has a first doping type, and the buried layer has a second doping type opposite to the first doping type; forming a hard mask layer on a top surface of the epitaxial layer; etching the hard mask layer and the semiconductor body by using a seventh soft mask layer to simultaneously form a second trench and a third trench in the semiconductor body, wherein the second trench extends from the top surface of the epitaxial layer into the substrate and has a second depth, and the third trench extends from the top surface of the epitaxial layer into the buried layer or to a position in the epitaxial layer and near the buried layer and has a third depth less than the second depth; forming a second deep trench isolation structure in the second trench, wherein the second deep trench isolation structure is configured to isolate different component regions in the epitaxial layer; forming a temporary deep trench structure in the third trench; etching the temporary deep trench structure in the third trench by using an eighth soft mask layer to remove the temporary deep trench structure in the third trench; obliquely implanting, in the third trench, a dopant of the second doping type into the semiconductor body to form, in the epitaxial layer, a first doped region having the second doping type near a sidewall of the third trench, wherein the first doped region extends from the top surface of the epitaxial layer to the buried layer, and is configured to electrically connect the buried layer to the top surface of the epitaxial layer; and filling the third trench with a dielectric material to form a third deep trench isolation structure.

According to a twenty-fourth aspect of the present disclosure, there is provided a semiconductor device, comprising: a semiconductor body, wherein the semiconductor body comprises a substrate, a buried layer disposed on the substrate, and an epitaxial layer disposed on the buried layer, the substrate has a first doping type, and the buried layer has a second doping type opposite to the first doping type; a second trench, extending from the top surface of the epitaxial layer into the substrate and having a second depth; a third trench, extending from the top surface of the epitaxial layer into the buried layer and having a third depth less than the second depth; a second deep trench isolation structure, disposed in the second trench and configured to isolate different component regions in the epitaxial layer; and a second conductive material, filling the third trench, and configured to electrically connect the buried layer to the top surface of the epitaxial layer.

The SUMMARY section is provided to describe selection of concepts in a simplified form. The concepts are further described below in DESCRIPTION OF EMBODIMENTS. The SUMMARY section is neither intended to identify key features or main features of the present disclosure, nor intended to limit the scope of the present disclosure.

### BRIEF DESCRIPTION OF DRAWINGS

The foregoing and other objectives, features, and advantages of embodiments of the present disclosure become easy to understand by reading the following detailed description with reference to accompanying drawings. In the accompanying drawings, several embodiments of the present disclosure are illustrated by way of example but not limitation, in which:

FIG. 1 illustratively shows a cross-sectional view of a semiconductor device according to a first embodiment of the present disclosure;

FIG. 2A to FIG. 2O show a process for fabricating a semiconductor device according to a second embodiment of the present disclosure;

FIG. 3A to FIG. 3J show a process for fabricating a semiconductor device according to a third embodiment of the present disclosure;

FIG. 4A to FIG. 4E show a process for fabricating a semiconductor device according to a fourth embodiment of the present disclosure;

FIG. 5A to FIG. 5J show a process for fabricating a semiconductor device according to a fifth embodiment of the present disclosure;

FIG. 6 illustratively shows a cross-sectional view of a semiconductor device according to a sixth embodiment of the present disclosure;

FIG. 7A to FIG. 7L show a process for fabricating a semiconductor device according to a seventh embodiment of the present disclosure;

FIG. 8 illustratively shows a cross-sectional view of a semiconductor device according to an eighth embodiment of the present disclosure;

FIG. 9A to FIG. 9I show a process for fabricating a semiconductor device according to a ninth embodiment of the present disclosure;

FIG. 10A to FIG. 10K show a process for fabricating a semiconductor device according to a tenth embodiment of the present disclosure;

FIG. 11A to FIG. 11J show a process for fabricating a semiconductor device according to an eleventh embodiment of the present disclosure;

FIG. 12A to FIG. 12L show a process for fabricating a semiconductor device according to a twelfth embodiment of the present disclosure;

FIG. 13 illustratively shows a cross-sectional view of a semiconductor device according to a thirteenth embodiment of the present disclosure; and

FIG. 14A to FIG. 14M show a process for fabricating a semiconductor device according to a fourteenth embodiment of the present disclosure.

### DESCRIPTION OF EMBODIMENTS

Exemplary embodiments of the present disclosure are described in more detail below with reference to accompanying drawings. Although the exemplary embodiments of the present disclosure are shown in the accompanying drawings, it should be understood that the present disclosure can be implemented in various forms and should not be limited by the embodiments described herein. Instead, these embodiments are provided in order to make the present disclosure more thorough and complete, and the scope of the present disclosure can be completely conveyed to a person skilled in the art.

The term “comprise” and variants thereof used herein represent open-ended inclusion, that is, “comprising but not limited to”. Unless otherwise specifically stated, the term “or” represents “and/or”. The term “based on” represents “at least partially based on”. The terms “an exemplary embodiment” and “an embodiment” represent “at least one exemplary embodiment”. The term “another embodiment” represents “at least one further embodiment”. The terms “first”, “second”, and the like may refer to different or same objects.

In addition, the terms “top”, “bottom”, “above”, “below”, “over”, “under”, and the like used herein are used for descriptive purposes and are not necessarily used to describe relative positions. It should be understood that the terms so used are interchangeable where appropriate, and the embodiments of the present disclosure can operate in other directions than those described or illustrated herein.

The embodiments of the present disclosure generally relate to a semiconductor device or an integrated circuit (IC). More specifically, some embodiments relate to a semiconductor device or an integrated circuit that integrates a high power component and other components such as logic and storage components on the same substrate. For example, the high power component comprises a lateral double diffused metal oxide semiconductor (LDMOS) transistor. Another suitable high power component is also usable. The high power component can be used as a switching regulator for a power management application. Embodiments of the present disclosure provide a plurality of types of deep trench isolation (DTI) structures or regions without requiring additional masking steps. The DTI structures or regions effectively isolate the high power component from other components in the same IC together with a buried layer (for example, an N+ buried layer (NBL)).

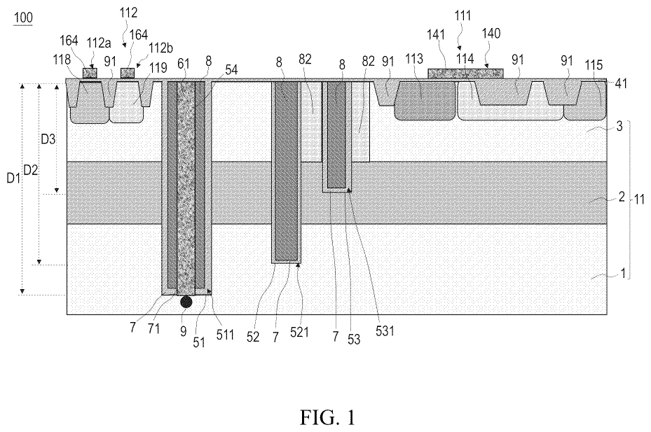

FIG. 1 illustratively shows a cross-sectional view of a semiconductor device 100 according to a first embodiment of the present disclosure. For example, the semiconductor device 100 is an integrated circuit. Another type of device is also feasible. As shown in FIG. 1, the semiconductor device 100 comprises a semiconductor body 11. The semiconductor body 11 comprises a substrate 1, a buried layer 2 disposed on the substrate 1, and an epitaxial layer 3 disposed on the buried layer 2. The substrate 1 has a first doping type, and the buried layer 2 has a second doping type opposite to the first doping type. For example, when the first doping type is a p-type, the second doping type is an n-type. Similarly, when the first doping type is an n-type, the second doping type is a p-type. A p-type dopant may comprise boron (B), aluminum (Al), indium (In), or a combination thereof, and an n-type dopant may comprise phosphorus (P), arsenic (As), antimony (Sb), or a combination thereof. In an embodiment, the buried layer 2 may have a blanket (blanket) structure, which has substantially the same horizontal extension as the substrate 1 and is laid flatly on the substrate 1. In another embodiment, the buried layer 2 may have a patterned structure. This is not strictly limited in the embodiments of the present disclosure.

The epitaxial layer 3 may comprise a plurality of component regions. For purposes of illustration, the epitaxial layer 3 shown in FIG. 1 comprises a first component region 111 and a second component region 112. For example, the first component region 111 may be a high voltage (HV) component region used for an HV component (such as an HV transistor). In an embodiment, the first component region 111 used as an HV component region comprises one or more lateral double diffused metal oxide semiconductor (LDMOS) transistors 140. The first component region 111 is prepared for a component operating within a high voltage range, for example, at a voltage of about 100 V. Another suitable voltage value is also feasible. The second component region 112 can be used as a low voltage (LV) or medium voltage (MV) component region. When the second component region 112 is a low voltage component region, the second component region 112 is suitable for accommodating an LV transistor, and when the second component region is an MV component region, the second component region 112 is suitable for accommodating an MV transistor. In an embodiment, the second component region 112 comprises one or more complementary metal oxide semiconductor (CMOS) transistors.

As shown in FIG. 1, the LDMOS transistor 140 comprises a gate electrode 141 disposed over a top surface of the epitaxial layer 3. A gate dielectric, such as a first oxide layer 41, is disposed between the gate electrode 141 and the epitaxial layer 3. A first well region 113 is disposed in the epitaxial layer 3 and used as a body (body) of the LDMOS transistor 140. The first well region 113 comprises a doping type opposite to the type of the LDMOS transistor 140. For example, for an n-type LDMOS transistor 140, the first well region 113 comprises a p-type dopant. For a p-type LDMOS transistor 140, the first well region 113 comprises an n-type dopant. A second well region 115 is disposed in the epitaxial layer 3, and is spaced apart from the first well region 113. The second well region 115 comprises a doping type opposite to the type of the LDMOS transistor 140. For the n-type LDMOS transistor 140, the second well region 115 comprises a p-type dopant. For the p-type LDMOS transistor 140, the second well region 115 comprises an n-type dopant. A source and a drain of the LDMOS transistor 140 may be formed in the first well region 113 and the second well region 115. A drift region 114 is disposed in the epitaxial layer 3 and between the first well region 113 and the second well region 115. The drift region 114 comprises a doping type same as the type of the LDMOS transistor 140. For example, for the n-type LDMOS transistor 140, the drift region 114 comprises an n-type dopant. For the p-type LDMOS transistor 140, the drift region 114 comprises a p-type dopant. A plurality of isolation regions 91, such as shallow trench isolation (STI) regions, are disposed in the first component region 111 to isolate different doped regions in the epitaxial layer 3.

As shown in FIG. 1, a first transistor 112a and a second transistor 112b are disposed in the second component region 112. A plurality of isolation regions 91, such as shallow trench isolation (STI) regions, are disposed in the second component region 112 to isolate the first transistor 112a from the second transistor 112b. The first transistor 112a comprises a third well region 118 and a gate electrode 164 disposed over the third well region 118. A gate dielectric, such as a first oxide layer 41, is disposed between the gate electrode 164 and the third well region 118. The third well region 118 comprises a dopant having a type opposite to the type of the first transistor 112a. The second transistor 112b comprises a fourth well region 119 and a gate electrode 164 disposed over the fourth well region 119. A gate dielectric, such as the first oxide layer 41, is disposed between the gate electrode 164 and the fourth well region 119. The fourth well region 119 comprises a dopant having a type opposite to the type of the second transistor 112b.

In an embodiment, the first transistor 112a and the second transistor 112b are transistors of opposite polarity types, thereby forming a complementary metal oxide semiconductor (CMOS) transistor. For example, when the first transistor 112a is a p-type transistor, the second transistor 112b is an n-type transistor. When the first transistor 112a is an n-type transistor, the second transistor 112b is a p-type transistor.

To isolate the first component region 111 from the second component region 112, a first trench 51, a second trench 52, a third trench 53, a first deep trench structure 511, a second deep trench isolation structure 521, a third deep trench isolation structure 531, and a first doped region 82 are formed in the semiconductor body 11. The first trench 51 extends from the top surface of the epitaxial layer 3 into the substrate 1 and has a first depth D1. In other words, a bottom of the first trench 51 is lower than a top surface of the substrate 1. The second trench 52 extends from the top surface of the epitaxial layer 3 into the substrate 1 and has a second depth D2 less than the first depth D1. In other words, a bottom of the second trench 52 is lower than the top surface of the substrate 1 and higher than the bottom of the first trench 51. The third trench 53 extends from the top surface of the epitaxial layer 3 into the buried layer 2 and has a third depth D3 less than the second depth D2. The first doped region 82 is formed in the epitaxial layer 3 and near a sidewall of the third trench 53 and has a second doping type. The first trench 51, the second trench 52, and the third trench 53 may be formed in a same process step or in different process steps. Details are described below. When the first trench 51, the second trench 52, and the third trench 53 are formed in the same process step, different trench depths can be implemented by providing different mask opening sizes. A larger mask opening leads to a deeper trench. On the contrary, a smaller mask opening leads to a shallower trench.

The first deep trench structure 511 is disposed in the first trench 51 to electrically connect the substrate 1 to the top surface of the epitaxial layer 3. In an embodiment, as shown in FIG. 1, the first deep trench structure 511 comprises a pad 7, a dielectric layer 8, and a first conductive material 61. The pad 7 is formed on a sidewall and at least a portion of a bottom of the first trench 51, and comprises a first opening 71 formed at the bottom of the first trench 51. The pad 7 can repair damage caused to the sidewall of the trench when the semiconductor body 11 is etched to form the first trench 51, so as to deposit a subsequent layer thereon. In an embodiment, the pad 7 comprises oxide such as silicon oxide. Another type of pad is also feasible. The dielectric layer 8 is disposed inside the pad 7 in the first trench 51, and comprises a second opening 54 extending from the top surface of the epitaxial layer 3 to the pad 7 at the bottom of the first trench 51. The second opening 54 is aligned with the first opening 71, thereby forming an opening extending from the top surface of the epitaxial layer 3 to the bottom of the first trench 51. In an embodiment, the dielectric layer 8 comprises oxide such as silicon oxide. Another type of dielectric layer is also feasible. The first conductive material 61 fills the first opening 71 and the second opening 54, that is, extends from the top surface of the epitaxial layer 3 to the bottom of the first trench 51 and is in contact with the substrate 1. With this arrangement, the first conductive material 61 can be used as a pickup (pickup) structure of the substrate 1 to electrically connect the substrate 1 to the top surface of the epitaxial layer 3. This can, on one hand, connect the substrate 1 to any desired potential to avoid impact from noise, and can, on the other hand, avoid a latch-up problem. In addition, because the pad 7 and the dielectric layer 8 that are disposed in the first trench 51 extend from the top surface of the epitaxial layer 3 to the bottom of the trench, different component regions, such as the first component region 111 and the second component region 112, can be isolated to some extent, thereby enhancing isolation performance between the first component region 111 and the second component region 112.

In an embodiment, the first conductive material 61 comprises polysilicon having the first doping type. Because the first conductive material 61 and the substrate 1 have the same doping type, the first conductive material 61 can be used as a pickup structure of the substrate 1, so as to electrically connect the substrate 1 to the top surface of the epitaxial layer 3 at low resistivity, thereby avoiding a latch-up problem. In another embodiment, another type of first conductive material 61 is also feasible, provided that the substrate 1 can be electrically connected to the top surface of the epitaxial layer 3.

The first deep trench structure 511 may have another structure to electrically connect the substrate 1 to the top surface of the epitaxial layer 3. For example, in some embodiments, the dielectric layer 8 may be omitted, and the first conductive material 61 may directly fill internal space surrounded by the pad 7. With this arrangement, the substrate 1 can also be electrically connected to the top surface of the epitaxial layer 3. In some embodiments, the pad 7 may be omitted, the dielectric layer 8 may be directly formed on the sidewall of the first trench 51, and internal space surrounded by the dielectric layer 8 is filled with the first conductive material 61. With this arrangement, the substrate 1 can also be electrically connected to the top surface of the epitaxial layer 3. In addition, in some embodiments, both the pad 7 and the dielectric layer 8 may be even omitted, and the first conductive material 61 may directly fill the first trench 51. With this arrangement, the substrate 1 can also be electrically connected to the top surface of the epitaxial layer 3. It should be understood that the first deep trench structure 511 may have various structures, provided that the substrate 1 can be electrically connected to the top surface of the epitaxial layer 3.

In an embodiment, as shown in FIG. 1, the semiconductor device 100 further comprises a second doped region 9. The second doped region 9 is formed in the substrate 1 near the bottom of the first trench 51. The second doped region 9 has the same first doping type as the substrate 1, and has a doping concentration higher than that of the substrate 1. Using such arrangement can enhance electrical connection performance between the first conductive material 61 and the substrate 1, thereby electrically connecting the substrate 1 to the top surface of the epitaxial layer 3 more reliably. Certainly, when the doping concentration of the substrate 1 is high, the second doped region 9 may be omitted.

The second deep trench isolation structure 521 is disposed in the second trench 52 to isolate different component regions in the epitaxial layer 3, for example, to isolate the first component region 111 from the second component region 112. In an embodiment, as shown in FIG. 1, the second deep trench isolation structure 521 comprises a pad 7 and a dielectric layer 8. The pad 7 is disposed on a sidewall and a bottom of the second trench 52. The pad 7 can repair damage caused to the sidewall of the trench when the semiconductor body 11 is etched to form the second trench 52, so as to deposit a subsequent layer thereon. In an embodiment, the pad 7 comprises oxide such as silicon oxide. Another type of pad is also feasible. The dielectric layer 8 is disposed inside the pad 7 in the second trench 52, and completely or partially fills the second trench 52. The dielectric layer 8 partially fills the second trench 52. On one hand, stress can be reduced, and on the other hand, parasitic capacitance can be reduced. For example, an air gap may be formed in the dielectric layer 8 in the second trench 52. In an embodiment, the dielectric layer 8 comprises oxide such as silicon oxide. Another type of dielectric layer is also feasible. Because the pad 7 and the dielectric layer 8 that are disposed in the second trench 52 extend from the top surface of the epitaxial layer 3 to the bottom of the trench, different component regions in the epitaxial layer 3 can be isolated. In an embodiment, the pad 7 and the dielectric layer 8 in the second trench 52 may be formed in the same process steps in which the pad 7 and the dielectric layer 8 in the first trench 51 are respectively formed. In another embodiment, the pad 7 and the dielectric layer 8 in the second trench 52 may be formed in process steps different from the ones in which the pad 7 and the dielectric layer 8 in the first trench 51 are respectively formed.

The second deep trench isolation structure 52 may have another structure to isolate different component regions in the epitaxial layer 3. For example, in some embodiments, the pad 7 may be omitted and the dielectric layer 8 may be directly deposited into the second trench 52. With this arrangement, different component regions in the epitaxial layer 3 can also be isolated reliably.

In some embodiments, as shown in FIG. 1, the depth D1 of the first trench 51 is greater than the depth D2 of the second trench 52. However, it should be understood that in another embodiment, D1 of the first trench 51 may be close to the depth D2 of the second trench 52. This can also implement reliable isolation between different component regions.

The third deep trench isolation structure 531 is disposed in the third trench 53 to isolate different component regions in the epitaxial layer 3, for example, to isolate the first component region 111 from the second component region 112. In an embodiment, as shown in FIG. 1, the third deep trench isolation structure 531 comprises a pad 7 and a dielectric layer 8. The pad 7 is disposed on a sidewall and a bottom of the third trench 53. The pad 7 can repair damage caused to the sidewall of the trench when the semiconductor body 11 is etched to form the third trench 53, so as to deposit a subsequent layer thereon. In an embodiment, the pad 7 comprises oxide such as silicon oxide. Another type of pad is also feasible. The dielectric layer 8 is disposed inside the pad 7 in the third trench 53, and completely fills the third trench 53. In an embodiment, the dielectric layer 8 comprises oxide such as silicon oxide. Another type of dielectric layer is also feasible. Because the pad 7 and the dielectric layer 8 that are disposed in the third trench 53 extend from the top surface of the epitaxial layer 3 to the bottom of the trench, different component regions in the epitaxial layer 3 can be isolated. In an embodiment, the pad 7 and the dielectric layer 8 in the third trench 53 may be formed in the same process steps in which the pad 7 and the dielectric layer 8 in the first trench 51 are respectively formed. In another embodiment, the pad 7 and the dielectric layer 8 in the third trench 53 may be formed in process steps different from the ones in which the pad 7 and the dielectric layer 8 in the first trench 51 are respectively formed.

In some embodiments, the third deep trench isolation structure 531 may comprise: a diffusion material 81 which partially fills the third trench 53; and a dielectric material (such as silicon oxide, undoped polysilicon, and silicon nitride, etc.) which seals the diffusion material 81 in the third trench 53. The diffusion material 81 and the dielectric material jointly form the third deep trench isolation structure 531. In this way, the dielectric material can ensure that an opening of the third trench 53 is sealed, so as to prevent subsequent wet etching from removing a diffusion material 81 in the third trench 53. The diffusion material 81 is a material used to form the first doped region 82 in the epitaxial layer 3 through thermal annealing, as described below. The diffusion material 81 comprises a dopant of the second doping type. In an embodiment, when the first doping type is a p-type, the diffusion material 81 comprises at least one of POCl3 glass and phosphate silicate glass, and the dopant is a phosphorus element. In an embodiment, when the first doping type is an n-type, the diffusion material 81 comprises borosilicate glass, and the dopant is a boron element. Another type of diffusion material and another type of dopant are feasible.

The first doped region 82 is formed in the epitaxial layer 3 and near the sidewall of the third trench 53 and has the same second doping type as the buried layer 2. The first doped region 82 extends from the top surface of the epitaxial layer 3 to the buried layer 2 to electrically connect the buried layer 2 to the top surface of the epitaxial layer 3. Because the first doped region 82 and the buried layer 2 have the same doping type, the first doped region 82 can be used as a pickup structure of the buried layer 2, so as to connect the buried layer 2 to the top surface of the epitaxial layer 3 at low resistivity.

In some embodiments, as shown in FIG. 1, the first doped region 82 is disposed near both sides of the third trench 53. Simultaneously disposing the first doped region 82 on both sides of the third trench 53 can enhance reliability of the pickup structure of the buried layer 2. Even when electrical connection performance of the first doped region 82 on one side of the third trench 53 is degraded, the buried layer 2 can still be electrically connected to the top surface of the epitaxial layer 3 reliably by using the first doped region 82 on the other side of the third trench 53. In some embodiments, the first doped region 82 may be disposed only near one side of the third trench 53. This can also electrically connect the buried layer 2 to the top surface of the epitaxial layer 3. Details are described below.

In a first embodiment, the first deep trench structure 511, the second deep trench isolation structure 521, the third deep trench isolation structure 531, and the first doped region 82 can achieve different functions. Specifically, the first deep trench structure 511 can be used as a pickup structure of the substrate 1 to electrically connect the substrate 1 to the top surface of the epitaxial layer 3. When the first deep trench structure 511 further comprises the pad 7 and the dielectric layer 8, the first deep trench structure 511 can further isolate different component regions to some extent. The second deep trench isolation structure 521 can provide a sufficiently high breakdown voltage (BV) to reliably isolate different component regions in the epitaxial layer 3. Specifically, compared with an isolation effect between components achieved by using the pad 7 and the dielectric layer 8 in the first deep trench structure 511, the dielectric layer 8 (or further comprising the pad 7) that plays an isolation role in the second deep trench isolation structure 521 has a greater width, and achieves a better isolation effect, and therefore can provide a higher breakdown voltage (BV). The third deep trench isolation structure 531 can further enhance isolation performance between different component regions. Therefore, the first deep trench structure 511, the second deep trench isolation structure 521, and the third deep trench isolation structure 531 work together to enhance an isolation effect, so that reliability of a device is improved. In addition, the first doped region 82 can be used as a pickup structure of the buried layer 2 to electrically connect the buried layer 2 to the top surface of the epitaxial layer 3. When the buried layer 2 is buried more deeply, the semiconductor device 100 can tolerate a higher voltage. However, how to connect such a deep buried layer 2 is a challenge. Compared with a conventional solution in which a plurality of masking steps need to be used to implement connection of the buried layer 2, a manner of doping a trench sidewall with a doping material is more cost-effective. Because the first doped region 82 is close to the third deep trench isolation structure 531, an isolation effect of the third deep trench isolation structure 531 enables the first doped region 82 being closer to a neighboring region, so that a structural layout of an entire chip or IC is more compact, thereby reducing an area and reducing costs. In this way, a reliable, high-performance, simple, and cost-effective solution is provided to integrate various suitable isolation structures, effectively isolating HV components from other components in the same IC.

It should be understood that, in some embodiments, when the low voltage component region and the medium voltage component region are isolated, the second deep trench isolation structure 521 may be omitted, and the first deep trench structure 511, the third deep trench isolation structure 531, and the first doped region 82 are disposed between different component regions. In such an embodiment, except that the second trench 52 and the second deep trench isolation structure 521 are not comprised, another structure of the semiconductor device 100 is similar to that of the semiconductor device 100 described with reference to FIG. 1, and details are not described herein again.

In addition, it should be understood that in some embodiments, only isolation between component regions and electrical connection of the buried layer 2 to the surface of the epitaxial layer 3 may need to be implemented between some component regions, without requiring a pickup structure of the substrate 1. The first deep trench structure 511 may be omitted between such component regions, and the second deep trench isolation structure 521, the third deep trench isolation structure 531, and the first doped region 82 are disposed between different component regions. In such an embodiment, except that the first trench 51 and the first deep trench structure 511 are not comprised, another structure of the semiconductor device 100 is similar to that of the semiconductor device 100 described with reference to FIG. 1, and details are not described herein again.

In addition, it should be understood that the isolation structure described above is used to isolate the LDMOS transistor 140 from the CMOS transistors 112a and 112b. However, it should be understood that the foregoing isolation structure may also be used to isolate another type of component region. This is not strictly limited in the embodiments of the present disclosure.

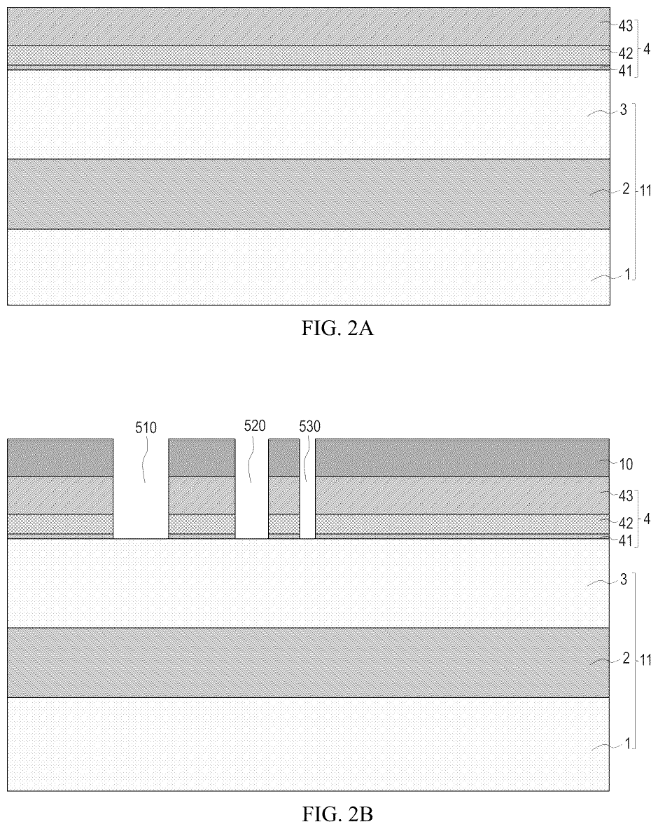

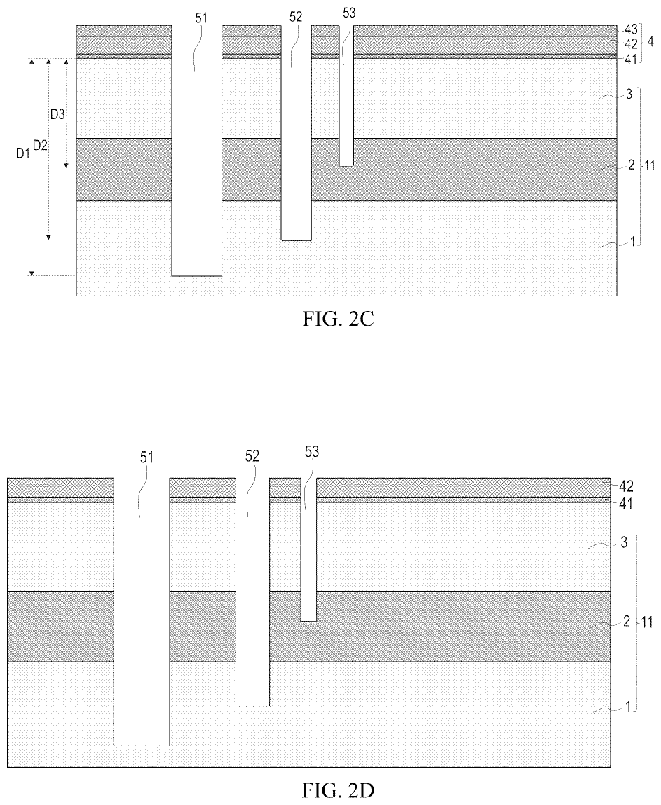

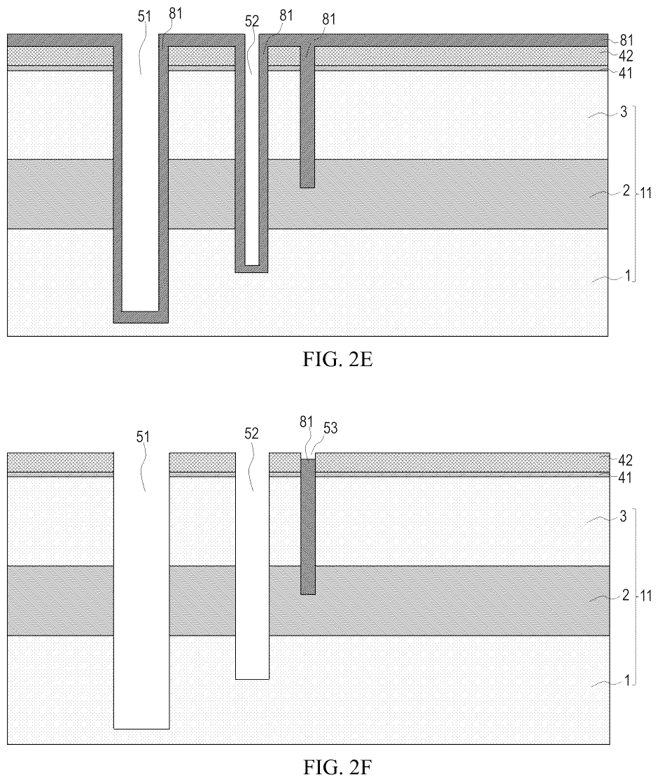

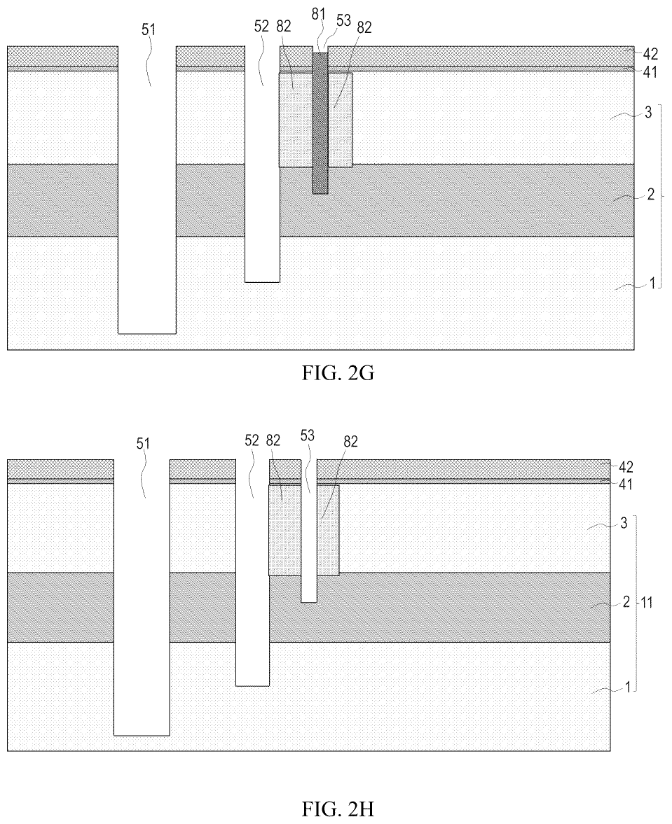

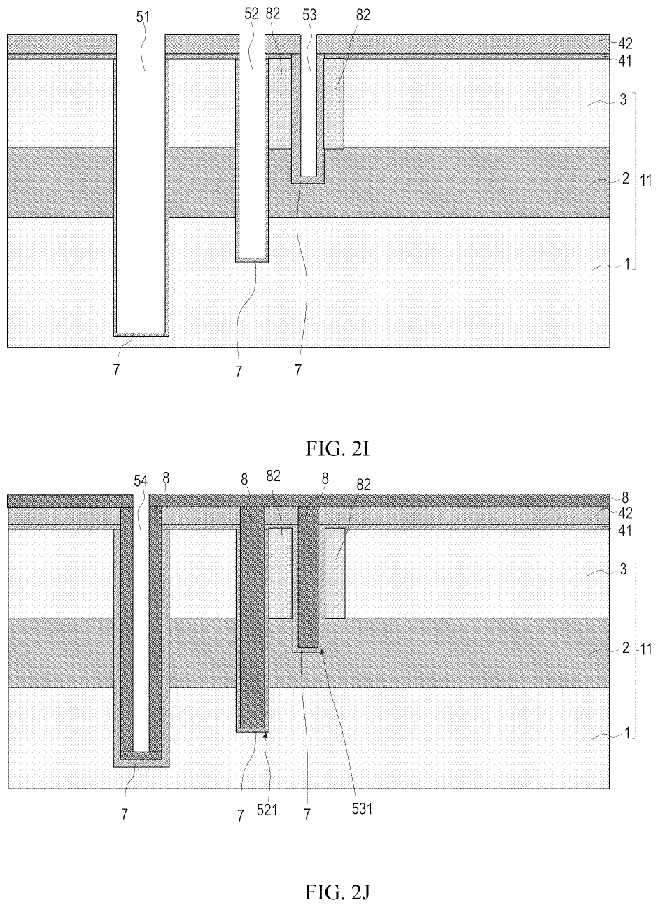

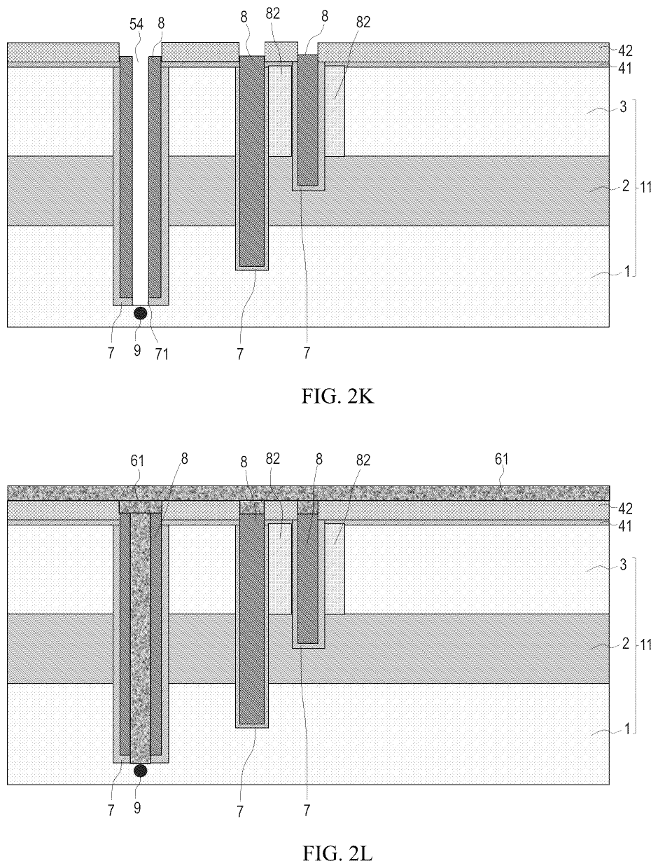

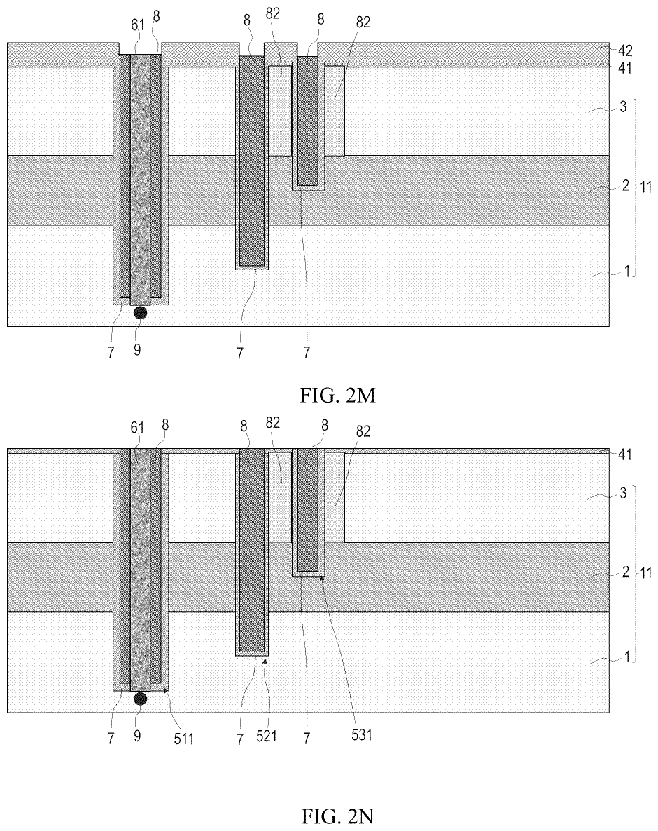

FIG. 2A to FIG. 2O show a process for fabricating a semiconductor device 100 according to a second embodiment of the present disclosure. The process shown in FIG. 2A to FIG. 2O may be used to fabricate the semiconductor device 100 shown in FIG. 1. The foregoing description of the semiconductor device 100 with reference to FIG. 1 may be combined herein.

As shown in FIG. 2A, a semiconductor body 11 is provided. The semiconductor body 11 comprises a substrate 1, a buried layer 2 disposed on the substrate 1, and an epitaxial layer 3 disposed on the buried layer 2. The buried layer 2 may be formed on the substrate 1 through epitaxial growth. The epitaxial layer 3 may be formed on the buried layer 2 through epitaxial growth. The substrate 1 has a first doping type. The buried layer 2 has a second doping type opposite to the first doping type. For example, when the first doping type is a p-type, the second doping type is an n-type. Similarly, when the first doping type is an n-type, the second doping type is a p-type. In an embodiment, the buried layer 2 may have a blanket structure, which has substantially the same horizontal extension as the substrate 1 and is laid flatly on the substrate 1. In another embodiment, the buried layer 2 may have a patterned structure. This is not strictly limited in the embodiments of the present disclosure. The epitaxial layer 3 may be used to form different component regions.

In addition, as shown in FIG. 2A, a hard mask layer 4 is formed on a top surface of the epitaxial layer 3. Forming the hard mask layer 4 may comprise: growing a first oxide layer 41 on the top surface of the epitaxial layer 3; depositing a nitride layer 42 on the first oxide layer 41; and depositing a second oxide layer 43 on the nitride layer 42. In another embodiment, the hard mask layer 4 may have another structure. This is not strictly limited in the embodiments of the present disclosure.

As shown in FIG. 2B, first etching is performed on the hard mask layer 4 by using a single soft mask layer 10 to simultaneously form, in the hard mask layer 4, a first trench opening 510, a second trench opening 520, and a third trench opening 530 that penetrate through the hard mask layer 4. In an embodiment, a width of the first trench opening 510 is greater than a width of the second trench opening 520, and the width of the second trench opening 520 is greater than a width of the third trench opening 530.

As shown in FIG. 2C, the single soft mask layer 10 is stripped from a top surface of the hard mask layer 4. Subsequently, second etching is performed on the semiconductor body 11 by using the hard mask layer 4 to form, in the semiconductor body 11, a first trench 51 aligned with the first trench opening 510, a second trench 52 aligned with the second trench opening 520, and a third trench 53 aligned with the third trench opening 530. The first trench 51 extends from the top surface of the epitaxial layer 3 into the substrate 1 and has a first depth D1. The second trench 52 extends from the top surface of the epitaxial layer 3 into the substrate 1 and has a second depth D2. The third trench 53 extends from the top surface of the epitaxial layer 3 into the buried layer 2 and has a third depth D3. The width of the first trench opening 510 is greater than the width of the second trench opening 520, and the width of the second trench opening 520 is greater than the width of the third trench opening 530. Therefore, the first depth D1 of the first trench 51 is greater than the second depth D2 of the second trench 52, and the second depth D2 of the second trench 52 is greater than the third depth D3 of the third trench 53.

In some embodiments, unlike the first etching and the second etching described with reference to FIG. 2B and FIG. 2C, single etching may be performed on the hard mask layer 4 and the semiconductor body 11 by using the single soft mask layer 10 to simultaneously form, in the hard mask layer 4, the first trench opening 510, the second trench opening 520, and the third trench opening 530 that penetrate through the hard mask layer 4, and to simultaneously form, in the semiconductor body 11, the first trench 51 aligned with the first trench opening 510, the second trench 52 aligned with the second trench opening 520, and the third trench 53 aligned with the third trench opening 530.

As shown in FIG. 2D, the second oxide layer 43 is removed. It should be understood that the step of removing the second oxide layer 43 is optional. In another embodiment, a subsequent step may be performed without removing the second oxide layer 43.

As shown in FIG. 2E, a diffusion material 81 of a proper thickness is deposited so that the diffusion material 81 completely fills the third trench 53, whereas the first trench 51 and the second trench 52 are only partially filled. The diffusion material 81 comprises a dopant of the second doping type. In an embodiment, when the first doping type is a p-type, the diffusion material 81 comprises at least one of POCl3 glass and phosphate silicate glass, and the dopant is a phosphorus element. In an embodiment, when the first doping type is an n-type, the diffusion material 81 comprises borosilicate glass, and the dopant is a boron element. Another type of diffusion material and another type of dopant are feasible. As shown in FIG. 2F, isotropic etching (for example, wet etching) is performed on the diffusion material 81 to remove the diffusion material 81 in the first trench 51 and the second trench 52, and only the diffusion material 81 in the third trench 53 is retained. In some embodiments, ion implantation may be performed at the bottom of the first trench 51 and/or the second trench 52 to form, in the substrate 1, respective doped regions near the bottom of the first trench 51 and/or the second trench 52. The doped region has the first doping type and has a doping concentration higher than that of the substrate 1. Forming a doped region under the second trench 52 can reduce a gain of a lateral parasitic transistor (a concentration of a base region increases), thereby suppressing lateral leakage. In some embodiments, after the isotropic etching and before ion implantation is performed on the bottom of the first trench 51 and/or the second trench 52, a very thin protective layer (such as non-doped silicon dioxide/silicon nitride) may be formed in the first trench 51 and the second trench 52 and on an upper surface of the third trench 53, avoiding ion implantation on a side of the first trench 51 and/or the second trench 52, and preventing a doping element in the third trench 53 from escaping from an upper part of the third trench 53.

As shown in FIG. 2G, thermal annealing is performed on the diffusion material 81 so that the dopant of the second doping type in the diffusion material 81 is diffused into a region of the epitaxial layer 3 near the sidewall of the third trench 53 to form the first doped region 82. The first doped region 82 is formed near both sides of the third trench 53 and extends from the top surface of the epitaxial layer 3 to the buried layer 2 to electrically connect the buried layer 2 to the top surface of the epitaxial layer 3. Because the first doped region 82 and the buried layer 2 have the same second doping type, the first doped region 82 can be used as a pickup structure of the buried layer 2, so as to connect the buried layer 2 to the top surface of the epitaxial layer 3 at low resistivity. In addition, a dopant in the buried layer 2 may be alternatively diffused upward into the epitaxial layer 3 or downward into the substrate 1 during the thermal annealing. Therefore, the buried layer 2 may have a wider extension range than that shown in FIG. 2G, for example, extends upward to a specific depth in the epitaxial layer 3 or downward to a specific depth in the substrate 1. In this case, the third trench 53 formed in the semiconductor body 11 may not extend into the buried layer 2 (certainly, extending into the buried layer 2 is still feasible), but the bottom of the third trench 53 may move upward to a position of the epitaxial layer 3 near the buried layer 2, as shown in FIG. 2G (for example, within a range of a level of several microns apart from a top surface of the buried layer 2 shown in FIG. 2G). In the thermal annealing process, the buried layer 2 extends upward and is in contact with the first doped region 82. Therefore, with such arrangement, the first doped region 82 can also electrically connect the buried layer 2 to the top surface of the epitaxial layer 3 reliably.

As shown in FIG. 2H, isotropic etching is performed on the diffusion material 81 in the third trench 53 to completely remove the diffusion material 81 from the third trench 53.

In some embodiments, unlike the steps shown in FIG. 2E to FIG. 2H, the first doped region 82 may be alternatively formed by implanting, at an oblique angle, a dopant of the second doping type through the sidewall of the third trench 53. Optionally, after the dopant of the second doping type is implanted, the dopant of the second doping type may be further diffused in the epitaxial layer 3 by using a thermal annealing step.

As shown in FIG. 2I, the first trench 51, the second trench 52, and the third trench 53 are lined to form a pad 7 on a sidewall and a bottom of each of the first trench 51, the second trench 52, and the third trench 53. The pad 7 can repair damage caused to the sidewall of the trench when the semiconductor body 11 is etched to form the first trench 51, the second trench 52, and the third trench 53, so as to deposit a subsequent layer thereon. In an embodiment, the pad 7 comprises oxide such as silicon oxide. Another type of pad is also feasible.

As shown in FIG. 2J, the dielectric layer 8 is deposited so that the dielectric layer 8 forms, in the first trench 51, a second opening 54 that extends from the top surface of the epitaxial layer 3 toward the bottom of the first trench 51, and the dielectric layer 8 completely fills the second trench 52 and the third trench 53. In some embodiments, the dielectric layer 8 may partially fill the second trench 52. This can reduce stress on one hand, and reduce parasitic capacitance on the other hand. For example, an air gap may be formed in the dielectric layer 8 in the second trench 52. In an embodiment, the dielectric layer 8 comprises oxide such as silicon oxide. Another type of dielectric layer is also feasible. The pad 7 and the dielectric layer 8 in the second trench 52 form the second deep trench isolation structure 521, and the pad 7 and the dielectric layer 8 in the third trench 53 form the third deep trench isolation structure 531 to isolate different component regions that are to be formed in the epitaxial layer 3 in subsequent steps.

As shown in FIG. 2K, anisotropic etching is performed on the dielectric layer 8 and the pad 7 to remove the dielectric layer 8 from a top surface of the nitride layer 42, and to extend the second opening 54 to the pad 7 at the bottom of the first trench 51, and to form a first opening 71 aligned with the second opening 54 in the pad 7 at the bottom of the first trench 51. Optionally, ion implantation may be performed on the substrate 1 through the second opening 54 and the first opening 71 to form, in the substrate 1, a second doped region 9 near the bottom of the first trench 51. The second doped region 9 has the first doping type and has a doping concentration higher than that of the substrate 1. When the doping concentration of the substrate 1 is high, the second doped region 9 may be omitted. In addition, in some embodiments, before the anisotropic etching is performed on the dielectric layer 8 and the pad 7, ion implantation may be performed in the substrate 1 near the bottom of the first trench 51 to form the second doped region 9. In addition, in some embodiments, after the pad 7 is formed and before the dielectric layer 8 is formed, ion implantation may be performed in the substrate 1 near the bottom of the first trench 51 to form the second doped region 9. Forming the second doped region 9 in another process step is also feasible. For example, the second doped region 9 is formed after thermal annealing is performed on the diffusion material 81 and before the pad 7 is formed.

As shown in FIG. 2L, the first conductive material 61 is deposited so that the first conductive material 61 fills the first opening 71 and the second opening 54, and covers the top surface of the nitride layer 42. In an embodiment, the first conductive material 61 comprises polysilicon having the first doping type. Another type of first conductive material 61 is also feasible.

As shown in FIG. 2M, the extra first conductive material 61 is removed by using a chemical mechanical polishing (CMP) process, and then an etch back process is performed. In some embodiments, CMP may not be performed, and the etch back process is directly performed.

As shown in FIG. 2N, the nitride layer 42 is stripped. The pad 7, the dielectric layer 8, and the first conductive material 61 in the first trench 51 may form the first deep trench structure 511. Because the first conductive material 61 extends from the top surface of the epitaxial layer 3 to the bottom of the first trench 51 and is in contact with the substrate 1, the first conductive material 61 can be used as a pickup structure of the substrate 1 to electrically connect the substrate 1 to the top surface of the epitaxial layer 3. In addition, because the pad 7 and the dielectric layer 8 that are disposed in the first trench 51 extend from the top surface of the epitaxial layer 3 to the bottom of the trench, different component regions can be isolated to some extent, thereby enhancing isolation performance.

As shown in FIG. 2O, a plurality of component regions may be formed in the epitaxial layer 3. For purposes of illustration, a first component region 111 and a second component region 112 are shown in the epitaxial layer 3 shown in FIG. 2O. For example, the first component region 111 may be a high voltage (HV) component region of an HV component (such as an HV transistor). In an embodiment, an LDMOS transistor 140 may be formed in the first component region 111, and a plurality of isolation regions 91, such as STI regions, may be formed in the first component region 111 to isolate different doped regions in the epitaxial layer 3. The second component region 112 can be used as a low voltage (LV) or medium voltage (MV) component region. In an embodiment, a first transistor 112a and a second transistor 112b may be formed in the second component region 112, and a plurality of isolation regions 91, such as shallow trench isolation (STI) regions, may be formed in the second component region 112 to isolate the first transistor 112a from the second transistor 112b. Regarding the exemplary structures of the LDMOS transistor 140, the first transistor 112a, and the second transistor 112b, reference may be made to the foregoing description with reference to FIG. 1, and details are not described herein again.

In some embodiments, the diffusion material 81 may partially fill the third trench 53, and then the third trench 53 is further filled with a dielectric material (such as silicon oxide, undoped polysilicon, and silicon nitride) to seal the diffusion material 81. Subsequently, thermal annealing is performed on the diffusion material 81 so that the dopant of the second doping type in the diffusion material 81 is diffused into a region of the epitaxial layer 3 near the sidewall of the third trench 53 to form the first doped region 82. In addition, in this manner, the diffusion material 81 and the dielectric material may jointly form a third deep trench isolation structure 531.

At this point, according to the second embodiment of the present disclosure, the semiconductor device 100 shown in FIG. 1 is obtained by using the exemplary steps shown in FIG. 2A to FIG. 2O. In such an embodiment, the first deep trench structure 511, the second deep trench isolation structure 521, the third deep trench isolation structure 531, and the first doped region 82 are formed by using only one masking step and one deep trench etching step in the semiconductor body 11, without requiring an additional masking step and an additional thermal step. Therefore, it is highly cost-effective.

It should be understood that, in some embodiments, when the low voltage component region and the medium voltage component region are isolated, formation of the second deep trench isolation structure 521 may be omitted, and the first deep trench structure 511, the third deep trench isolation structure 531, and the first doped region 82 are formed between different component regions. To this end, in the step of performing first etching on the hard mask layer 4 by using a single soft mask layer 10, as shown in FIG. 2B, the first trench opening 510 and the third trench opening 530 that penetrate through the hard mask layer 4 are simultaneously formed in the hard mask layer 4, and the second trench opening 520 shown in FIG. 2B is not formed. And in the step of performing second etching on the semiconductor body 11 by using the hard mask layer 4, as shown in FIG. 2C, the first trench 51 aligned with the first trench opening 510 and the third trench 53 aligned with the third trench opening 530 are formed in the semiconductor body 11, but the second trench 52 aligned with the second trench opening 520 shown in FIG. 2C is not formed. In this way, in a subsequent fabricating step, for example, in the step of forming the pad 7 shown in FIG. 2I and the step of forming the dielectric layer 8 shown in FIG. 2J, no operation is performed regarding the second trench 52, and the second deep trench isolation structure 521 is not formed. In such an embodiment, except that the second trench 52 and the second deep trench isolation structure 521 are not formed, another fabricating step of the semiconductor device 100 is similar to the fabricating step of the semiconductor device 100 described with reference to FIG. 2A to FIG. 2O, and details are not described herein again.

In addition, it should be understood that in some embodiments, only isolation between component regions and electrical connection of the buried layer 2 to the surface of the epitaxial layer 3 may need to be implemented between some component regions, without requiring a pickup structure of the substrate 1. Formation of the first deep trench structure 511 may be omitted between such component regions, and the second deep trench isolation structure 521, the third deep trench isolation structure 531, and the first doped region 82 are formed between different component regions. To this end, in the step of performing first etching on the hard mask layer 4 by using a single soft mask layer 10, as shown in FIG. 2B, the second trench opening 520 and the third trench opening 530 that penetrate through the hard mask layer 4 are simultaneously formed in the hard mask layer 4, and the first trench opening 510 shown in FIG. 2B is not formed. And in the step of performing second etching on the semiconductor body 11 by using the hard mask layer 4, as shown in FIG. 2C, the second trench 52 aligned with the second trench opening 520 and the third trench 53 aligned with the third trench opening 530 are formed in the semiconductor body 11, but the first trench 51 aligned with the first trench opening 510 shown in FIG. 2C is not formed. In this way, in a subsequent fabricating step, for example, in the step of forming the pad 7 shown in FIG. 2I and the step of forming the dielectric layer 8 shown in FIG. 2J, no operation is performed regarding the first trench 51. In addition, subsequent steps of fabricating the first trench 51 and the first deep trench structure 511 may also be omitted. For example, the following steps may be omitted: the step of extending the second opening 54 to the pad 7 at the bottom of the first trench 51, and forming the first opening 71 aligned with the second opening 54 in the pad 7 at the bottom of the first trench 51 in FIG. 2K; the step (if any) of forming the second doped region 9 in FIG. 2K; the step of forming the first conductive material 61 in FIG. 2L; and the step of removing the first conductive material 61 in FIG. 2M. In such an embodiment, except that the first trench 51 and the first deep trench structure 511 are not formed, another fabricating step of the semiconductor device 100 is similar to the fabricating step of the semiconductor device 100 described with reference to FIG. 2A to FIG. 2O, and details are not described herein again.

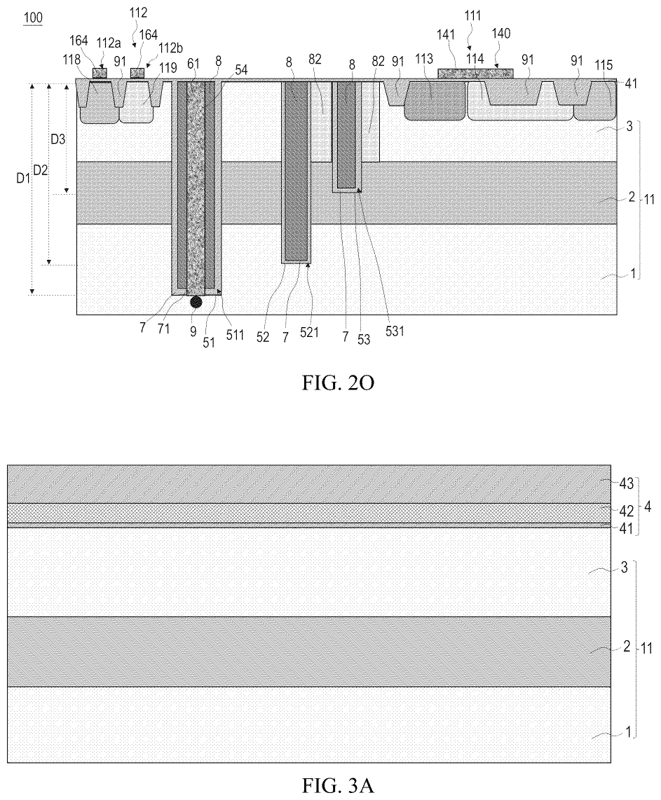

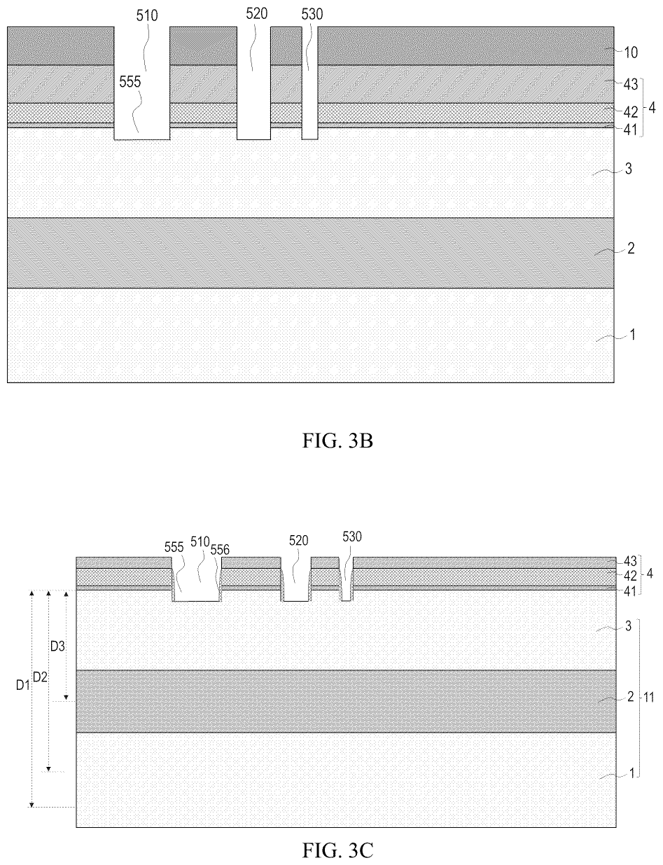

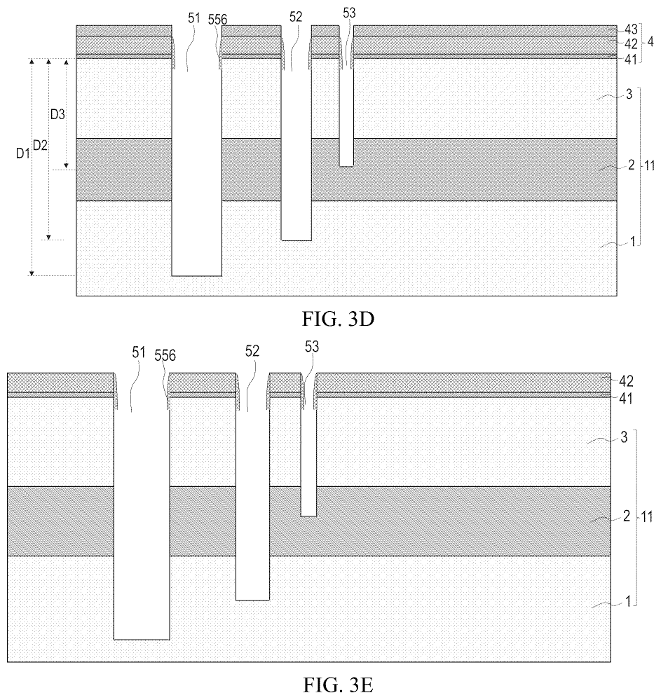

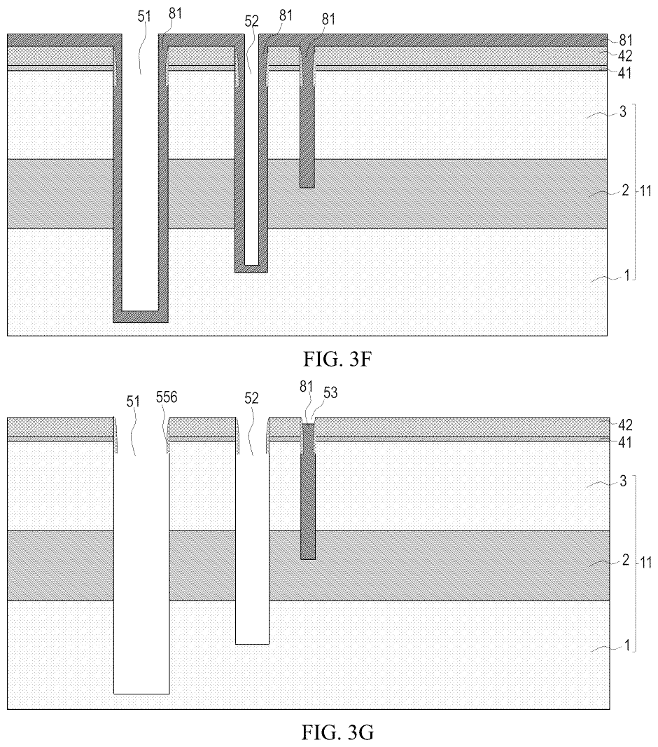

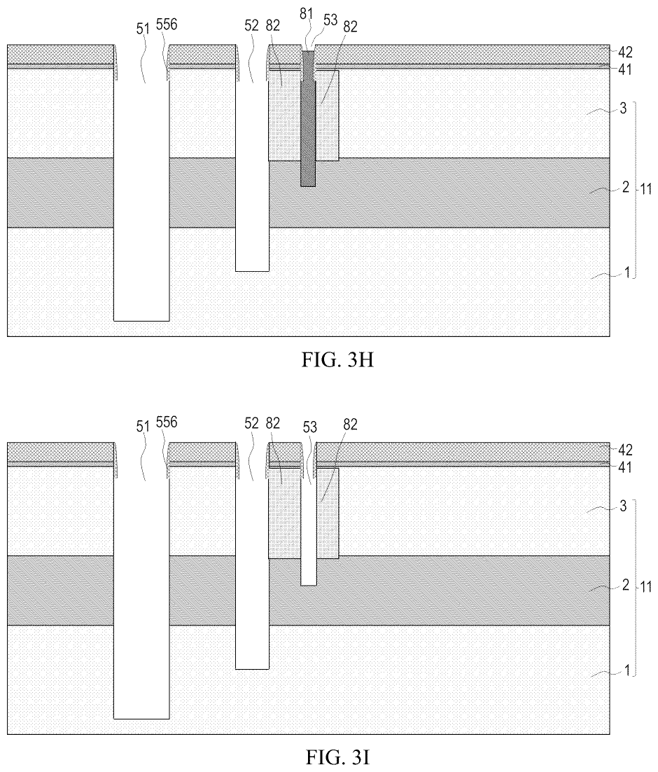

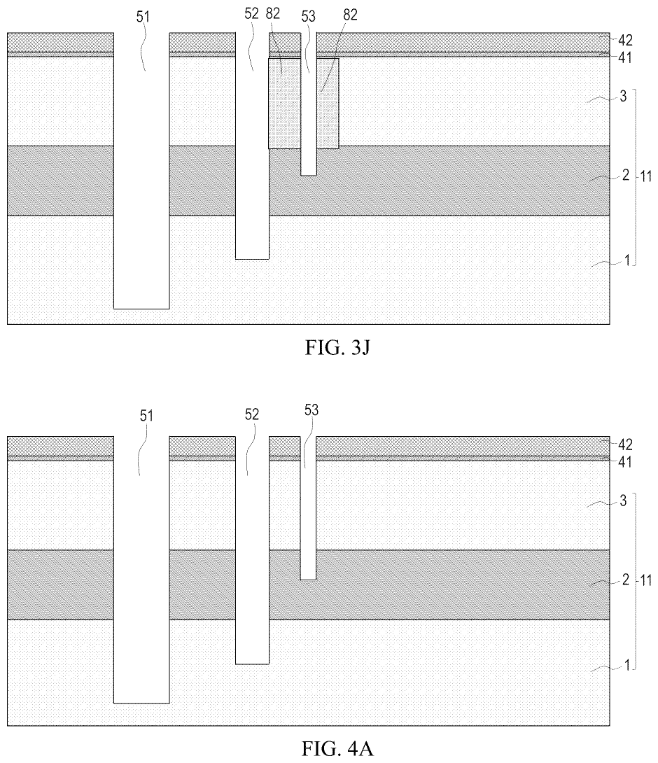

FIG. 3A to FIG. 3J show a process for fabricating a semiconductor device 100 according to a third embodiment of the present disclosure.

As shown in FIG. 3A, a semiconductor body 11 is provided. The semiconductor body 11 comprises a substrate 1, a buried layer 2 disposed on the substrate 1, and an epitaxial layer 3 disposed on the buried layer 2. In addition, as shown in FIG. 3A, a hard mask layer 4 is formed on a top surface of the epitaxial layer 3. The hard mask layer 4 comprises a first oxide layer 41, a nitride layer 42 on the first oxide layer 41, and a second oxide layer 43 on the nitride layer 42. A process shown in FIG. 3A is similar to the process shown in FIG. 2A, and details are not described herein again.

As shown in FIG. 3B, first etching is performed on the hard mask layer 4 and the epitaxial layer 3 by using the single soft mask layer 10 to simultaneously form, in the hard mask layer 4, a first trench opening 510, a second trench opening 520, and a third trench opening 530 that penetrate through the hard mask layer 4, and to form, in the epitaxial layer 3, a first shallow trench 555 aligned with each of the first trench opening 510, the second trench opening 520, and the third trench opening 530.

As shown in FIG. 3C, the single soft mask layer 10 is stripped from a top surface of the hard mask layer 4. It should be understood that in some embodiments, the single soft mask layer 10 may be removed after a first trench 51, a second trench 52, and a third trench 53 are formed. Subsequently, a thin protective layer is deposited in the first trench opening 510, the second trench opening 520, the third trench opening 530, and the first shallow trench 555, and anisotropic etching is performed on the thin protective layer to form a sidewall spacer 556 on the sidewall of each of the first trench opening 510, the second trench opening 520, the third trench opening 530, and the first shallow trench 555. In an embodiment, the thin protective layer is, for example, a thin nitride layer. A thin protective layer comprising another protective material is also feasible.

As shown in FIG. 3D, second etching is performed on the semiconductor body 11 by using the hard mask layer 4 to form, in the semiconductor body 11, the first trench 51 corresponding to the first trench opening 510, the second trench 52 corresponding to the second trench opening 520, and the third trench 53 corresponding to the third trench opening 530. A process shown in FIG. 3D is similar to the process shown in FIG. 2C, and details are not described herein again. It should be understood that, due to existence of the sidewall spacer 556, when second etching is performed on the semiconductor body 11, a portion, exactly under the sidewall spacer 556, of the semiconductor body 11 is not etched, so that a width of the formed portion, formed through the second etching, of each of the first trench 51, the second trench 52, and the third trench 53 is slightly less than a width of each of the corresponding first trench opening 510, the corresponding second trench opening 520, and the corresponding third trench opening 530. However, because a thickness of the sidewall spacer 556 in the lateral direction is small, the first trench 51, the second trench 52, and the third trench 53 are still substantially aligned with the corresponding first trench opening 510, the corresponding second trench opening 520, and the corresponding third trench opening 530. In some embodiments, ion implantation may be performed at the bottom of the first trench 51 and/or the second trench 52 to form, in the substrate 1, respective doped regions near the bottom of the first trench 51 and/or the second trench 52. The doped region has the first doping type and has a doping concentration higher than that of the substrate 1. Forming a doped region under the second trench 52 can reduce a gain of a lateral parasitic transistor (a concentration of a base region increases), thereby suppressing lateral leakage.

As shown in FIG. 3E, the second oxide layer 43 is removed. It should be understood that the step of removing the second oxide layer 43 is optional. In another embodiment, a subsequent step may be performed without removing the second oxide layer 43.

As shown in FIG. 3F, a diffusion material 81 of a proper thickness is deposited so that the diffusion material 81 completely fills the third trench 53, whereas the first trench 51 and the second trench 52 are only partially filled. A process shown in FIG. 3F is similar to the process shown in FIG. 2E, and details are not described herein again.

As shown in FIG. 3G, isotropic etching (for example, wet etching) is performed on the diffusion material 81 to remove the diffusion material 81 in the first trench 51 and the second trench 52, and only the diffusion material 81 in the third trench 53 is retained. In the process of etching the diffusion material 81, the sidewall spacer 556 may protect the first oxide layer 41 against etching. In addition, a process shown in FIG. 3G is similar to the process shown in FIG. 2F, and details are not described herein again. In some embodiments, ion implantation may be performed at the bottoms of the first trench 51 and the second trench 52 to form, in the substrate 1, respective doped regions near the bottoms of the first trench 51 and the second trench 52. The doped region has the first doping type and has a doping concentration higher than that of the substrate 1. Forming a doped region under the second trench 52 can reduce a gain of a lateral parasitic transistor (a concentration of a base region increases), thereby suppressing lateral leakage.

As shown in FIG. 3H, thermal annealing is performed on the diffusion material 81 so that the dopant of the second doping type in the diffusion material 81 is diffused into a region of the epitaxial layer 3 near the sidewall of the third trench 53 to form the first doped region 82. A process shown in FIG. 3H is similar to the process shown in FIG. 2G, and details are not described herein again.

As shown in FIG. 3I, isotropic etching is performed on the diffusion material 81 in the third trench 53 to completely remove the diffusion material 81 from the third trench 53. In the process of etching the diffusion material 81, the sidewall spacer 556 may protect the first oxide layer 41 against etching. In addition, a process shown in FIG. 3I is similar to the process shown in FIG. 2H, and details are not described herein again.

As shown in FIG. 3J, the sidewall spacer 556 is removed from the trench sidewall through isotropic etching. At this point, a structure similar to the structure shown in FIG. 2H is obtained, and a difference lies only in that a width of the portion, formed through the second etching, of each of the first trench 51, the second trench 52, and the third trench 53 is slightly less than a width of each of the corresponding first trench opening 510, the corresponding second trench opening 520, and the corresponding third trench opening 530, as described with reference to FIG. 3D. Subsequently, the semiconductor device 100 may be formed in a manner similar to the manner described with reference to FIG. 2I to FIG. 2O, and details are not described herein again.

It should be understood that, in some embodiments, when the low voltage component region and the medium voltage component region are isolated, formation of the second deep trench isolation structure 521 may be omitted, and the first deep trench structure 511, the third deep trench isolation structure 531, and the first doped region 82 are formed between different component regions. To this end, in the step of performing first etching on the hard mask layer 4 by using a single soft mask layer 10, as shown in FIG. 3B, the first trench opening 510 and the third trench opening 530 that penetrate through the hard mask layer 4 are simultaneously formed in the hard mask layer 4, and the second trench opening 520 shown in FIG. 3B is not formed, and the first shallow trench 555 aligned with the second trench opening 520 is not formed in the epitaxial layer 3 neither. In this way, in the step of forming the sidewall spacer 556 shown in FIG. 3C, there is no formation of the sidewall spacer 556 in the second trench opening 520 and the first shallow trench 555 aligned with the second trench opening 520. And in the step of performing second etching on the semiconductor body 11 by using the hard mask layer 4, as shown in FIG. 3D, the first trench 51 aligned with the first trench opening 510 and the third trench 53 aligned with the third trench opening 530 are formed in the semiconductor body 11, but the second trench 52 aligned with the second trench opening 520 shown in FIG. 3D is not formed. In such an embodiment, except that the second trench 52 and the second deep trench isolation structure 521 are not formed, another fabricating step of the semiconductor device 100 is similar to the fabricating step of the semiconductor device 100 described with reference to FIG. 3A to FIG. 3J, and details are not described herein again.

In addition, it should be understood that in some embodiments, only isolation between component regions and electrical connection of the buried layer 2 to the surface of the epitaxial layer 3 may need to be implemented between some component regions, without requiring a pickup structure of the substrate 1. Formation of the first deep trench structure 511 may be omitted between such component regions, and the second deep trench isolation structure 521, the third deep trench isolation structure 531, and the first doped region 82 are formed between different component regions. To this end, in the step of performing first etching on the hard mask layer 4 by using a single soft mask layer 10, as shown in FIG. 3B, the second trench opening 520 and the third trench opening 530 that penetrate through the hard mask layer 4 are simultaneously formed in the hard mask layer 4, and the first trench opening 510 shown in FIG. 3B is not formed. In this way, in the step of forming the sidewall spacer 556 shown in FIG. 3C, there is no formation of the sidewall spacer 556 in the first trench opening 510 and the first shallow trench 555 aligned with the first trench opening 510. And in the step of performing second etching on the semiconductor body 11 by using the hard mask layer 4, as shown in FIG. 3D, the second trench 52 aligned with the second trench opening 520 and the third trench 53 aligned with the third trench opening 530 are formed in the semiconductor body 11, but the first trench 51 aligned with the first trench opening 510 shown in FIG. 3D is not formed. In such an embodiment, except that the first trench 51 and the first deep trench structure 511 are not formed, another fabricating step of the semiconductor device 100 is similar to the fabricating step of the semiconductor device 100 described with reference to FIG. 3A to FIG. 3J, and details are not described herein again.

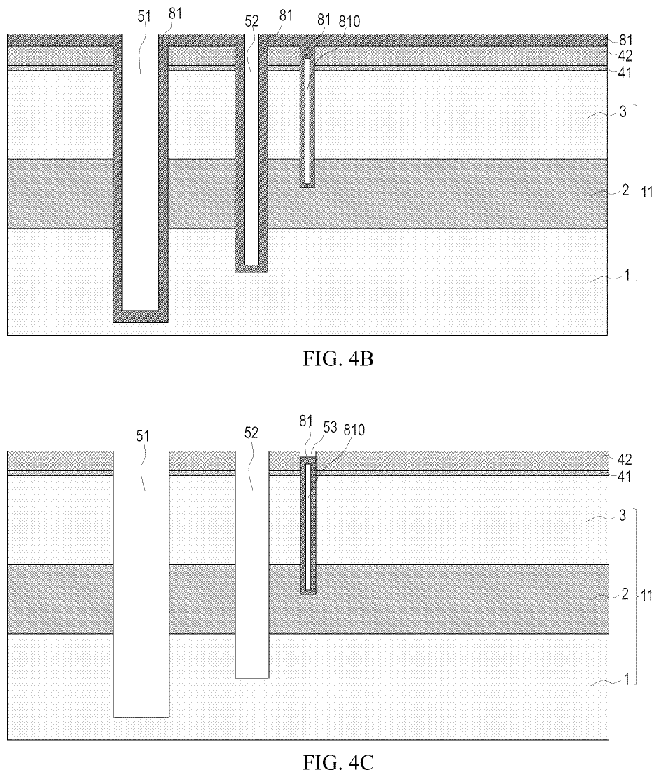

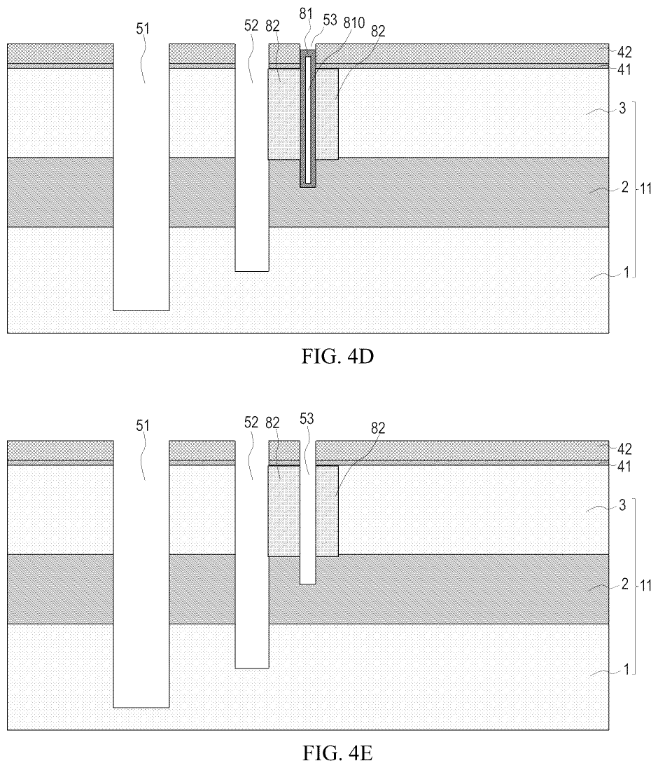

FIG. 4A to FIG. 4E show a process for fabricating a semiconductor device 100 according to a fourth embodiment of the present disclosure. The process for fabricating the semiconductor device 100 according to the fourth embodiment of the present disclosure is similar to the process for fabricating the semiconductor device 100 according to the second embodiment of the present disclosure described with reference to FIG. 2A to FIG. 2O. Only a difference between the two processes is described herein, and a same or similar part is not described again.

A structure shown in FIG. 4A is the same as a structure shown in FIG. 2D, and a first trench 51, a second trench 52, and a third trench 53 have been formed. The structure shown in FIG. 4A may be obtained in a manner described with reference to FIG. 2A to FIG. 2D, and details are not described herein again.

As shown in FIG. 4B, a diffusion material 81 of a proper thickness is deposited so that the diffusion material 81 partially fills the first trench 51, the second trench 52, and the third trench 53. As described above, in the deposition process shown in FIG. 2E, the third trench 53 is completely filled with the diffusion material 81. In the deposition process shown in FIG. 4B, the third trench 53 is partially filled with the diffusion material 81. Partially filling the third trench 53 with the diffusion material 81 makes the deposition process easier to control. In an embodiment, an air gap 810 may be formed in the third trench 53. In addition, a process shown in FIG. 4B is similar to the process shown in FIG. 2E, and details are not described herein again.

As shown in FIG. 4C, isotropic etching (for example, wet etching) is performed on the diffusion material 81 to remove the diffusion material 81 in the first trench 51 and the second trench 52, and only the diffusion material 81 in the third trench 53 is retained. A process shown in FIG. 4C is similar to the process shown in FIG. 2F, and details are not described herein again.

As shown in FIG. 4D, thermal annealing is performed on the diffusion material 81 so that the dopant of the second doping type in the diffusion material 81 is diffused into a region of the epitaxial layer 3 near the sidewall of the third trench 53 to form the first doped region 82. A process shown in FIG. 4D is similar to the process shown in FIG. 2G, and details are not described herein again.

As shown in FIG. 4E, isotropic etching is performed on the diffusion material 81 in the third trench 53 to completely remove the diffusion material 81 from the third trench 53. A process shown in FIG. 4E is similar to the process shown in FIG. 2H, and details are not described herein again. At this point, a structure similar to the structure shown in FIG. 2H is obtained. Subsequently, the semiconductor device 100 may be formed in a manner similar to the manner described with reference to FIG. 2I to FIG. 2O, and details are not described herein again.

It should be understood that, in some embodiments, when the low voltage component region and the medium voltage component region are isolated, formation of the second deep trench isolation structure 521 may be omitted, and the first deep trench structure 511, the third deep trench isolation structure 531, and the first doped region 82 are formed between different component regions. In such an embodiment, except that the second trench 52 and the second deep trench isolation structure 521 are not formed, another fabricating step of the semiconductor device 100 is similar to the fabricating step of the semiconductor device 100 described with reference to FIG. 4A to FIG. 4E, and details are not described herein again.

In addition, it should be understood that in some embodiments, only isolation between component regions and electrical connection of the buried layer 2 to the surface of the epitaxial layer 3 may need to be implemented between some component regions, without requiring a pickup structure of the substrate 1. Formation of the first deep trench structure 511 may be omitted between such component regions, and the second deep trench isolation structure 521, the third deep trench isolation structure 531, and the first doped region 82 are formed between different component regions. In such an embodiment, except that the first trench 51 and the first deep trench structure 511 are not formed, another fabricating step of the semiconductor device 100 is similar to the fabricating step of the semiconductor device 100 described with reference to FIG. 4A to FIG. 4E, and details are not described herein again.

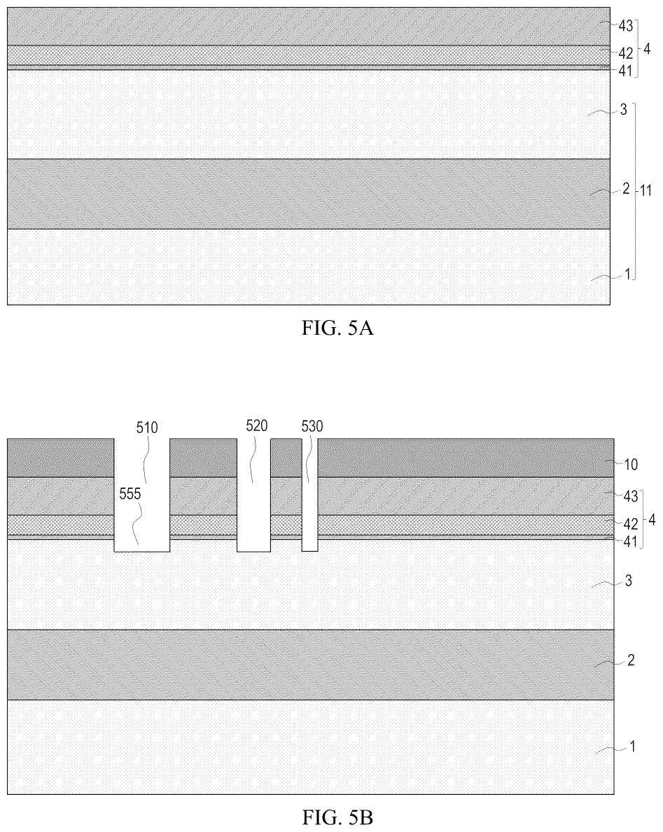

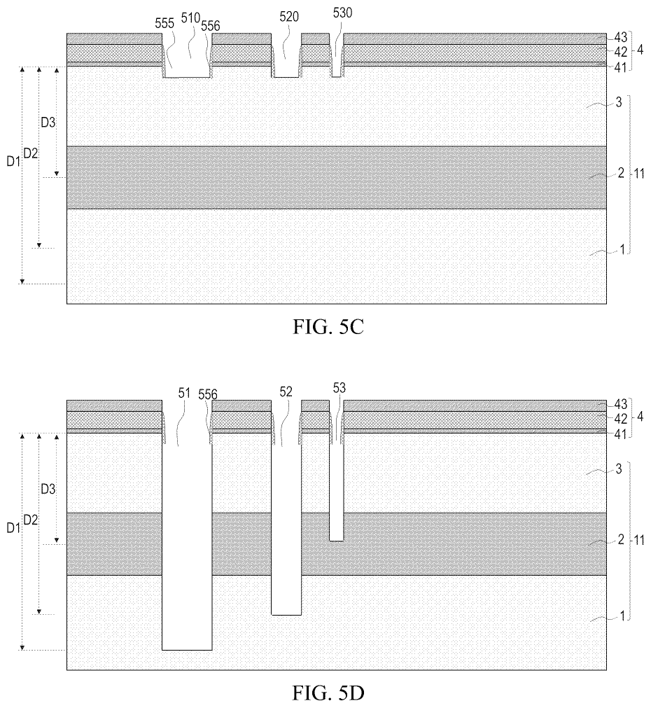

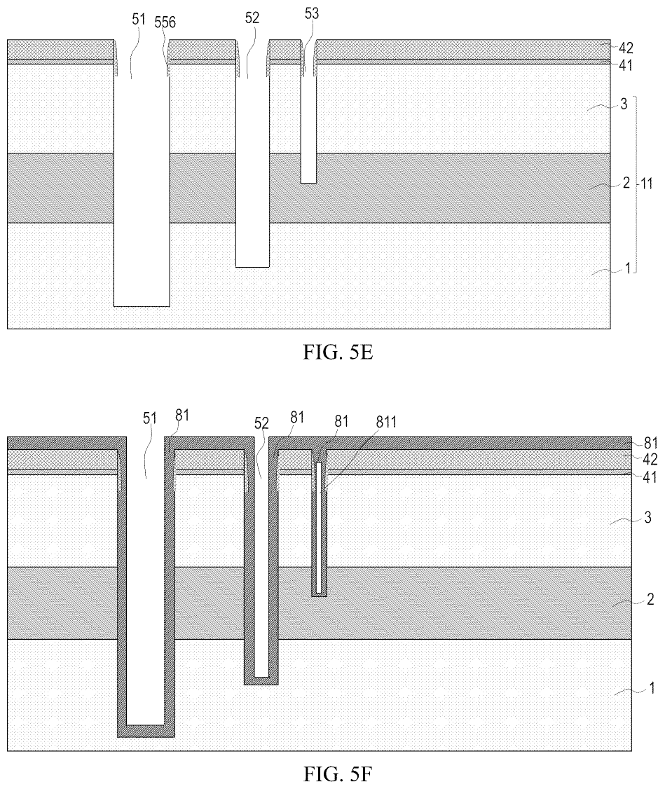

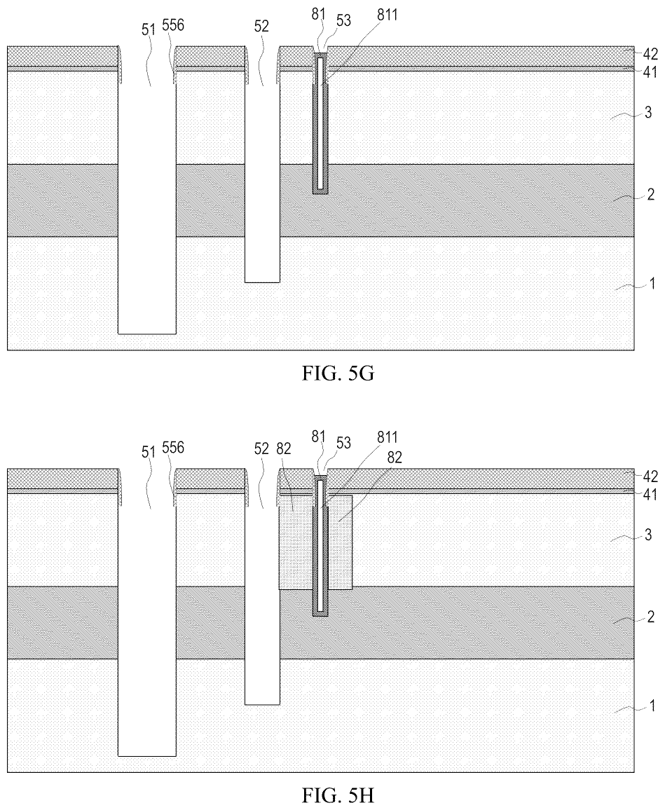

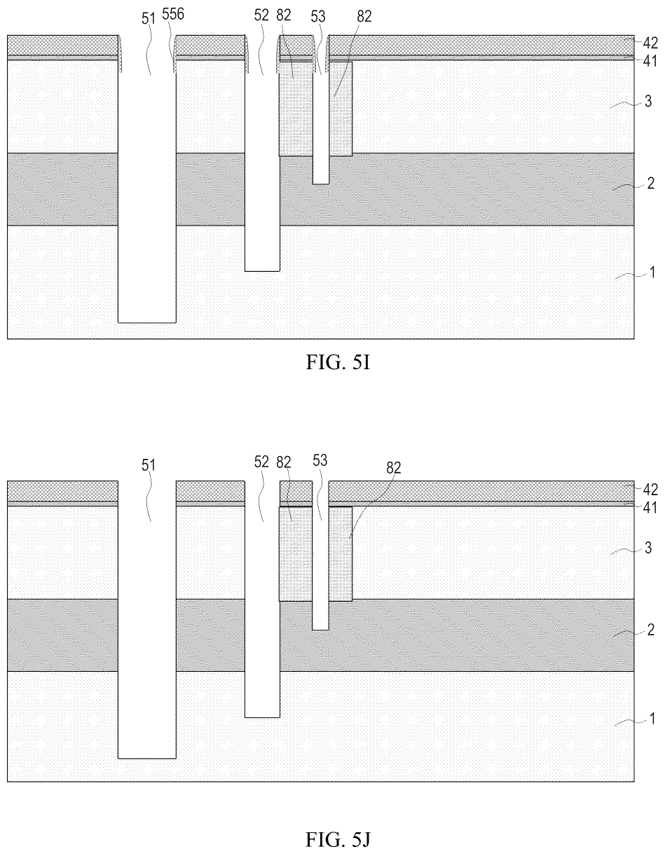

FIG. 5A to FIG. 5J show a process for fabricating a semiconductor device 100 according to a fifth embodiment of the present disclosure.

As shown in FIG. 5A, a semiconductor body 11 is provided. The semiconductor body 11 comprises a substrate 1, a buried layer 2 disposed on the substrate 1, and an epitaxial layer 3 disposed on the buried layer 2. In addition, as shown in FIG. 3A, a hard mask layer 4 is formed on a top surface of the epitaxial layer 3. The hard mask layer 4 comprises a first oxide layer 41, a nitride layer 42 on the first oxide layer 41, and a second oxide layer 43 on the nitride layer 42. A process shown in FIG. 5A is similar to the process shown in FIG. 3A, and details are not described herein again.

As shown in FIG. 5B, first etching is performed on the hard mask layer 4 and the epitaxial layer 3 by using the single soft mask layer 10 to simultaneously form, in the hard mask layer 4, a first trench opening 510, a second trench opening 520, and a third trench opening 530 that penetrate through the hard mask layer 4, and to form, in the epitaxial layer 3, a first shallow trench 555 aligned with each of the first trench opening 510, the second trench opening 520, and the third trench opening 530. A process shown in FIG. 5B is similar to the process shown in FIG. 3B, and details are not described herein again.

As shown in FIG. 5C, the single soft mask layer 10 is stripped from a top surface of the hard mask layer 4. It should be understood that in some embodiments, the single soft mask layer 10 may be removed after a first trench 51, a second trench 52, and a third trench 53 are formed. Subsequently, a thin protective layer is deposited in the first trench opening 510, the second trench opening 520, the third trench opening 530, and the first shallow trench 555, and anisotropic etching is performed on the thin protective layer to form a sidewall spacer 556 on the sidewall of each of the first trench opening 510, the second trench opening 520, the third trench opening 530, and the first shallow trench 555. In an embodiment, the thin protective layer is, for example, a thin nitride layer. A thin protective layer comprising another protective material is also feasible. A process shown in FIG. 5C is similar to the process shown in FIG. 3C, and details are not described herein again.

As shown in FIG. 5D, second etching is performed on the semiconductor body 11 by using the hard mask layer 4 to form, in the semiconductor body 11, the first trench 51 corresponding to the first trench opening 510, the second trench 52 corresponding to the second trench opening 520, and the third trench 53 corresponding to the third trench opening 530. A process shown in FIG. 5D is similar to the process shown in FIG. 3D, and details are not described herein again. It should be understood that, due to existence of the sidewall spacer 556, when second etching is performed on the semiconductor body 11, a portion, exactly under the sidewall spacer 556, of the semiconductor body 11 is not etched, so that a width of the formed portion, formed through the second etching, of each of the first trench 51, the second trench 52, and the third trench 53 is slightly less than a width of each of the corresponding first trench opening 510, the corresponding second trench opening 520, and the corresponding third trench opening 530. However, because a thickness of the sidewall spacer 556 in the lateral direction is small, the first trench 51, the second trench 52, and the third trench 53 are still substantially aligned with the corresponding first trench opening 510, the corresponding second trench opening 520, and the corresponding third trench opening 530. In some embodiments, ion implantation may be performed at the bottom of the first trench 51 and/or the second trench 52 to form, in the substrate 1, respective doped regions near the bottom of the first trench 51 and/or the second trench 52. The doped region has the first doping type and has a doping concentration higher than that of the substrate 1. Forming a doped region under the second trench 52 can reduce a gain of a lateral parasitic transistor (a concentration of a base region increases), thereby suppressing lateral leakage.

As shown in FIG. 5E, the second oxide layer 43 is removed. It should be understood that the step of removing the second oxide layer 43 is optional. In another embodiment, a subsequent step may be performed without removing the second oxide layer 43. A process shown in FIG. 5E is similar to the process shown in FIG. 3E, and details are not described herein again.

As shown in FIG. 5F, a diffusion material 81 of a proper thickness is deposited so that the diffusion material 81 partially fills the first trench 51, the second trench 52, and the third trench 53. Partially filling the third trench 53 with the diffusion material 81 makes the deposition process easier to control. In an embodiment, an air gap 810 may be formed in the third trench 53. A process shown in FIG. 5F is similar to the process shown in FIG. 4B, and details are not described herein again.

As shown in FIG. 5G, isotropic etching (for example, wet etching) is performed on the diffusion material 81 to remove the diffusion material 81 in the first trench 51 and the second trench 52, and only the diffusion material 81 in the third trench 53 is retained. In the process of etching the diffusion material 81, the sidewall spacer 556 may protect the first oxide layer 41 against etching. A process shown in FIG. 5G is similar to the process shown in FIG. 4C, and details are not described herein again.

As shown in FIG. 5H, thermal annealing is performed on the diffusion material 81 so that the dopant of the second doping type in the diffusion material 81 is diffused into a region of the epitaxial layer 3 near the sidewall of the third trench 53 to form the first doped region 82. A process shown in FIG. 5H is similar to the process shown in FIG. 4D, and details are not described herein again.

As shown in FIG. 5I, isotropic etching is performed on the diffusion material 81 in the third trench 53 to completely remove the diffusion material 81 from the third trench 53. In the process of etching the diffusion material 81, the sidewall spacer 556 may protect the first oxide layer 41 against etching. A process shown in FIG. 5I is similar to the process shown in FIG. 4E, and details are not described herein again.

As shown in FIG. 5J, the sidewall spacer 556 is removed from the trench sidewall through isotropic etching. At this point, a structure similar to the structure shown in FIG. 2H is obtained, and a difference lies only in that a width of the portion, formed through the second etching, of each of the first trench 51, the second trench 52, and the third trench 53 is slightly less than a width of each of the corresponding first trench opening 510, the corresponding second trench opening 520, and the corresponding third trench opening 530, as described with reference to FIG. 5D. Subsequently, the semiconductor device 100 may be formed in a manner similar to the manner described with reference to FIG. 2I to FIG. 2O, and details are not described herein again.

It should be understood that, in some embodiments, when the low voltage component region and the medium voltage component region are isolated, formation of the second deep trench isolation structure 521 may be omitted, and the first deep trench structure 511, the third deep trench isolation structure 531, and the first doped region 82 are formed between different component regions. To this end, in the step of performing first etching on the hard mask layer 4 by using a single soft mask layer 10, as shown in FIG. 5B, the first trench opening 510 and the third trench opening 530 that penetrate through the hard mask layer 4 are simultaneously formed in the hard mask layer 4, and the second trench opening 520 shown in FIG. 5B is not formed neither. In this way, in the step of forming the sidewall spacer 556 shown in FIG. 5C, there is no formation of the sidewall spacer 556 in the second trench opening 520 and the first shallow trench 555 aligned with the second trench opening 520. And in the step of performing second etching on the semiconductor body 11 by using the hard mask layer 4, as shown in FIG. 5D, the first trench 51 aligned with the first trench opening 510 and the third trench 53 aligned with the third trench opening 530 are formed in the semiconductor body 11, but the second trench 52 aligned with the second trench opening 520 shown in FIG. 5D is not formed. In this way, in a subsequent fabricating step, for example, in a step of depositing the diffusion material 81 shown in FIG. 5F and a step of removing the diffusion material 81 shown in FIG. 5G, no operation is performed regarding the second trench 52. In such an embodiment, except that the second trench 52 and the second deep trench isolation structure 521 are not formed, another fabricating step of the semiconductor device 100 is similar to the fabricating step of the semiconductor device 100 described with reference to FIG. 5A to FIG. 5J, and details are not described herein again.

In addition, it should be understood that in some embodiments, only isolation between component regions and electrical connection of the buried layer 2 to the surface of the epitaxial layer 3 may need to be implemented between some component regions, without requiring a pickup structure of the substrate 1. Formation of the first deep trench structure 511 may be omitted between such component regions, and the second deep trench isolation structure 521, the third deep trench isolation structure 531, and the first doped region 82 are formed between different component regions. To this end, in the step of performing first etching on the hard mask layer 4 by using a single soft mask layer 10, as shown in FIG. 5B, the second trench opening 520 and the third trench opening 530 that penetrate through the hard mask layer 4 are simultaneously formed in the hard mask layer 4, and the first trench opening 510 shown in FIG. 5B is not formed. In this way, in the step of forming the sidewall spacer 556 shown in FIG. 5C, there is no formation of the sidewall spacer 556 in the first trench opening 510 and the first shallow trench 555 aligned with the first trench opening 510. And in the step of performing second etching on the semiconductor body 11 by using the hard mask layer 4, as shown in FIG. 5D, the second trench 52 aligned with the second trench opening 520 and the third trench 53 aligned with the third trench opening 530 are formed in the semiconductor body 11, but the first trench 51 aligned with the first trench opening 510 shown in FIG. 5D is not formed. In this way, in a subsequent fabricating step, for example, in a step of depositing the diffusion material 81 shown in FIG. 5F and a step of removing the diffusion material 81 shown in FIG. 5G, no operation is performed regarding the first trench 51. In such an embodiment, except that the first trench 51 and the first deep trench structure 511 are not formed, another fabricating step of the semiconductor device 100 is similar to the fabricating step of the semiconductor device 100 described with reference to FIG. 5A to FIG. 5J, and details are not described herein again.

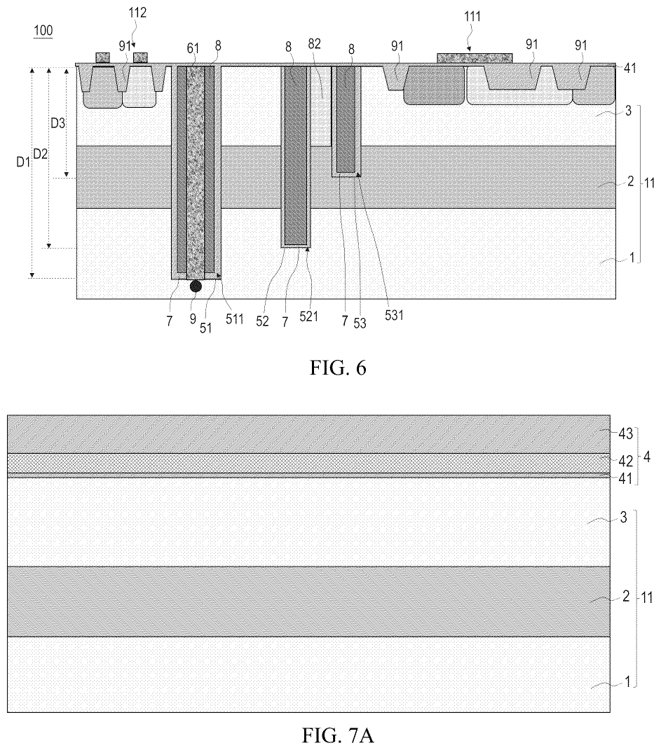

FIG. 6 illustratively shows a cross-sectional view of a semiconductor device 100 according to a sixth embodiment of the present disclosure. The semiconductor device 100 shown in FIG. 6 has a similar structure to the semiconductor device 100 shown in FIG. 1, and a difference lies in that the first doped region 82 is disposed only near one side of the third trench 53, not both sides of the third trench 53. In an embodiment, the first doped region 82 is formed between the second trench 52 and the third trench 53. Compared with the semiconductor device 100 shown in FIG. 1, removing the first doped region 82 on the other side of the third trench 53 and disposing the first doped region 82 only between the second trench 52 and the third trench 53 ensure that a structure of the device is more compact, thereby reducing an area of the device. In another embodiment, the first doped region 82 may be formed between any two of the first trench 51, the second trench 52, and the third trench 53. In addition, the third deep trench isolation structure 531 may also provide good lateral high voltage isolation performance, thereby reducing a component area to a great extent for components such as the LDMOS and the DEMOS. Another structure of the semiconductor device 100 shown in FIG. 6 is similar to a structure of the semiconductor device 100 shown in FIG. 1, and details are not described herein again.

It should be understood that, in some embodiments, when the low voltage component region and the medium voltage component region are isolated, the second deep trench isolation structure 521 may be omitted, and the first deep trench structure 511, the third deep trench isolation structure 531, and the first doped region 82 are disposed between different component regions. In such an embodiment, except that the second trench 52 and the second deep trench isolation structure 521 are not comprised, another structure of the semiconductor device 100 is similar to that of the semiconductor device 100 described with reference to FIG. 6, and details are not described herein again.

In addition, it should be understood that in some embodiments, only isolation between component regions and electrical connection of the buried layer 2 to the surface of the epitaxial layer 3 may need to be implemented between some component regions, without requiring a pickup structure of the substrate 1. The first deep trench structure 511 may be omitted between such component regions, and the second deep trench isolation structure 521, the third deep trench isolation structure 531, and the first doped region 82 are disposed between different component regions. In such an embodiment, except that the first trench 51 and the first deep trench structure 511 are not comprised, another structure of the semiconductor device 100 is similar to that of the semiconductor device 100 described with reference to FIG. 6, and details are not described herein again.

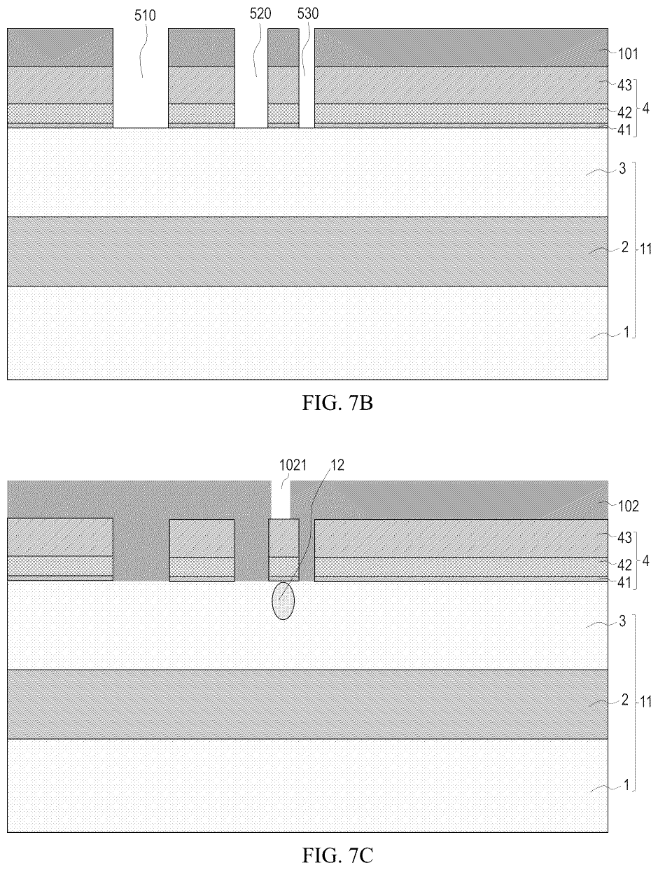

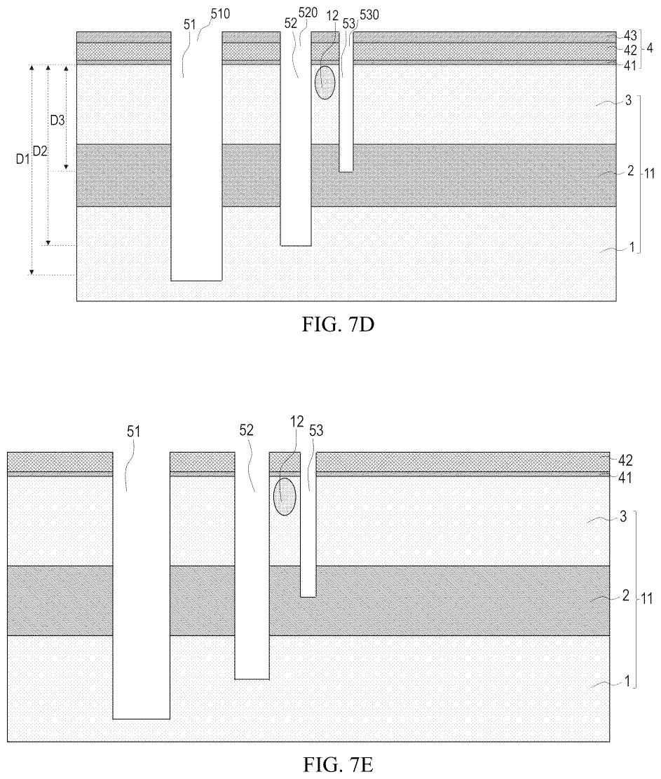

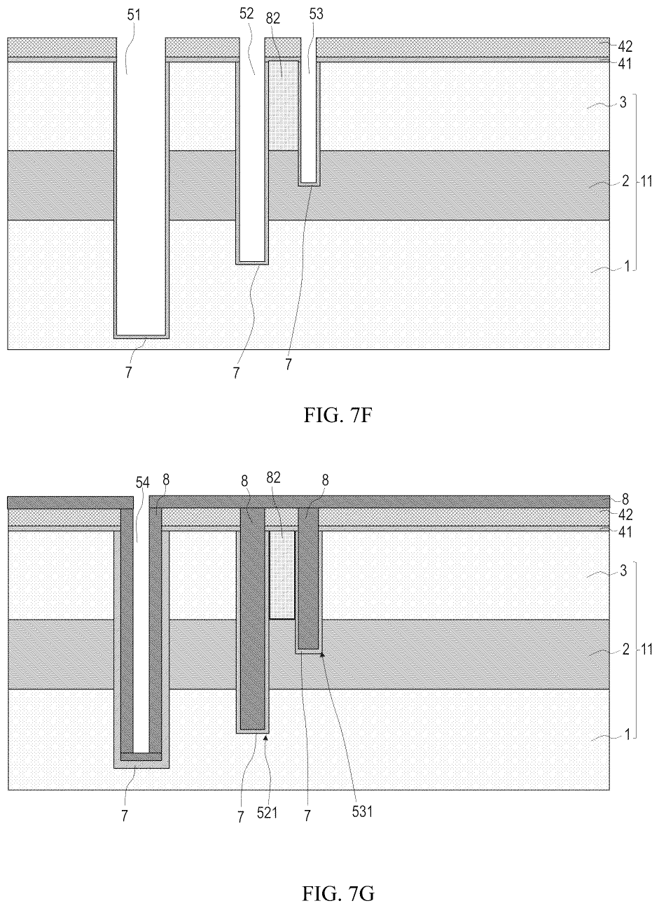

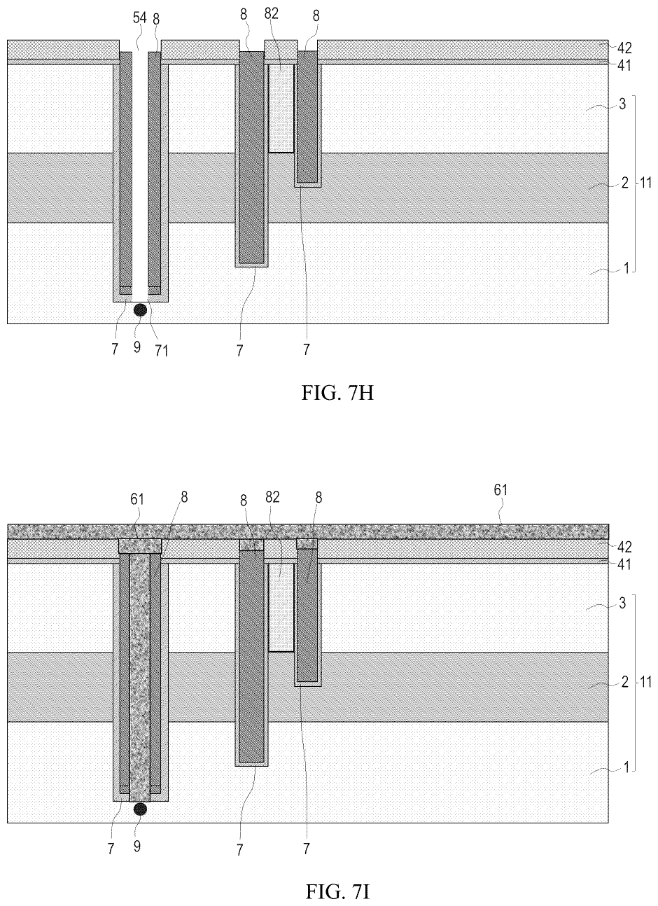

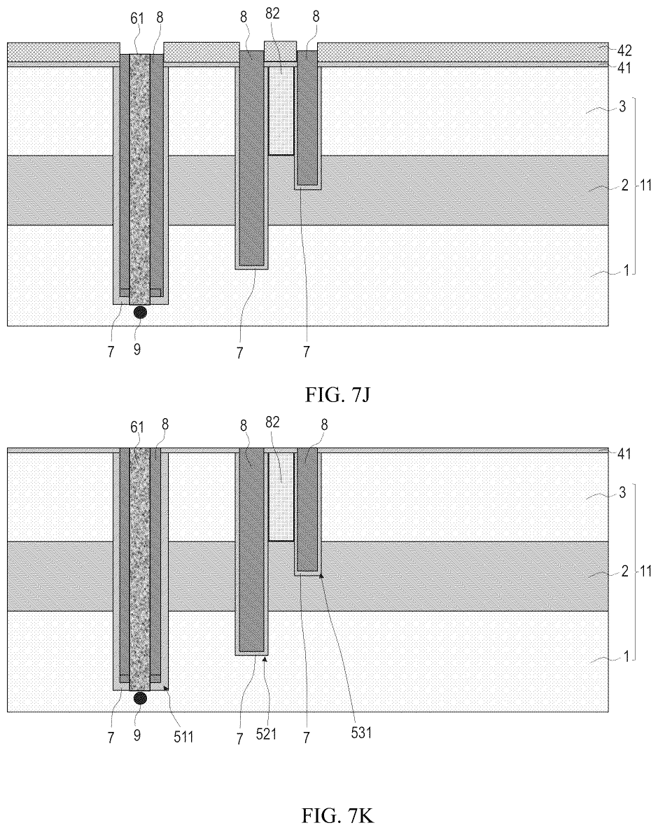

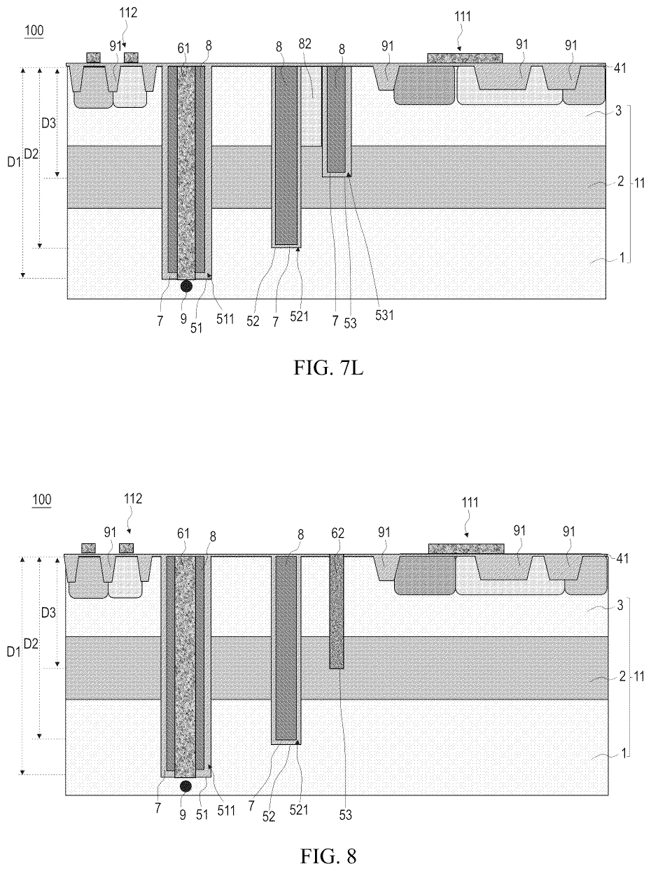

FIG. 7A to FIG. 7L show a process for fabricating a semiconductor device according to a seventh embodiment of the present disclosure. The process shown in FIG. 7A to FIG. 7L may be used to fabricate the semiconductor device 100 shown in FIG. 6. The foregoing description of the semiconductor device 100 with reference to FIG. 6 may be combined herein.

As shown in FIG. 7A, a semiconductor body 11 is provided. The semiconductor body 11 comprises a substrate 1, a buried layer 2 disposed on the substrate 1, and an epitaxial layer 3 disposed on the buried layer 2. The buried layer 2 may be formed on the substrate 1 through epitaxial growth. The epitaxial layer 3 may be formed on the buried layer 2 through epitaxial growth. The substrate 1 has a first doping type. The buried layer 2 has a second doping type opposite to the first doping type. For example, when the first doping type is a p-type, the second doping type is an n-type. Similarly, when the first doping type is an n-type, the second doping type is a p-type. In an embodiment, the buried layer 2 may have a blanket structure, which has substantially the same horizontal extension as the substrate 1 and is laid flatly on the substrate 1. In another embodiment, the buried layer 2 may have a patterned structure. This is not strictly limited in the embodiments of the present disclosure. The epitaxial layer 3 may be used to form different component regions.

In addition, as shown in FIG. 7A, a hard mask layer 4 is formed on a top surface of the epitaxial layer 3. Forming the hard mask layer 4 may comprise: growing a first oxide layer 41 on the top surface of the epitaxial layer 3; depositing a nitride layer 42 on the first oxide layer 41; and depositing a second oxide layer 43 on the nitride layer 42. In another embodiment, the hard mask layer 4 may have another structure. This is not strictly limited in the embodiments of the present disclosure.

As shown in FIG. 7B, first etching is performed on the hard mask layer 4 by using a first soft mask layer 101 to simultaneously form, in the hard mask layer 4, a first trench opening 510, a second trench opening 520, and a third trench opening 530 that penetrate through the hard mask layer 4. In an embodiment, a width of the first trench opening 510 is greater than a width of the second trench opening 520, and the width of the second trench opening 520 is greater than a width of the third trench opening 530.

As shown in FIG. 7C, the first soft mask layer 101 is stripped. Subsequently, a second soft mask layer 102 is formed on the hard mask layer 4, wherein the second soft mask layer 102 comprises a third opening 1021 and the third opening 1021 exposes one or more portions of the hard mask layer 4 near the third trench opening 530. Subsequently, a dopant of the second doping type is implanted into the epitaxial layer 3 via the third opening 1021 to form an implantation region 12 in the epitaxial layer. In an embodiment, when the first doping type is a p-type, the dopant is a phosphorus element, and when the first doping type is an n-type, the dopant is a boron element. Another type of dopant is also feasible.

As shown in FIG. 7D, the second soft mask layer 102 is stripped from a top surface of the hard mask layer 4. Subsequently, second etching is performed on the semiconductor body 11 by using the hard mask layer 4 to form, in the semiconductor body 11, a first trench 51 aligned with the first trench opening 510, a second trench 52 aligned with the second trench opening 520, and a third trench 53 aligned with the third trench opening 530. The first trench 51 extends from the top surface of the epitaxial layer 3 into the substrate 1 and has a first depth D1. The second trench 52 extends from the top surface of the epitaxial layer 3 into the substrate 1 and has a second depth D2. The third trench 53 extends from the top surface of the epitaxial layer 3 into the buried layer 2 and has a third depth D3. The width of the first trench opening 510 is greater than the width of the second trench opening 520, and the width of the second trench opening 520 is greater than the width of the third trench opening 530. Therefore, the first depth D1 of the first trench 51 is greater than the second depth D2 of the second trench 52, and the second depth D2 of the second trench 52 is greater than the third depth D3 of the third trench 53. In an embodiment, as shown in FIG. 7D, the implantation region 12 is located between the second trench 52 and the third trench 53. Another arrangement of the implantation region 12 is feasible.

As shown in FIG. 7E, the second oxide layer 43 is removed. It should be understood that the step of removing the second oxide layer 43 is optional. In another embodiment, a subsequent step may be performed without removing the second oxide layer 43. In some embodiments, ion implantation may be performed at the bottom of the first trench 51 and/or the second trench 52 to form, in the substrate 1, respective doped regions near the bottom of the first trench 51 and/or the second trench 52. The doped region has the first doping type and has a doping concentration higher than that of the substrate 1. Forming a doped region under the second trench 52 can reduce a gain of a lateral parasitic transistor (a concentration of a base region increases), thereby suppressing lateral leakage.

As shown in FIG. 7F, the first trench 51, the second trench 52, and the third trench 53 are lined to form a pad 7 on a sidewall and a bottom of each of the first trench 51, the second trench 52, and the third trench 53. The pad 7 can repair damage caused to the sidewall of the trench when the semiconductor body 11 is etched to form the first trench 51, the second trench 52, and the third trench 53, so as to deposit a subsequent layer thereon. In an embodiment, the pad 7 comprises oxide such as silicon oxide. Another type of pad is also feasible.

In addition, as shown in FIG. 7F, thermal annealing is performed on a dopant of the second doping type in the implantation region 12 to form a first doped region 82 in a region of the epitaxial layer 3 near a sidewall of the third trench 53, wherein the first doped region 82 extends from the top surface of the epitaxial layer 3 to the buried layer 2. Because the first doped region 82 and the buried layer 2 have the same doping type, the first doped region 82 can be used as a pickup structure of the buried layer 2, so as to connect the buried layer 2 to the top surface of the epitaxial layer 3 at low resistivity. A dopant in the buried layer 2 may be diffused upward into the epitaxial layer 3 or downward into the substrate 1 during the thermal annealing. Therefore, the buried layer 2 may have a wider extension range than that shown in FIG. 7E, for example, extends upward to a specific depth in the epitaxial layer 3 or downward to a specific depth in the substrate 1. In this case, the third trench 53 formed in the semiconductor body 11 may not extend into the buried layer 2 (certainly, extending into the buried layer 2 is still feasible), but the bottom of the third trench 53 may move upward to a position of the epitaxial layer 3 near the buried layer 2, as shown in FIG. 7F (for example, within a range of a level of several microns apart from a top surface of the buried layer 2 shown in FIG. 7F). In a thermal annealing process, the buried layer 2 extends upward and is in contact with the first doped region 82. Therefore, with such arrangement, the first doped region 82 can also electrically connect the buried layer 2 to the top surface of the epitaxial layer 3 reliably.

In addition, when the implantation region 12 is located between the second trench 52 and the third trench 53, the second trench 52 and the third trench 53 can limit lateral diffusion of a dopant in the implantation region 12, and the first doped region 82 is disposed between the second trench 52 and the third trench 53 so that a structure of the device is more compact, thereby reducing an area of the device. In another embodiment, the first doped region 82 may be formed between any two of the first trench 51, the second trench 52, and the third trench 53. In addition, because the first trench 51, the second trench 52, and the third trench 53 are not filled in this case, no great mechanical stress is generated in the semiconductor body 11 when the thermal annealing step is performed for a long time, so that device performance can be improved.

As shown in FIG. 7G, the dielectric layer 8 is deposited so that the dielectric layer 8 forms, in the first trench 51, a second opening 54 that extends from the top surface of the epitaxial layer 3 toward the bottom of the first trench 51, and the dielectric layer 8 completely fills the second trench 52 and the third trench 53. In some embodiments, the dielectric layer 8 may partially fill the second trench 52. This can reduce stress on one hand, and reduce parasitic capacitance on the other hand. For example, an air gap may be formed in the dielectric layer 8 in the second trench 52. In an embodiment, the dielectric layer 8 comprises oxide such as silicon oxide. Another type of dielectric layer is also feasible. The pad 7 and the dielectric layer 8 in the second trench 52 form the second deep trench isolation structure 521, and the pad 7 and the dielectric layer 8 in the third trench 53 form the third deep trench isolation structure 531 to isolate different component regions that are to be formed in the epitaxial layer 3 in subsequent steps.

As shown in FIG. 7H, anisotropic etching is performed on the dielectric layer 8 and the pad 7 to remove the dielectric layer 8 from a top surface of the nitride layer 42, and to extend the second opening 54 to the pad 7 at the bottom of the first trench 51, and to form a first opening 71 aligned with the second opening 54 in the pad 7 at the bottom of the first trench 51. Optionally, ion implantation may be performed on the substrate 1 through the second opening 54 and the first opening 71 to form, in the substrate 1, a second doped region 9 near the bottom of the first trench 51. The second doped region 9 has the first doping type and has a doping concentration higher than that of the substrate 1. When the doping concentration of the substrate 1 is high, the second doped region 9 may be omitted. In addition, in some embodiments, before the anisotropic etching is performed on the dielectric layer 8 and the pad 7, ion implantation may be performed in the substrate 1 near the bottom of the first trench 51 to form the second doped region 9. Forming the second doped region 9 in another process step is also feasible.

As shown in FIG. 7I, the first conductive material 61 is deposited so that the first conductive material 61 fills the first opening 71 and the second opening 54, and covers the top surface of the nitride layer 42. In an embodiment, the first conductive material 61 comprises polysilicon having the first doping type. Another type of first conductive material 61 is also feasible.

As shown in FIG. 7J, the extra first conductive material 61 is removed by using a chemical mechanical polishing (CMP) process, and then an etch back process is performed. In some embodiments, CMP may not be performed, and the etch back process is directly performed.

As shown in FIG. 7K, the nitride layer 42 is stripped. The pad 7, the dielectric layer 8, and the first conductive material 61 in the first trench 51 may form the first deep trench structure 511. Because the first conductive material 61 extends from the top surface of the epitaxial layer 3 to the bottom of the first trench 51 and is in contact with the substrate 1, the first conductive material 61 can be used as a pickup structure of the substrate 1 to electrically connect the substrate 1 to the top surface of the epitaxial layer 3. In addition, because the pad 7 and the dielectric layer 8 that are disposed in the first trench 51 extend from the top surface of the epitaxial layer 3 to the bottom of the trench, different component regions can be isolated to some extent, thereby enhancing isolation performance.

As shown in FIG. 7L, a plurality of component regions may be formed in the epitaxial layer 3. For purposes of illustration, a first component region 111 and a second component region 112 are shown in the epitaxial layer 3 shown in FIG. 7L. For example, the first component region 111 may be a high voltage (HV) component region of an HV component (such as an HV transistor). In an embodiment, an LDMOS transistor 140 may be formed in the first component region 111, and a plurality of isolation regions 91, such as STI regions, may be formed in the first component region 111 to isolate different doped regions in the epitaxial layer 3. The second component region 112 can be used as a low voltage (LV) or medium voltage (MV) component region. In an embodiment, a first transistor 112a and a second transistor 112b may be formed in the second component region 112, and a plurality of isolation regions 91, such as shallow trench isolation (STI) regions, may be formed in the second component region 112 to isolate the first transistor 112a from the second transistor 112b. Regarding the exemplary structures of the LDMOS transistor 140, the first transistor 112a, and the second transistor 112b, reference may be made to the foregoing description with reference to FIG. 1 and FIG. 6, and details are not described herein again.

It should be understood that, in some embodiments, when the low voltage component region and the medium voltage component region are isolated, formation of the second deep trench isolation structure 521 may be omitted, and the first deep trench structure 511, the third deep trench isolation structure 531, and the first doped region 82 are formed between different component regions. To this end, in the step of performing first etching on the hard mask layer 4 by using a single soft mask layer 10, as shown in FIG. 7B, the first trench opening 510 and the third trench opening 530 that penetrate through the hard mask layer 4 are simultaneously formed in the hard mask layer 4, and the second trench opening 520 shown in FIG. 7B is not formed. And in the step of performing second etching on the semiconductor body 11 by using the hard mask layer 4, as shown in FIG. 7D, the first trench 51 aligned with the first trench opening 510 and the third trench 53 aligned with the third trench opening 530 are formed in the semiconductor body 11, but the second trench 52 aligned with the second trench opening 520 shown in FIG. 7C is not formed. In this way, in a subsequent fabricating step, for example, in the step of forming the pad 7 shown in FIG. 7F and the step of forming the dielectric layer 8 shown in FIG. 7G, no operation is performed regarding the second trench 52, and the second deep trench isolation structure 521 is not formed. In such an embodiment, except that the second trench 52 and the second deep trench isolation structure 521 are not formed, another fabricating step of the semiconductor device 100 is similar to the fabricating step of the semiconductor device 100 described with reference to FIG. 7A to FIG. 7L, and details are not described herein again.

In addition, it should be understood that in some embodiments, only isolation between component regions and electrical connection of the buried layer 2 to the surface of the epitaxial layer 3 may need to be implemented between some component regions, without requiring a pickup structure of the substrate 1. Formation of the first deep trench structure 511 may be omitted between such component regions, and the second deep trench isolation structure 521, the third deep trench isolation structure 531, and the first doped region 82 are formed between different component regions. To this end, in the step of performing first etching on the hard mask layer 4 by using a single soft mask layer 10, as shown in FIG. 7B, the second trench opening 520 and the third trench opening 530 that penetrate through the hard mask layer 4 are simultaneously formed in the hard mask layer 4, and the first trench opening 510 shown in FIG. 7B is not formed. And in the step of performing second etching on the semiconductor body 11 by using the hard mask layer 4, as shown in FIG. 7D, the second trench 52 aligned with the second trench opening 520 and the third trench 53 aligned with the third trench opening 530 are formed in the semiconductor body 11, but the first trench 51 aligned with the first trench opening 510 shown in FIG. 7C is not formed. In this way, in a subsequent fabricating step, for example, in the step of forming the pad 7 shown in FIG. 7F and the step of forming the dielectric layer 8 shown in FIG. 7G, no operation is performed regarding the first trench 51, and the first deep trench structure 511 is not formed. In addition, subsequent steps of fabricating the first trench 51 and the first deep trench structure 511 may also be omitted. For example, the following steps may be omitted: the step of extending the second opening 54 to the pad 7 at the bottom of the first trench 51, and forming the first opening 71 aligned with the second opening 54 in the pad 7 at the bottom of the first trench 51, and the step (if any) of forming the second doped region 9 in FIG. 7H; the step of forming the first conductive material 61 in FIG. 7I; and the step of removing the first conductive material 61 in FIG. 7J. In such an embodiment, except that the first trench 51 and the first deep trench structure 511 are not formed, another fabricating step of the semiconductor device 100 is similar to the fabricating step of the semiconductor device 100 described with reference to FIG. 7A to FIG. 7L, and details are not described herein again.

FIG. 8 illustratively shows a cross-sectional view of a semiconductor device 100 according to an eighth embodiment of the present disclosure. The semiconductor device 100 shown in FIG. 8 has a similar structure to the semiconductor device 100 shown in FIG. 1 and FIG. 6. A difference lies in replacing the third deep trench isolation structure 531 that fills the third trench 53 and the diffusion material 81 that is located near the third deep trench isolation structure 531. The semiconductor device 100 shown in FIG. 8 comprises a second conductive material 62 that fills the third trench 53. The second conductive material 62 extends from the top surface of the epitaxial layer 3 to the buried layer 2, and is used as a pickup structure of the buried layer 2 to electrically connect the buried layer 2 to the top surface of the epitaxial layer 3. In an embodiment, the second conductive material 62 comprises polysilicon having the second doping type. Another type of second conductive material is feasible. Another structure of the semiconductor device 100 shown in FIG. 8 is similar to a structure of the semiconductor device 100 shown in FIG. 1 and FIG. 6, and details are not described herein again.

It should be understood that, in some embodiments, when the low voltage component region and the medium voltage component region are isolated, the second deep trench isolation structure 521 may be omitted, and the first deep trench structure 511 and the second conductive material 62 are disposed between different component regions. In such an embodiment, except that the second trench 52 and the second deep trench isolation structure 521 are not comprised, another structure of the semiconductor device 100 is similar to that of the semiconductor device 100 described with reference to FIG. 8, and details are not described herein again.

In addition, it should be understood that in some embodiments, only isolation between component regions and electrical connection of the buried layer 2 to the surface of the epitaxial layer 3 may need to be implemented between some component regions, without requiring a pickup structure of the substrate 1. The first deep trench structure 511 may be omitted between such component regions, and the second deep trench isolation structure 521 and the second conductive material 62 are disposed between different component regions. In such an embodiment, except that the first trench 51 and the first deep trench structure 511 are not comprised, another structure of the semiconductor device 100 is similar to that of the semiconductor device 100 described with reference to FIG. 8, and details are not described herein again.

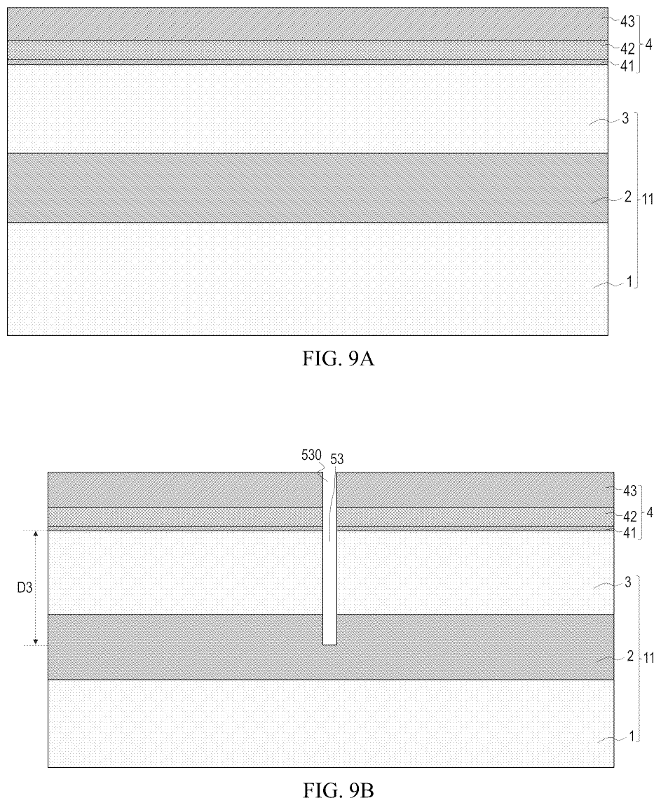

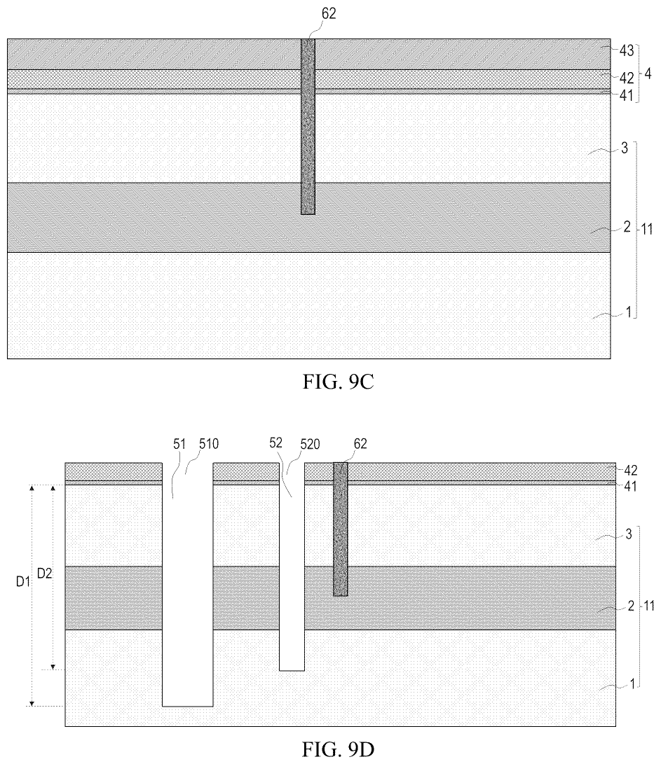

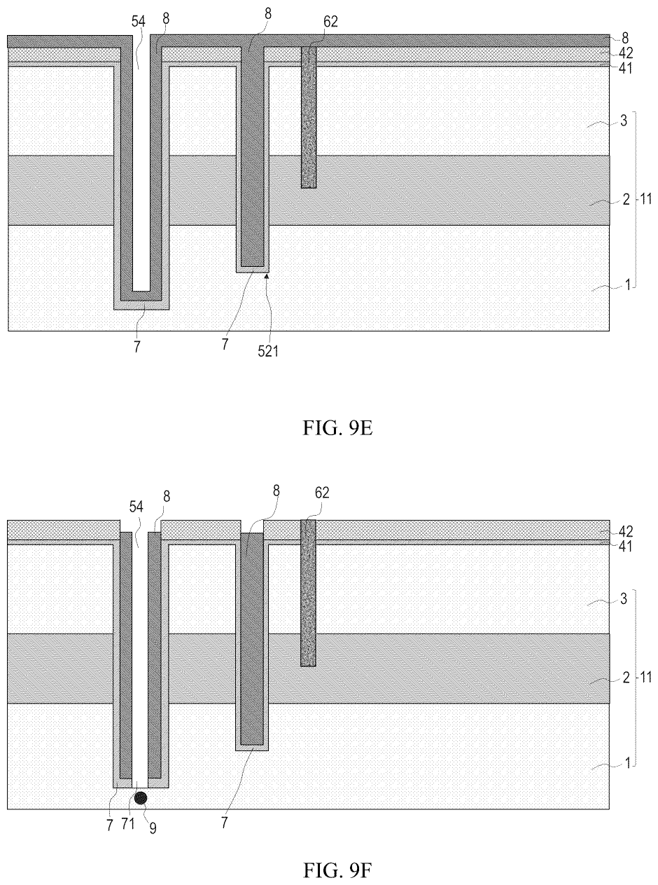

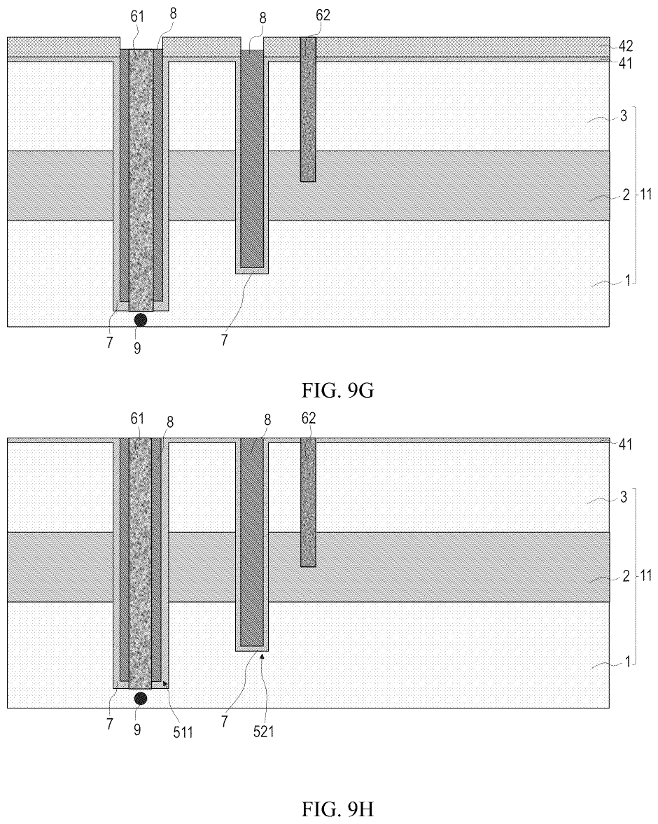

FIG. 9A to FIG. 9I show a process for fabricating a semiconductor device 100 according to a ninth embodiment of the present disclosure. The process shown in FIG. 9A to FIG. 9I may be used to fabricate the semiconductor device 100 shown in FIG. 8. The foregoing description of the semiconductor device 100 with reference to FIG. 8 may be combined herein.

As shown in FIG. 9A, a semiconductor body 11 is provided. The semiconductor body 11 comprises a substrate 1, a buried layer 2 disposed on the substrate 1, and an epitaxial layer 3 disposed on the buried layer 2. The buried layer 2 may be formed on the substrate 1 through epitaxial growth. The epitaxial layer 3 may be formed on the buried layer 2 through epitaxial growth. The substrate 1 has a first doping type. The buried layer 2 has a second doping type opposite to the first doping type. For example, when the first doping type is a p-type, the second doping type is an n-type. Similarly, when the first doping type is an n-type, the second doping type is a p-type. In an embodiment, the buried layer 2 may have a blanket structure, which has substantially the same horizontal extension as the substrate 1 and is laid flatly on the substrate 1. In another embodiment, the buried layer 2 may have a patterned structure. This is not strictly limited in the embodiments of the present disclosure. The epitaxial layer 3 may be used to form different component regions.

In addition, as shown in FIG. 9A, a hard mask layer 4 is formed on a top surface of the epitaxial layer 3. Forming the hard mask layer 4 may comprise: growing a first oxide layer 41 on the top surface of the epitaxial layer 3; depositing a nitride layer 42 on the first oxide layer 41; and depositing a second oxide layer 43 on the nitride layer 42. In another embodiment, the hard mask layer 4 may have another structure. This is not strictly limited in the embodiments of the present disclosure.

As shown in FIG. 9B, the hard mask layer 4 and the semiconductor body 11 are etched by using a third soft mask layer (not shown) to form, in the hard mask layer 4, a third trench opening 530 that penetrates through the hard mask layer 4, and to form, in the semiconductor body 11, a third trench 53 aligned with the third trench opening 530. The third trench 53 extends from the top surface of the epitaxial layer 3 into the buried layer 2 and has a third depth D3.

As shown in FIG. 9C, the third soft mask layer is stripped. Subsequently, the third trench opening 530 and the third trench 53 are filled with the second conductive material 62. In an embodiment, the second conductive material 62 comprises polysilicon having the second doping type. Another type of second conductive material is feasible. The second conductive material 62 can be used as a pickup structure of the buried layer 2 to connect the buried layer 2 to the top surface of the epitaxial layer 3. The second conductive material 62 may be formed in the third trench 53 through deposition or in another manner. After the second conductive material 62 is deposited, chemical mechanical polishing may be performed on the second conductive material 62.

As shown in FIG. 9D, the hard mask layer 4 and the semiconductor body 11 are etched by using a fourth soft mask layer (not shown) to form, in the hard mask layer 4, a first trench opening 510 and a second trench opening 520 that penetrate through the hard mask layer 4, and to form, in the semiconductor body 11, a first trench 51 aligned with the first trench opening 510 and a second trench 52 aligned with the second trench opening 520. The second trench 52 extends from the top surface of the epitaxial layer 3 into the substrate 1 and has a second depth D2 greater than the third depth D3, and the first trench 51 extends from the top surface of the epitaxial layer 3 into the substrate 1 and has a first depth D1 greater than the second depth D2. Optionally, the second oxide layer 43 may be removed. In some embodiments, ion implantation may be performed at the bottom of the first trench 51 and/or the second trench 52 to form, in the substrate 1, respective doped regions near the bottom of the first trench 51 and/or the second trench 52. The doped region has the first doping type and has a doping concentration higher than that of the substrate 1. Forming a doped region under the second trench 52 can reduce a gain of a lateral parasitic transistor (a concentration of a base region increases), thereby suppressing lateral leakage.

As shown in FIG. 9E, a sidewall and a bottom of each of the first trench 51 and the second trench 52 are lined to form a pad 7. In an embodiment, the pad 7 comprises oxide such as silicon oxide. Another type of pad 7 is feasible. Subsequently, a dielectric layer 8 is deposited inside the pad 7 so that the dielectric layer 8 forms, in the first trench 51, a second opening 54 that extends from the top surface of the epitaxial layer 3 toward the bottom of the first trench 51, and the dielectric layer 8 completely fills the second trench 52 and covers the top surface of the nitride layer 42. In some embodiments, the dielectric layer 8 may partially fill the second trench 52. This can reduce stress on one hand, and reduce parasitic capacitance on the other hand. For example, an air gap may be formed in the dielectric layer 8 in the second trench 52. In an embodiment, the dielectric layer 8 comprises oxide such as silicon oxide. Another type of dielectric layer is also feasible. The pad 7 and the dielectric layer 8 in the second trench 52 form the second deep trench isolation structure 521 to isolate different component regions that are to be formed in the epitaxial layer 3 in subsequent steps.

As shown in FIG. 9F, anisotropic etching is performed on the dielectric layer 8 and the pad 7 to remove the dielectric layer 8 from a top surface of the nitride layer 42, and to extend the second opening 54 to the pad 7 at the bottom of the first trench 51, and to form a first opening 71 aligned with the second opening 54 in the pad 7 at the bottom of the first trench 51. Optionally, ion implantation may be performed on the substrate 1 through the second opening 54 and the first opening 71 to form, in the substrate 1, a second doped region 9 near the bottom of the first trench 51. The second doped region 9 has the first doping type and has a doping concentration higher than that of the substrate 1. When the doping concentration of the substrate 1 is high, the second doped region 9 may be omitted. In addition, in some embodiments, before the anisotropic etching is performed on the dielectric layer 8 and the pad 7, ion implantation may be performed in the substrate 1 near the bottom of the first trench 51 to form the second doped region 9.

As shown in FIG. 9G, the first conductive material 61 is deposited so that the first conductive material 61 fills the first opening 71 and the second opening 54. In an embodiment, the first conductive material 61 comprises polysilicon having the first doping type. Another type of first conductive material 61 is also feasible. Subsequently, the extra first conductive material 61 may be removed by using a chemical mechanical polishing (CMP) process, and then an etch back process is performed. In some embodiments, CMP may not be performed, and the etch back process is directly performed.

As shown in FIG. 9H, the nitride layer 42 is stripped. The pad 7, the dielectric layer 8, and the first conductive material 61 in the first trench 51 may form the first deep trench structure 511. Because the first conductive material 61 extends from the top surface of the epitaxial layer 3 to the bottom of the first trench 51 and is in contact with the substrate 1, the first conductive material 61 can be used as a pickup structure of the substrate 1 to electrically connect the substrate 1 to the top surface of the epitaxial layer 3. In addition, because the pad 7 and the dielectric layer 8 that are disposed in the first trench 51 extend from the top surface of the epitaxial layer 3 to the bottom of the trench, different component regions can be isolated to some extent, thereby enhancing isolation performance.

As shown in FIG. 9I, a plurality of component regions may be formed in the epitaxial layer 3. For purposes of illustration, a first component region 111 and a second component region 112 are shown in the epitaxial layer 3 shown in FIG. 9I. For example, the first component region 111 may be a high voltage (HV) component region of an HV component (such as an HV transistor). In an embodiment, an LDMOS transistor 140 may be formed in the first component region 111, and a plurality of isolation regions 91, such as STI regions, may be formed in the first component region 111 to isolate different doped regions in the epitaxial layer 3. The second component region 112 can be used as a low voltage (LV) or medium voltage (MV) component region. In an embodiment, a first transistor 112a and a second transistor 112b may be formed in the second component region 112, and a plurality of isolation regions 91, such as shallow trench isolation (STI) regions, may be formed in the second component region 112 to isolate the first transistor 112a from the second transistor 112b. Regarding the exemplary structures of the LDMOS transistor 140, the first transistor 112a, and the second transistor 112b, reference may be made to the foregoing description with reference to FIG. 1, FIG. 6, and FIG. 8, and details are not described herein again.

At this point, according to the ninth embodiment of the present disclosure, the semiconductor device 100 shown in FIG. 8 is obtained by using the exemplary steps shown in FIG. 9A to FIG. 9I. In such an embodiment, the first deep trench structure 511, the second deep trench isolation structure 521, and the second conductive material 62 are formed by using only two masking steps and two deep trench etching steps in the semiconductor body 11, without requiring an additional masking step and an additional thermal step. Therefore, it is highly cost-effective. In addition, the second conductive material 62 is used as a pickup structure of the buried layer 2, avoiding forming a diffusion region used as a pickup structure in the epitaxial layer 3, and further reducing an area of the device.

In an alternative embodiment, with reference to FIG. 9D, a thermal annealing step may be further performed on the polysilicon having the second doping type in the third trench 53, so as to drive a dopant in the polysilicon to a neighboring region in the epitaxial layer 3 to form a diffusion region. The polysilicon and the neighboring diffusion region may jointly form a pickup structure of the buried layer 2. In addition, the polysilicon has almost the same thermal expansion coefficient as monocrystalline silicon in the semiconductor body 11, and therefore can reduce a lattice defect caused by mechanical stress.

In addition, a dopant in the buried layer 2 may be alternatively diffused upward into the epitaxial layer 3 or downward into the substrate 1 during the thermal annealing. Therefore, when thermal annealing has been performed, the buried layer 2 may have a wider extension range than that shown in FIG. 9D, for example, extends upward to a specific depth in the epitaxial layer 3 or downward to a specific depth in the substrate 1. In this case, the third trench 53 formed in the semiconductor body 11 may not extend into the buried layer 2 (certainly, extending into the buried layer 2 is still feasible), but the bottom of the third trench 53 may move upward to a position of the epitaxial layer 3 near the buried layer 2, as shown in FIG. 9D (for example, within a range of a level of several microns apart from a top surface of the buried layer 2 shown in FIG. 9D). In a thermal annealing process, the buried layer 2 extends upward and is in contact with the polysilicon (or is further in contact with the formed diffusion region) in the third trench 53. Therefore, using such arrangement can also electrically connect the buried layer 2 to the top surface of the epitaxial layer 3 reliably.

It should be understood that, in some embodiments, when the low voltage component region and the medium voltage component region are isolated, formation of the second deep trench isolation structure 521 may be omitted, and the first deep trench structure 511 and the second conductive material 62 are formed between different component regions. To this end, as shown in FIG. 9D, in the step of etching the hard mask layer 4 and the semiconductor body 11 by using a fourth soft mask layer, a first trench opening 510 that penetrates through the hard mask layer 4 is formed in the hard mask layer 4, and a second trench opening 520 shown in FIG. 9D is not formed; in addition, a first trench 51 aligned with the first trench opening 510 is formed in the semiconductor body 11, and a second trench 52 aligned with the second trench opening 520 is not formed. In this way, in a subsequent fabricating step, for example, in the step of forming the pad 7 and the dielectric layer 8 shown in FIG. 9E, no operation is performed regarding the second trench 52, and the second deep trench isolation structure 521 is not formed. In such an embodiment, except that the second trench 52 and the second deep trench isolation structure 521 are not formed, another fabricating step of the semiconductor device 100 is similar to the fabricating step of the semiconductor device 100 described with reference to FIG. 9A to FIG. 9I, and details are not described herein again.

In addition, it should be understood that in some embodiments, only isolation between component regions and electrical connection of the buried layer 2 to the surface of the epitaxial layer 3 may need to be implemented between some component regions, without requiring a pickup structure of the substrate 1. Formation of the first deep trench structure 511 may be omitted between such component regions, and the second deep trench isolation structure 521 and the second conductive material 62 are formed between different component regions. To this end, as shown in FIG. 9D, in the step of etching the hard mask layer 4 and the semiconductor body 11 by using a fourth soft mask layer, a second trench opening 520 that penetrates through the hard mask layer 4 is formed in the hard mask layer 4, and a first trench opening 510 shown in FIG. 9D is not formed; in addition, a second trench 52 aligned with the second trench opening 520 is formed in the semiconductor body 11, and a first trench 51 aligned with the first trench opening 510 is not formed. In this way, in a subsequent fabricating step, for example, in the step of forming the pad 7 and the dielectric layer 8 shown in FIG. 9E, no operation is performed regarding the first trench 51, and the first deep trench structure 511 is not formed. In addition, subsequent steps of fabricating the first trench 51 and the first deep trench structure 511 may also be omitted. For example, the following steps may be omitted: the step of extending the second opening 54 to the pad 7 at the bottom of the first trench 51, and forming the first opening 71 aligned with the second opening 54 in the pad 7 at the bottom of the first trench 51, and the step (if any) of forming the second doped region 9 in FIG. 9F; and the step of forming the first conductive material 61 and the step of removing the first conductive material 61 in FIG. 9G. In such an embodiment, except that the first trench 51 and the first deep trench structure 511 are not formed, another fabricating step of the semiconductor device 100 is similar to the fabricating step of the semiconductor device 100 described with reference to FIG. 9A to FIG. 9I, and details are not described herein again.

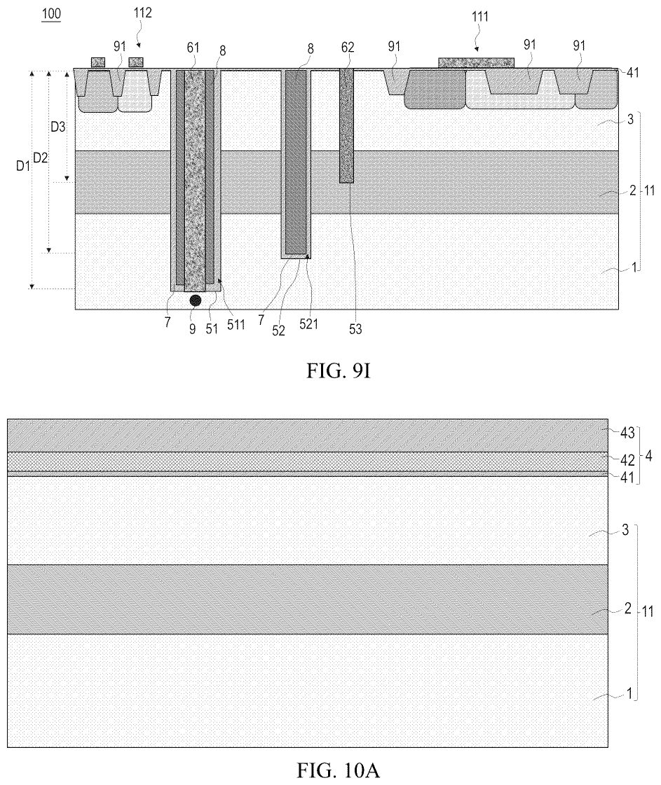

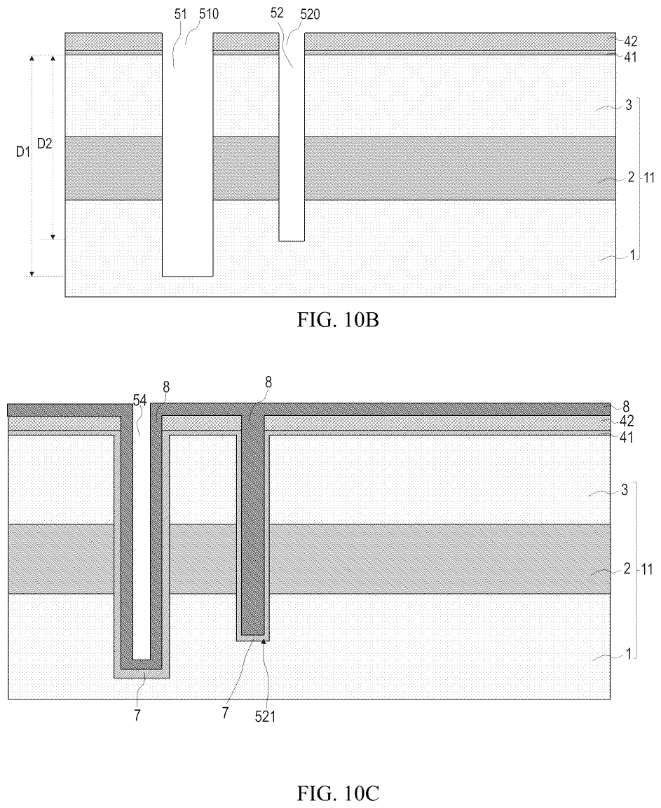

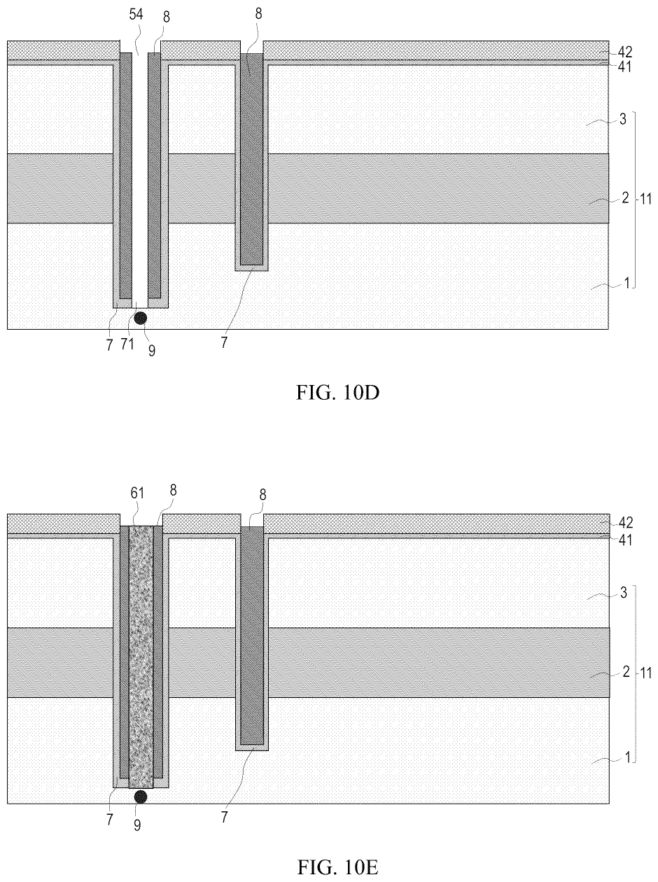

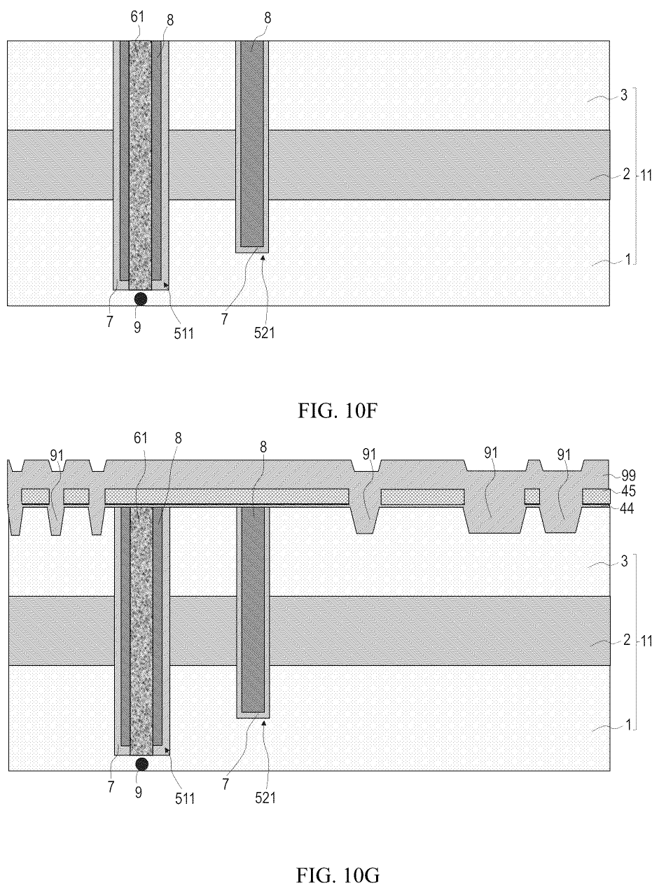

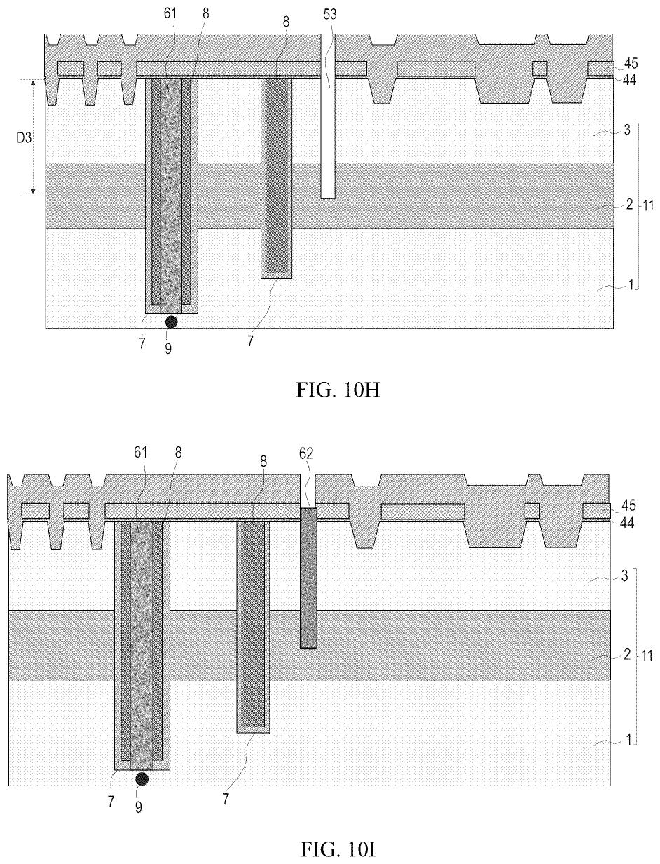

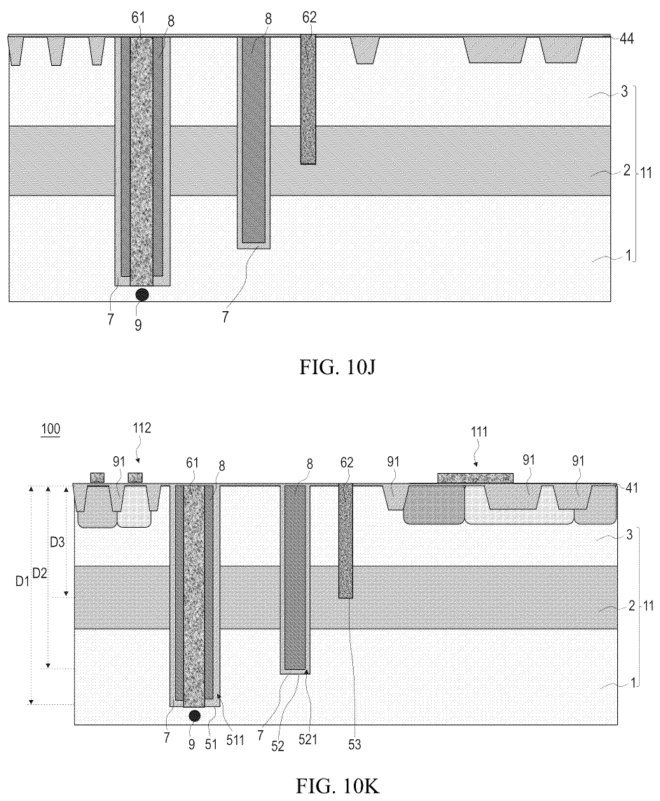

FIG. 10A to FIG. 10K show a process for fabricating a semiconductor device 100 according to a tenth embodiment of the present disclosure. The process shown in FIG. 10A to FIG. 10K may be used to fabricate the semiconductor device 100 shown in FIG. 8. The foregoing description of the semiconductor device 100 with reference to FIG. 8 may be combined herein.

As shown in FIG. 10A, a semiconductor body 11 is provided. The semiconductor body 11 comprises a substrate 1, a buried layer 2 disposed on the substrate 1, and an epitaxial layer 3 disposed on the buried layer 2. The buried layer 2 may be formed on the substrate 1 through epitaxial growth. The epitaxial layer 3 may be formed on the buried layer 2 through epitaxial growth. The substrate 1 has a first doping type. The buried layer 2 has a second doping type opposite to the first doping type. For example, when the first doping type is a p-type, the second doping type is an n-type. Similarly, when the first doping type is an n-type, the second doping type is a p-type. In an embodiment, the buried layer 2 may have a blanket structure, which has substantially the same horizontal extension as the substrate 1 and is laid flatly on the substrate 1. In another embodiment, the buried layer 2 may have a patterned structure. This is not strictly limited in the embodiments of the present disclosure. The epitaxial layer 3 may be used to form different component regions.

In addition, as shown in FIG. 10A, a hard mask layer 4 is formed on a top surface of the epitaxial layer 3. Forming the hard mask layer 4 may comprise: growing a first oxide layer 41 on the top surface of the epitaxial layer 3; depositing a nitride layer 42 on the first oxide layer 41; and depositing a second oxide layer 43 on the nitride layer 42. In another embodiment, the hard mask layer 4 may have another structure. This is not strictly limited in the embodiments of the present disclosure.

As shown in FIG. 10B, the hard mask layer 4 and the semiconductor body 11 are etched by using a fifth soft mask layer (not shown) to form, in the hard mask layer 4, a first trench opening 510 and a second trench opening 520 that penetrate through the hard mask layer 4, and to form, in the semiconductor body 11, a first trench 51 aligned with the first trench opening 510 and a second trench 52 aligned with the second trench opening 520. The first trench 51 extends from the top surface of the epitaxial layer 3 into the substrate 1 and has a first depth D1. The second trench 52 extends from the top surface of the epitaxial layer 3 into the substrate 1 and has a second depth D2 less than the first depth D1. Subsequently, the fifth soft mask layer is stripped. Optionally, the second oxide layer 43 may be removed. In some embodiments, ion implantation may be performed at the bottom of the first trench 51 and/or the second trench 52 to form, in the substrate 1, respective doped regions near the bottom of the first trench 51 and/or the second trench 52. The doped region has the first doping type and has a doping concentration higher than that of the substrate 1. Forming a doped region under the second trench 52 can reduce a gain of a lateral parasitic transistor (a concentration of a base region increases), thereby suppressing lateral leakage.

As shown in FIG. 10C, a sidewall and a bottom of each of the first trench 51 and the second trench 52 are lined to form a pad 7. In an embodiment, the pad 7 comprises oxide such as silicon oxide. Another type of pad 7 is feasible. Subsequently, a dielectric layer 8 is deposited inside the pad 7 so that the dielectric layer 8 forms, in the first trench 51, a second opening 54 that extends from the top surface of the epitaxial layer 3 toward the bottom of the first trench 51, and the dielectric layer 8 completely fills the second trench 52 and covers the top surface of the nitride layer 42. In some embodiments, the dielectric layer 8 may partially fill the second trench 52. This can reduce stress on one hand, and reduce parasitic capacitance on the other hand. For example, an air gap may be formed in the dielectric layer 8 in the second trench 52. In an embodiment, the dielectric layer 8 comprises oxide such as silicon oxide. Another type of dielectric layer is also feasible. The pad 7 and the dielectric layer 8 in the second trench 52 form the second deep trench isolation structure 521 to isolate different component regions that are to be formed in the epitaxial layer 3 in subsequent steps.

As shown in FIG. 10D, anisotropic etching is performed on the dielectric layer 8 and the pad 7 to remove the dielectric layer 8 from a top surface of the nitride layer 42, and to extend the second opening 54 to the pad 7 at the bottom of the first trench 51, and to form a first opening 71 aligned with the second opening 54 in the pad 7 at the bottom of the first trench 51. Optionally, ion implantation may be performed on the substrate 1 through the second opening 54 and the first opening 71 to form, in the substrate 1, a second doped region 9 near the bottom of the first trench 51. The second doped region 9 has the first doping type and has a doping concentration higher than that of the substrate 1. When the doping concentration of the substrate 1 is high, the second doped region 9 may be omitted. In addition, in some embodiments, before the anisotropic etching is performed on the dielectric layer 8 and the pad 7, ion implantation may be performed in the substrate 1 near the bottom of the first trench 51 to form the second doped region 9.

As shown in FIG. 10E, the first conductive material 61 is deposited so that the first conductive material 61 fills the first opening 71 and the second opening 54. In an embodiment, the first conductive material 61 comprises polysilicon having the first doping type. Another type of first conductive material 61 is also feasible. Subsequently, the extra first conductive material 61 may be removed by using a chemical mechanical polishing (CMP) process, and then an etch back process is performed. In some embodiments, CMP may not be performed, and the etch back process is directly performed.

As shown in FIG. 10F, the first oxide layer 41 and the nitride layer 42 are stripped. The pad 7, the dielectric layer 8, and the first conductive material 61 in the first trench 51 may form the first deep trench structure 511. Because the first conductive material 61 extends from the top surface of the epitaxial layer 3 to the bottom of the first trench 51 and is in contact with the substrate 1, the first conductive material 61 can be used as a pickup structure of the substrate 1 to electrically connect the substrate 1 to the top surface of the epitaxial layer 3. In addition, because the pad 7 and the dielectric layer 8 that are disposed in the first trench 51 extend from the top surface of the epitaxial layer 3 to the bottom of the trench, different component regions can be isolated to some extent, thereby enhancing isolation performance.

As shown in FIG. 10G, a third oxide layer 44 and a second nitride layer 45 are formed on the top surface of the epitaxial layer 3. Subsequently, the third oxide layer 44 and the second nitride layer 45 are etched to form a plurality of openings, and further etched into the epitaxial layer 3 to form a plurality of recesses. Subsequently, the formed openings and recesses are filled with a dielectric material 99 to form a plurality of shallow trench isolation (STI) regions 91 in the epitaxial layer 3.

As shown in FIG. 10H, the semiconductor body 11 is etched by using a sixth soft mask layer (not shown) to form a third trench 53 in the semiconductor body 11. The third trench 53 extends from the top surface of the epitaxial layer 3 into the buried layer 2 and has a third depth D less than the second depth D2. Subsequently, the sixth soft mask layer may be stripped. In some embodiments, after chemical mechanical polishing (CMP) is performed on the dielectric material 99, the semiconductor body 11 may be etched to form the third trench 53.

As shown in FIG. 10I, the third trench 53 is filled with the second conductive material 62. In an embodiment, the second conductive material 62 comprises polysilicon having the second doping type. Another type of second conductive material is feasible. The second conductive material 62 can be used as a pickup structure of the buried layer 2 to connect the buried layer 2 to the top surface of the epitaxial layer 3. The second conductive material 62 may be formed in the third trench 53 through deposition or in another manner. After the second conductive material 62 is deposited, chemical mechanical polishing and an etch back process may be performed on the second conductive material 62.

As shown in FIG. 10J, chemical mechanical polishing (CMP) is performed on the dielectric material 99, and the second nitride layer 45 is stripped.

As shown in FIG. 10K, a plurality of component regions may be formed in the epitaxial layer 3. For purposes of illustration, a first component region 111 and a second component region 112 are shown in the epitaxial layer 3 shown in FIG. 10K. For example, the first component region 111 may be a high voltage (HV) component region of an HV component (such as an HV transistor). In an embodiment, an LDMOS transistor 140 may be formed in the first component region 111, and a plurality of isolation regions 91, such as STI regions, may be formed in the first component region 111 to isolate different doped regions in the epitaxial layer 3. The second component region 112 can be used as a low voltage (LV) or medium voltage (MV) component region. In an embodiment, a first transistor 112a and a second transistor 112b may be formed in the second component region 112, and a plurality of isolation regions 91, such as shallow trench isolation (STI) regions, may be formed in the second component region 112 to isolate the first transistor 112a from the second transistor 112b. Regarding the exemplary structures of the LDMOS transistor 140, the first transistor 112a, and the second transistor 112b, reference may be made to the foregoing description with reference to FIG. 1, FIG. 6, and FIG. 8, and details are not described herein again.

At this point, according to the tenth embodiment of the present disclosure, the semiconductor device 100 shown in FIG. 8 is obtained by using the exemplary steps shown in FIG. 10A to FIG. 10K. In such an embodiment, the first deep trench structure 511, the second deep trench isolation structure 521, and the second conductive material 62 are formed by using only two masking steps and two deep trench etching steps in the semiconductor body 11, without requiring an additional masking step and an additional thermal step. Therefore, it is highly cost-effective. In addition, the second conductive material 62 is used as a pickup structure of the buried layer 2, avoiding forming a diffusion region used as a pickup structure in the epitaxial layer 3, and further reducing an area of the device.

In an alternative embodiment, with reference to FIG. 10I, a thermal annealing step may be further performed on the polysilicon having the second doping type in the third trench 53, so as to drive a dopant in the polysilicon to a neighboring region in the epitaxial layer 3 to form a diffusion region. The polysilicon and the neighboring diffusion region may jointly form a pickup structure of the buried layer 2. In addition, the polysilicon has almost the same thermal expansion coefficient as monocrystalline silicon in the semiconductor body 11, and therefore can reduce a lattice defect caused by mechanical stress.

In addition, a dopant in the buried layer 2 may be alternatively diffused upward into the epitaxial layer 3 or downward into the substrate 1 during the thermal annealing. Therefore, when thermal annealing has been performed, the buried layer 2 may have a wider extension range than that shown in FIG. 10I, for example, extends upward to a specific depth in the epitaxial layer 3 or downward to a specific depth in the substrate 1. In this case, the third trench 53 formed in the semiconductor body 11 may not extend into the buried layer 2 (certainly, extending into the buried layer 2 is still feasible), but the bottom of the third trench 53 may move upward to a position of the epitaxial layer 3 near the buried layer 2, as shown in FIG. 10I (for example, within a range of a level of several microns apart from a top surface of the buried layer 2 shown in FIG. 10I). In a thermal annealing process, the buried layer 2 extends upward and is in contact with the polysilicon (or is further in contact with the formed diffusion region) in the third trench 53. Therefore, using such arrangement can also electrically connect the buried layer 2 to the top surface of the epitaxial layer 3 reliably.

It should be understood that, in some embodiments, when the low voltage component region and the medium voltage component region are isolated, formation of the second deep trench isolation structure 521 may be omitted, and the first deep trench structure 511 and the second conductive material 62 are formed between different component regions. To this end, as shown in FIG. 10B, in the step of etching the hard mask layer 4 and the semiconductor body 11 by using a fifth soft mask layer, a first trench opening 510 that penetrates through the hard mask layer 4 is formed in the hard mask layer 4, and a second trench opening 520 shown in FIG. 10B is not formed; in addition, a first trench 51 aligned with the first trench opening 510 is formed in the semiconductor body 11, and a second trench 52 aligned with the second trench opening 520 is not formed. In this way, in a subsequent fabricating step, for example, in the step of forming the pad 7 and the dielectric layer 8 shown in FIG. 10C, no operation is performed regarding the second trench 52, and the second deep trench isolation structure 521 is not formed. In such an embodiment, except that the second trench 52 and the second deep trench isolation structure 521 are not formed, another fabricating step of the semiconductor device 100 is similar to the fabricating step of the semiconductor device 100 described with reference to FIG. 10A to FIG. 10K, and details are not described herein again.

In addition, it should be understood that in some embodiments, only isolation between component regions and electrical connection of the buried layer 2 to the surface of the epitaxial layer 3 may need to be implemented between some component regions, without requiring a pickup structure of the substrate 1. Formation of the first deep trench structure 511 may be omitted between such component regions, and the second deep trench isolation structure 521 and the second conductive material 62 are formed between different component regions. To this end, as shown in FIG. 10B, in the step of etching the hard mask layer 4 and the semiconductor body 11 by using a fifth soft mask layer, a second trench opening 520 that penetrates through the hard mask layer 4 is formed in the hard mask layer 4, and a first trench opening 510 shown in FIG. 10B is not formed; in addition, a second trench 52 aligned with the second trench opening 520 is formed in the semiconductor body 11, and a first trench 51 aligned with the first trench opening 510 is not formed. In this way, in a subsequent fabricating step, for example, in the step of forming the pad 7 and the dielectric layer 8 shown in FIG. 10C, no operation is performed regarding the first trench 51, and no first deep trench structure 511 is formed. In addition, subsequent steps of fabricating the first trench 51 and the first deep trench structure 511 may also be omitted. For example, the following steps may be omitted: the step of extending the second opening 54 to the pad 7 at the bottom of the first trench 51, and forming the first opening 71 aligned with the second opening 54 in the pad 7 at the bottom of the first trench 51, and the step (if any) of forming the second doped region 9 in FIG. 10D; and the step of forming the first conductive material 61 and the step of removing the first conductive material 61 in FIG. 10E. In such an embodiment, except that the first trench 51 and the first deep trench structure 511 are not formed, another fabricating step of the semiconductor device 100 is similar to the fabricating step of the semiconductor device 100 described with reference to FIG. 10A to FIG. 10K, and details are not described herein again.

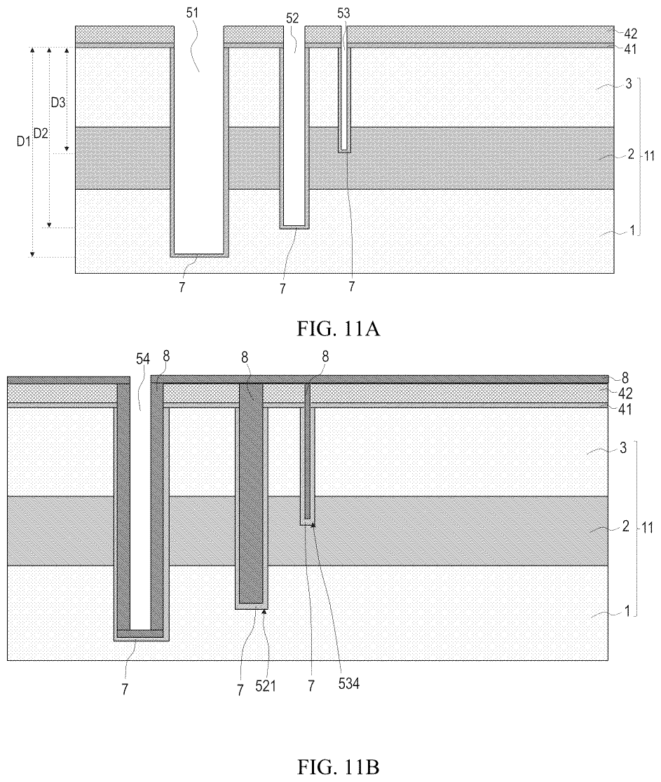

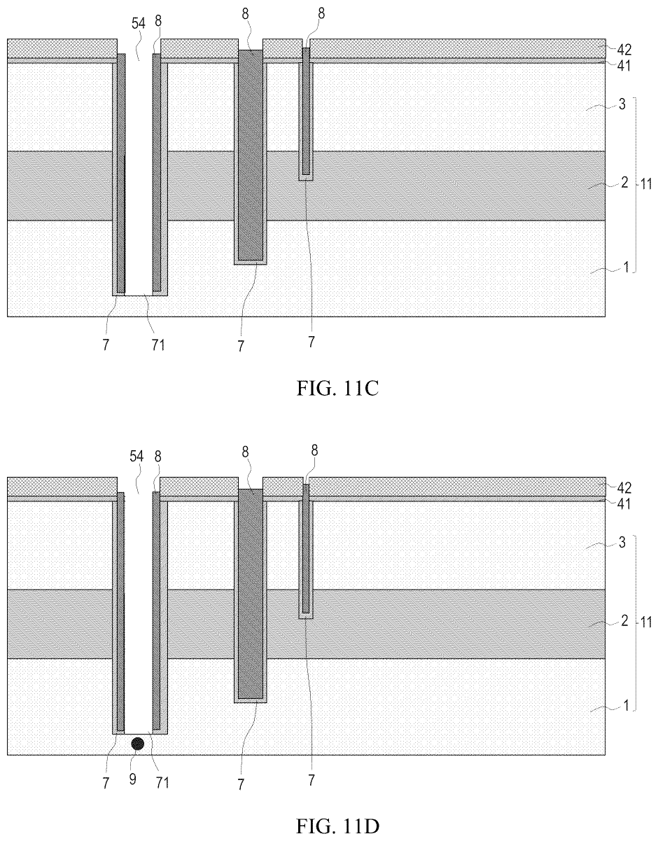

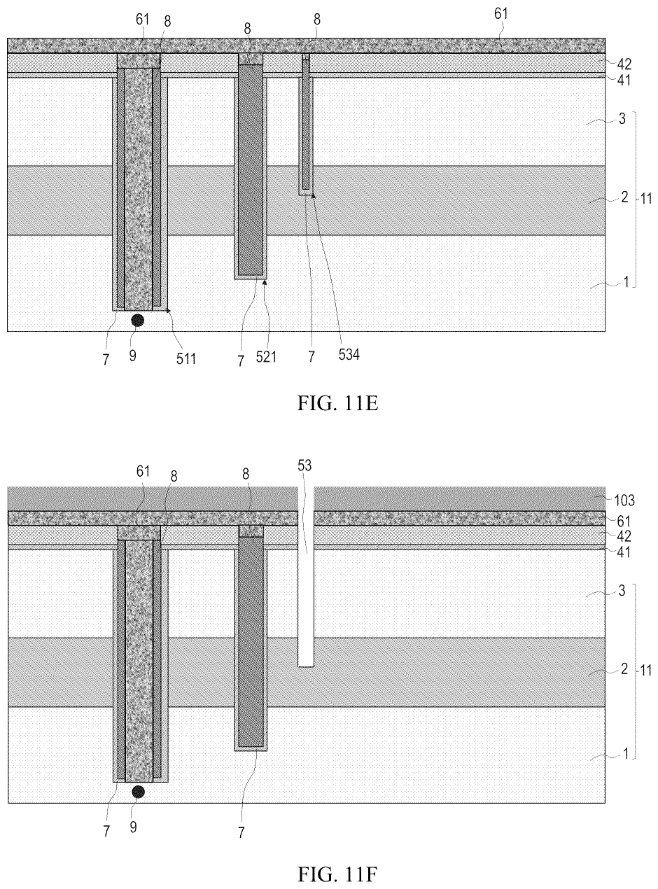

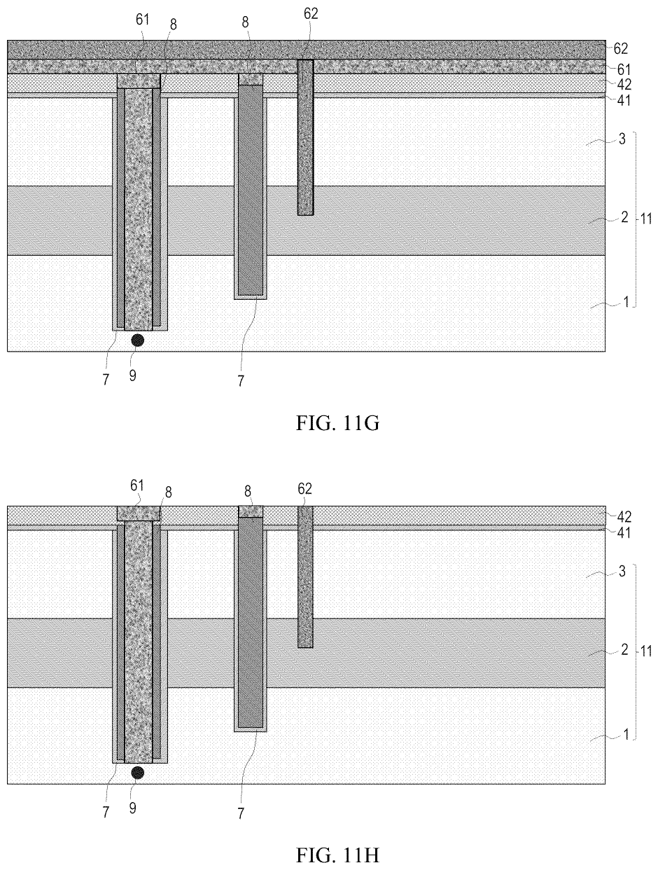

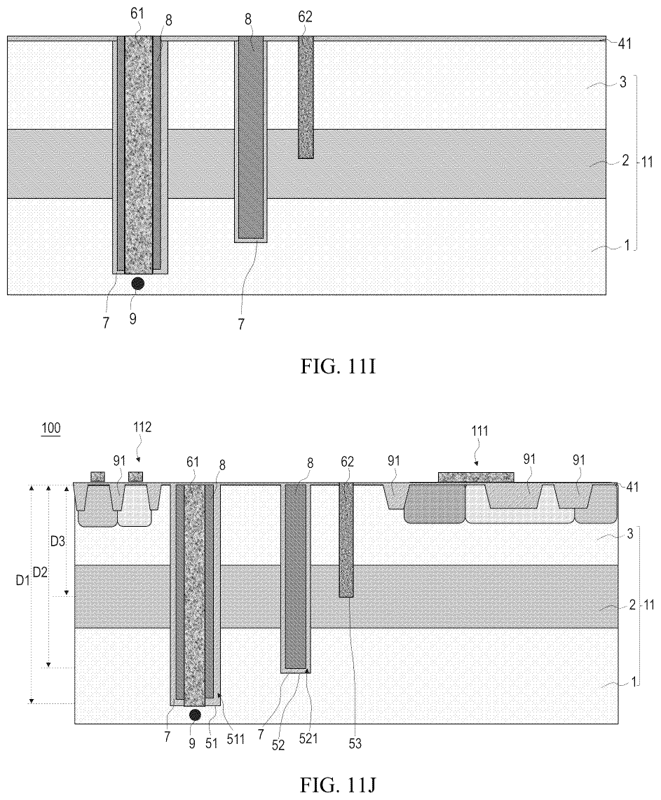

FIG. 11A to FIG. 11J show a process for fabricating a semiconductor device 100 according to an eleventh embodiment of the present disclosure. The process shown in FIG. 11A to FIG. 11J may be used to fabricate the semiconductor device 100 shown in FIG. 8. The foregoing description of the semiconductor device 100 with reference to FIG. 8 may be combined herein.

A structure shown in FIG. 11A is similar to the structure shown in FIG. 2I. A specific description of a formation process of the structure shown in FIG. 11A is omitted herein. For example steps, reference may be made to the descriptions with reference to FIG. 2A to FIG. 2I. For example, the hard mask layer 4 and the semiconductor body 11 may be etched by using a seventh soft mask layer (not shown) to simultaneously form the first trench 51, the second trench 52, and the third trench 53 in the semiconductor body 11. The first trench 51 extends from the top surface of the epitaxial layer 3 into the substrate 1 and has a first depth D1. The second trench 52 extends from the top surface of the epitaxial layer 3 into the substrate 1 and has a second depth D2 less than the first depth D1. The third trench 53 extends from the top surface of the epitaxial layer 3 into the buried layer 2 and has a third depth D3 less than the second depth D2. In addition, as shown in FIG. 11A, a pad 7 has been formed on a sidewall and a bottom of each of the first trench 51, the second trench 52, and the third trench 53.

As shown in FIG. 11B, the dielectric layer 8 is deposited so that the dielectric layer 8 forms, in the first trench 51, a second opening 54 that extends from the top surface of the epitaxial layer 3 toward the bottom of the first trench 51, and the dielectric layer 8 completely fills the second trench 52 and the third trench 53. In some embodiments, the dielectric layer 8 may partially fill the second trench 52. This can reduce stress on one hand, and reduce parasitic capacitance on the other hand. For example, an air gap may be formed in the dielectric layer 8 in the second trench 52. In an embodiment, the dielectric layer 8 comprises oxide such as silicon oxide. Another type of dielectric layer is also feasible. The pad 7 and the dielectric layer 8 in the second trench 52 form the second deep trench isolation structure 521, and the pad 7 and the dielectric layer 8 in the third trench 53 form a temporary deep trench structure 534.

As shown in FIG. 11C, anisotropic etching is performed on the dielectric layer 8 and the pad 7 to remove the dielectric layer 8 from a top surface of the nitride layer 42, and to extend the second opening 54 to the pad 7 at the bottom of the first trench 51, and to form a first opening 71 aligned with the second opening 54 in the pad 7 at the bottom of the first trench 51.

As shown in FIG. 11D, ion implantation is performed on the substrate 1 through the second opening 54 and the first opening 71 to form, in the substrate 1, a second doped region 9 near the bottom of the first trench 51. The second doped region 9 has the first doping type and has a doping concentration higher than that of the substrate 1. When the doping concentration of the substrate 1 is high, the second doped region 9 may be omitted. In addition, in some embodiments, before the anisotropic etching is performed on the dielectric layer 8 and the pad 7, ion implantation may be performed in the substrate 1 near the bottom of the first trench 51 to form the second doped region 9.

As shown in FIG. 11E, the first conductive material 61 is deposited so that the first conductive material 61 fills the first opening 71 and the second opening 54, and covers the top surface of the nitride layer 42. In an embodiment, the first conductive material 61 comprises polysilicon having the first doping type. Another type of first conductive material 61 is also feasible. The pad 7, the dielectric layer 8, and the first conductive material 61 in the first trench 51 may form the first deep trench structure 511. Because the first conductive material 61 extends from the top surface of the epitaxial layer 3 to the bottom of the first trench 51 and is in contact with the substrate 1, the first conductive material 61 can be used as a pickup structure of the substrate 1 to electrically connect the substrate 1 to the top surface of the epitaxial layer 3. In addition, because the pad 7 and the dielectric layer 8 that are disposed in the first trench 51 extend from the top surface of the epitaxial layer 3 to the bottom of the trench, different component regions can be isolated to some extent, thereby enhancing isolation performance.

As shown in FIG. 11F, the temporary deep trench structure 534 in the third trench 53 and the first conductive material 61 are etched by using an eighth soft mask layer 103 to remove the temporary deep trench structure 534 in the third trench 53.

As shown in FIG. 11G, the eighth soft mask layer 103 is stripped. Subsequently, the third trench 53 is filled with a second conductive material 62, wherein the second conductive material 62 is configured to electrically connect the buried layer 2 to the top surface of the epitaxial layer 3. In an embodiment, the second conductive material 62 comprises polysilicon having the second doping type. Another type of second conductive material is feasible. The second conductive material 62 can be used as a pickup structure of the buried layer 2 to connect the buried layer 2 to the top surface of the epitaxial layer 3. Compared with an embodiment in which a diffusion region is used as a pickup structure, using polysilicon as a pickup structure of the buried layer 2 can better electrically connect the buried layer 2 to the top surface of the epitaxial layer 3. In some embodiments, a thermal annealing step may be performed to drive a dopant in the polysilicon to a neighboring region in the epitaxial layer 3 to form a diffusion region. The polysilicon and the neighboring diffusion region may jointly form a pickup structure of the buried layer 2. In addition, the polysilicon has almost the same thermal expansion coefficient as monocrystalline silicon in the semiconductor body 11, and therefore can reduce a lattice defect caused by mechanical stress.

Alternatively, instead of the second conductive material 62, a diffusion material such as POCl3 glass and phosphate silicate glass (when the first doping type is a p-type) or borosilicate glass (when the first doping type is an n-type) may fill the third trench 53, and subsequently a dopant is diffused into the epitaxial layer 3 through thermal annealing to form a pickup structure of the buried layer 2.

In addition, a dopant in the buried layer 2 may be alternatively diffused upward into the epitaxial layer 3 or downward into the substrate 1 during the thermal annealing. Therefore, when thermal annealing has been performed, the buried layer 2 may have a wider extension range than that shown in FIG. 11G, for example, extends upward to a specific depth in the epitaxial layer 3 or downward to a specific depth in the substrate 1. In this case, the third trench 53 formed in the semiconductor body 11 may not extend into the buried layer 2 (certainly, extending into the buried layer 2 is still feasible), but the bottom of the third trench 53 may move upward to a position of the epitaxial layer 3 near the buried layer 2, as shown in FIG. 11G (for example, within a range of a level of several microns apart from a top surface of the buried layer 2 shown in FIG. 11G). In a thermal annealing process, the buried layer 2 extends upward and is in contact with the polysilicon (or is further in contact with the formed diffusion region) in the third trench 53. Therefore, using such arrangement can also electrically connect the buried layer 2 to the top surface of the epitaxial layer 3 reliably.

As shown in FIG. 11H, the extra first conductive material 61 or diffusion material is removed by using a chemical mechanical polishing (CMP) process, and then an etch back process is performed. In some embodiments, CMP may not be performed, and the etch back process is directly performed.

As shown in FIG. 11I, the nitride layer 42 is stripped.

As shown in FIG. 11J, a plurality of component regions may be formed in the epitaxial layer 3. For purposes of illustration, a first component region 111 and a second component region 112 are shown in the epitaxial layer 3 shown in FIG. 11J. For example, the first component region 111 may be a high voltage (HV) component region of an HV component (such as an HV transistor). In an embodiment, an LDMOS transistor 140 may be formed in the first component region 111, and a plurality of isolation regions 91, such as STI regions, may be formed in the first component region 111 to isolate different doped regions in the epitaxial layer 3. The second component region 112 can be used as a low voltage (LV) or medium voltage (MV) component region. In an embodiment, a first transistor 112a and a second transistor 112b may be formed in the second component region 112, and a plurality of isolation regions 91, such as shallow trench isolation (STI) regions, may be formed in the second component region 112 to isolate the first transistor 112a from the second transistor 112b. Regarding the exemplary structures of the LDMOS transistor 140, the first transistor 112a, and the second transistor 112b, reference may be made to the foregoing description with reference to FIG. 1, FIG. 6, and FIG. 8, and details are not described herein again.

At this point, according to the eleventh embodiment of the present disclosure, the semiconductor device 100 shown in FIG. 8 is obtained by using the exemplary steps shown in FIG. 11A to FIG. 11J. In such an embodiment, the first deep trench structure 511, the second deep trench isolation structure 521, and the second conductive material 62 are formed by using only two masking steps, without requiring an additional masking step and an additional thermal step. Therefore, it is highly cost-effective. In addition, compared with a solution in which ion implantation and diffusion are used to form a pickup structure, using the second conductive material 62 as a pickup structure of the buried layer 2 can ensure that a structure of the device is more compact, thereby reducing an area of the device.

It should be understood that, in some embodiments, when the low voltage component region and the medium voltage component region are isolated, formation of the second deep trench isolation structure 521 may be omitted, and the first deep trench structure 511 and the second conductive material 62 are formed between different component regions. To this end, the first trench opening 510 and the third trench opening 530 that penetrate through the hard mask layer 4 are simultaneously formed in the hard mask layer 4, and the second trench opening 520 is not formed. In addition, the first trench 51 aligned with the first trench opening 510 and the third trench 53 aligned with the third trench opening 530 are formed in the semiconductor body 11, and the second trench 52 aligned with the second trench opening 520 is not formed. In this way, in a subsequent fabricating step, for example, in the step of forming the pad 7 shown in FIG. 11A and the step of forming the dielectric layer 8 shown in FIG. 11B, no operation is performed regarding the second trench 52, and the second deep trench isolation structure 521 is not formed. In such an embodiment, except that the second trench 52 and the second deep trench isolation structure 521 are not formed, another fabricating step of the semiconductor device 100 is similar to the fabricating step of the semiconductor device 100 described with reference to FIG. 11A to FIG. 11J, and details are not described herein again.

In addition, it should be understood that in some embodiments, only isolation between component regions and electrical connection of the buried layer 2 to the surface of the epitaxial layer 3 may need to be implemented between some component regions, without requiring a pickup structure of the substrate 1. Formation of the first deep trench structure 511 may be omitted between such component regions, and the second deep trench isolation structure 521 and the second conductive material 62 are formed between different component regions. To this end, the second trench opening 520 and the third trench opening 530 that penetrate through the hard mask layer 4 are simultaneously formed in the hard mask layer 4, and the first trench opening 510 is not formed. In addition, the second trench 52 aligned with the second trench opening 520 and the third trench 53 aligned with the third trench opening 530 are formed in the semiconductor body 11, and the first trench 51 aligned with the first trench opening 510 is not formed. In this way, in a subsequent fabricating step, for example, in the step of forming the pad 7 shown in FIG. 11A and the step of forming the dielectric layer 8 shown in FIG. 11B, no operation is performed regarding the first trench 51, and the first deep trench structure 511 is not formed. In addition, subsequent steps of fabricating the first trench 51 and the first deep trench structure 511 may also be omitted. For example, the following steps may be omitted: the step of extending the second opening 54 to the pad 7 at the bottom of the first trench 51, and forming the first opening 71 aligned with the second opening 54 in the pad 7 at the bottom of the first trench 51 in FIG. 11C, and the step (if any) of forming the second doped region 9 in FIG. 11D; and the step of forming the first conductive material 61 in FIG. 11E. In such an embodiment, except that the first trench 51 and the first deep trench structure 511 are not formed, another fabricating step of the semiconductor device 100 is similar to the fabricating step of the semiconductor device 100 described with reference to FIG. 11A to FIG. 11J, and details are not described herein again.

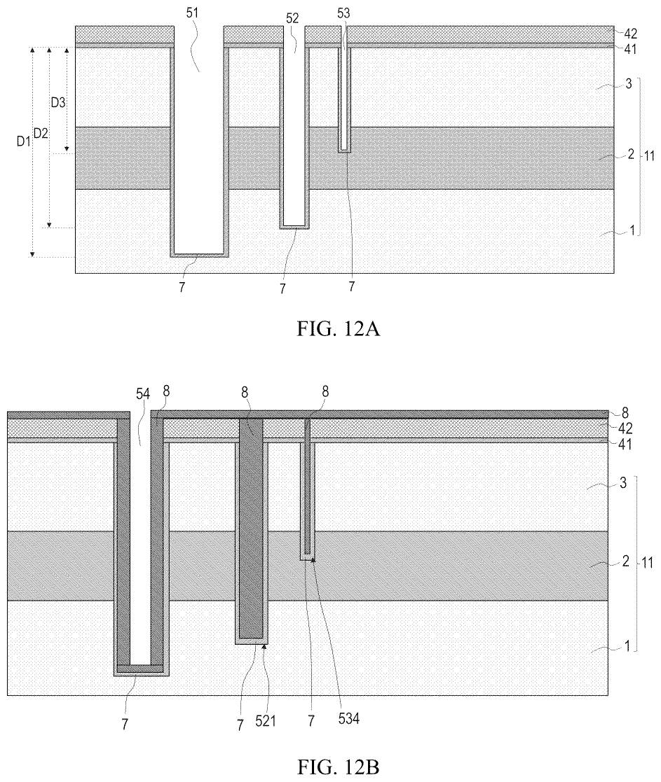

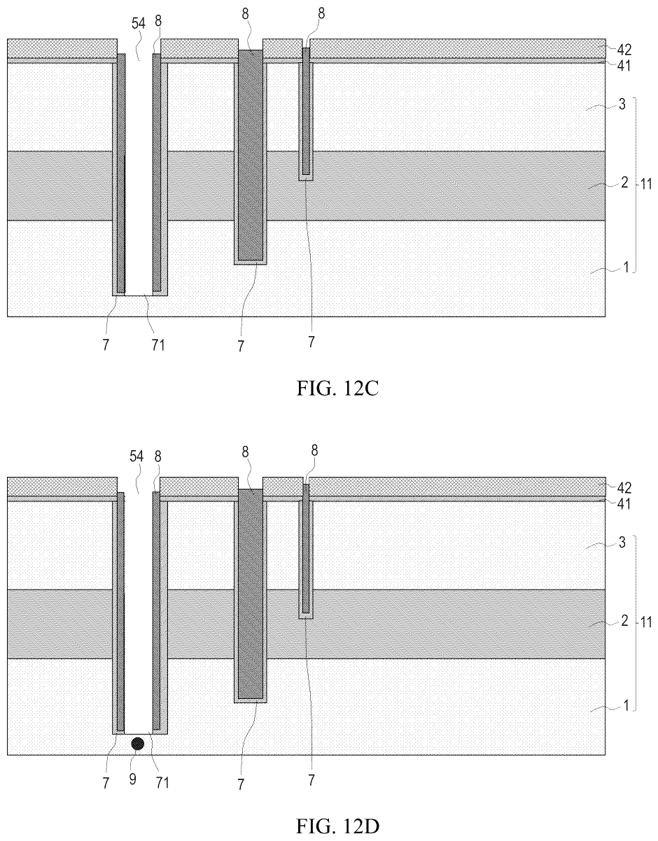

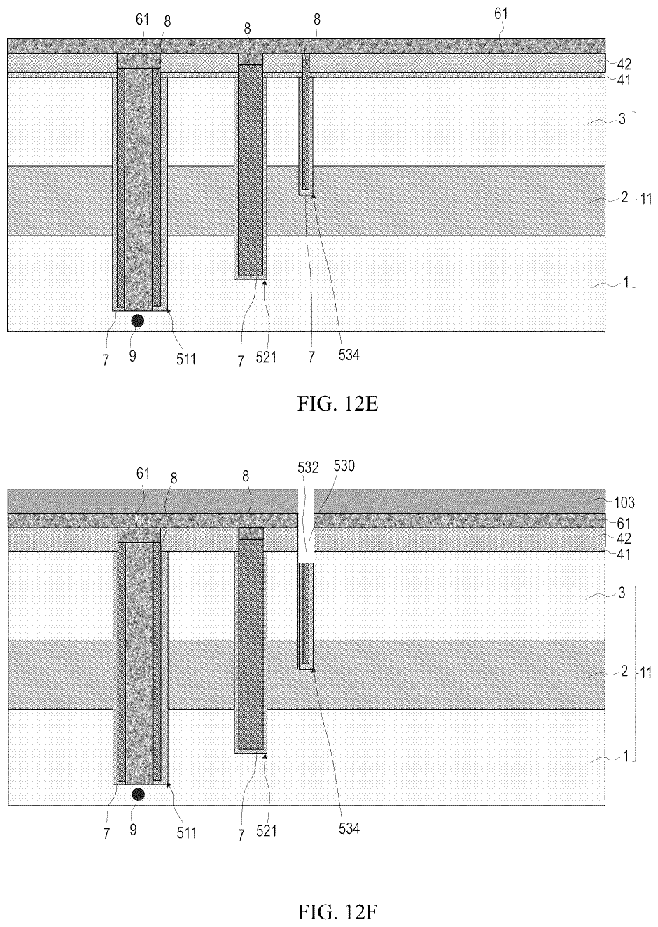

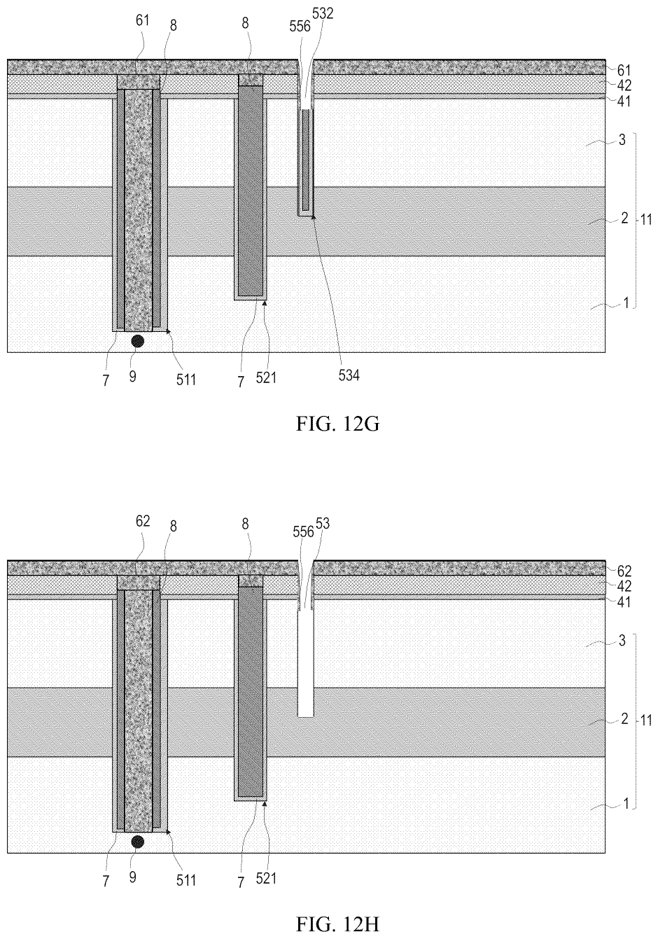

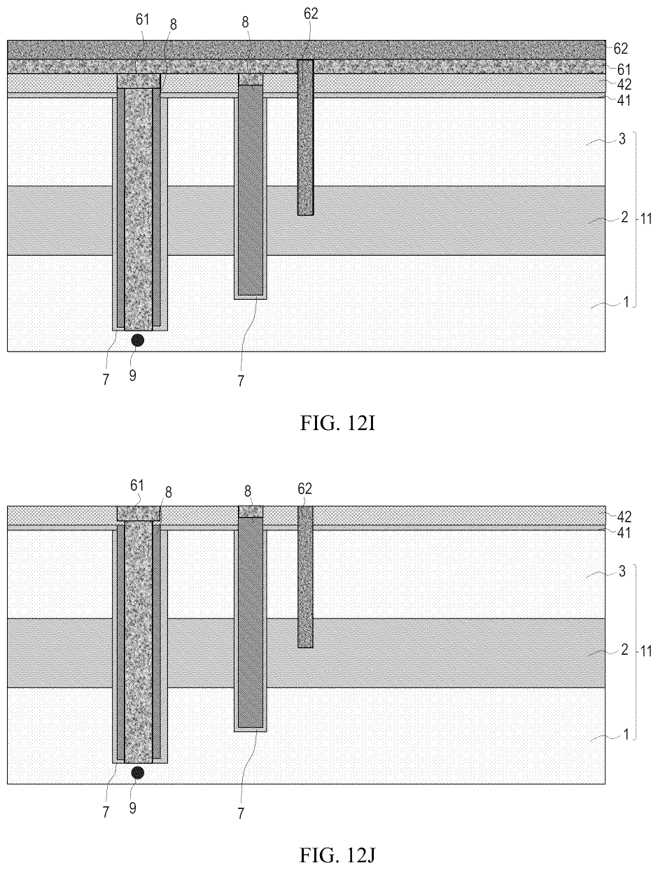

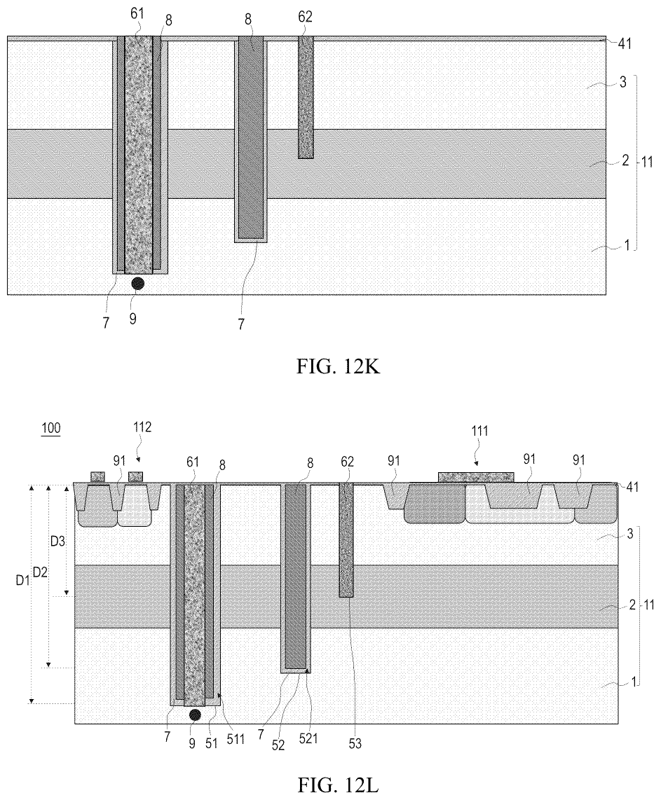

FIG. 12A to FIG. 12L show a process for fabricating a semiconductor device 100 according to a twelfth embodiment of the present disclosure. The process shown in FIG. 12A to FIG. 12L may be used to fabricate the semiconductor device 100 shown in FIG. 8. The foregoing description of the semiconductor device 100 with reference to FIG. 8 may be combined herein.

A structure shown in FIG. 12A is similar to the structure shown in FIG. 2I. A specific description of a formation process of the structure shown in FIG. 12A is omitted herein. For example steps, reference may be made to the descriptions with reference to FIG. 2A to FIG. 2I. For example, the hard mask layer 4 and the semiconductor body 11 may be etched by using a seventh soft mask layer (not shown) to simultaneously form the first trench 51, the second trench 52, and the third trench 53 in the semiconductor body 11. The first trench 51 extends from the top surface of the epitaxial layer 3 into the substrate 1 and has a first depth D1. The second trench 52 extends from the top surface of the epitaxial layer 3 into the substrate 1 and has a second depth D2 less than the first depth D1. The third trench 53 extends from the top surface of the epitaxial layer 3 into the buried layer 2 and has a third depth D3 less than the second depth D2. In addition, as shown in FIG. 12A, a pad 7 has been formed on a sidewall and a bottom of each of the first trench 51, the second trench 52, and the third trench 53.

As shown in FIG. 12B, the dielectric layer 8 is deposited so that the dielectric layer 8 forms, in the first trench 51, a second opening 54 that extends from the top surface of the epitaxial layer 3 toward the bottom of the first trench 51, and the dielectric layer 8 completely fills the second trench 52 and the third trench 53. In some embodiments, the dielectric layer 8 may partially fill the second trench 52. This can reduce stress on one hand, and reduce parasitic capacitance on the other hand. For example, an air gap may be formed in the dielectric layer 8 in the second trench 52. In an embodiment, the dielectric layer 8 comprises oxide such as silicon oxide. Another type of dielectric layer is also feasible. The pad 7 and the dielectric layer 8 in the second trench 52 form the second deep trench isolation structure 521, and the pad 7 and the dielectric layer 8 in the third trench 53 form the temporary deep trench structure 534.

As shown in FIG. 12C, anisotropic etching is performed on the dielectric layer 8 and the pad 7 to remove the dielectric layer 8 from a top surface of the nitride layer 42, and to extend the second opening 54 to the pad 7 at the bottom of the first trench 51, and to form a first opening 71 aligned with the second opening 54 in the pad 7 at the bottom of the first trench 51.

As shown in FIG. 12D, ion implantation is performed on the substrate 1 through the second opening 54 and the first opening 71 to form, in the substrate 1, a second doped region 9 near the bottom of the first trench 51. The second doped region 9 has the first doping type and has a doping concentration higher than that of the substrate 1. When the doping concentration of the substrate 1 is high, the second doped region 9 may be omitted. In addition, in some embodiments, before the anisotropic etching is performed on the dielectric layer 8 and the pad 7, ion implantation may be performed in the substrate 1 near the bottom of the first trench 51 to form the second doped region 9.

As shown in FIG. 12E, the first conductive material 61 is deposited so that the first conductive material 61 fills the first opening 71 and the second opening 54, and covers the top surface of the nitride layer 42. In an embodiment, the first conductive material 61 comprises polysilicon having the first doping type. Another type of first conductive material 61 is also feasible. The pad 7, the dielectric layer 8, and the first conductive material 61 in the first trench 51 may form the first deep trench structure 511. Because the first conductive material 61 extends from the top surface of the epitaxial layer 3 to the bottom of the first trench 51 and is in contact with the substrate 1, the first conductive material 61 can be used as a pickup structure of the substrate 1 to electrically connect the substrate 1 to the top surface of the epitaxial layer 3. In addition, because the pad 7 and the dielectric layer 8 that are disposed in the first trench 51 extend from the top surface of the epitaxial layer 3 to the bottom of the trench, different component regions can be isolated to some extent, thereby enhancing isolation performance.

As shown in FIG. 12F, the temporary deep trench structure 534 in the third trench 53 is etched by using the eighth soft mask layer 103 to remove a portion of the temporary deep trench structure 534 in the third trench 53, thereby forming a second shallow trench 532.

As shown in FIG. 12G, a sidewall spacer 556 is formed on a sidewall of each of a third trench opening 530 in the hard mask layer 4 and the second shallow trench 532. In an embodiment, the sidewall spacer 556 comprises nitride or polysilicon. Another type of sidewall spacer is feasible.

As shown in FIG. 12H, the remaining portion of the temporary deep trench structure 534 is etched to remove the remaining portion of the temporary deep trench structure 534 in the third trench 53. In the process of etching the remaining portion of the temporary deep trench structure 534, the sidewall spacer 556 may protect the first oxide layer 41 against etching. Subsequently, the sidewall spacer 556 may be removed through isotropic etching.

As shown in FIG. 12I, the third trench 53 is filled with a second conductive material 62, wherein the second conductive material 62 is configured to electrically connect the buried layer 2 to the top surface of the epitaxial layer 3. In an embodiment, the second conductive material 62 comprises polysilicon having the second doping type. Another type of second conductive material is feasible. The second conductive material 62 can be used as a pickup structure of the buried layer 2 to connect the buried layer 2 to the top surface of the epitaxial layer 3. Compared with an embodiment in which a diffusion region is used as a pickup structure, using polysilicon as a pickup structure of the buried layer 2 can better electrically connect the buried layer 2 to the top surface of the epitaxial layer 3. In some embodiments, a thermal annealing step may be performed to drive a dopant in the polysilicon to a neighboring region in the epitaxial layer 3 to form a diffusion region. The polysilicon and the neighboring diffusion region may jointly form a pickup structure of the buried layer 2. In addition, the polysilicon has almost the same thermal expansion coefficient as monocrystalline silicon in the semiconductor body 11, and therefore can reduce a lattice defect caused by mechanical stress.

As shown in FIG. 12J, the extra first conductive material 61 or diffusion material is removed by using a chemical mechanical polishing (CMP) process, and then an etch back process is performed. In some embodiments, CMP may not be performed, and the etch back process is directly performed.

As shown in FIG. 12K, the nitride layer 42 is stripped.

As shown in FIG. 12L, a plurality of component regions may be formed in the epitaxial layer 3. For purposes of illustration, a first component region 111 and a second component region 112 are shown in the epitaxial layer 3 shown in FIG. 11J. For example, the first component region 111 may be a high voltage (HV) component region of an HV component (such as an HV transistor). In an embodiment, an LDMOS transistor 140 may be formed in the first component region 111, and a plurality of isolation regions 91, such as STI regions, may be formed in the first component region 111 to isolate different doped regions in the epitaxial layer 3. The second component region 112 can be used as a low voltage (LV) or medium voltage (MV) component region. In an embodiment, a first transistor 112a and a second transistor 112b may be formed in the second component region 112, and a plurality of isolation regions 91, such as shallow trench isolation (STI) regions, may be formed in the second component region 112 to isolate the first transistor 112a from the second transistor 112b. Regarding the exemplary structures of the LDMOS transistor 140, the first transistor 112a, and the second transistor 112b, reference may be made to the foregoing description with reference to FIG. 1, FIG. 6, and FIG. 8, and details are not described herein again.

It should be understood that, in some embodiments, when the low voltage component region and the medium voltage component region are isolated, formation of the second deep trench isolation structure 521 may be omitted, and the first deep trench structure 511 and the second conductive material 62 are formed between different component regions. To this end, the first trench opening 510 and the third trench opening 530 that penetrate through the hard mask layer 4 are simultaneously formed in the hard mask layer 4, and the second trench opening 520 is not formed. In addition, the first trench 51 aligned with the first trench opening 510 and the third trench 53 aligned with the third trench opening 530 are formed in the semiconductor body 11, and the second trench 52 aligned with the second trench opening 520 is not formed. In this way, in a subsequent fabricating step, for example, in the step of forming the pad 7 shown in FIG. 12A and the step of forming the dielectric layer 8 shown in FIG. 12B, no operation is performed regarding the second trench 52, and the second deep trench isolation structure 521 is not formed. In such an embodiment, except that the second trench 52 and the second deep trench isolation structure 521 are not formed, another fabricating step of the semiconductor device 100 is similar to the fabricating step of the semiconductor device 100 described with reference to FIG. 12A to FIG. 12L, and details are not described herein again.

In addition, it should be understood that in some embodiments, only isolation between component regions and electrical connection of the buried layer 2 to the surface of the epitaxial layer 3 may need to be implemented between some component regions, without requiring a pickup structure of the substrate 1. Formation of the first deep trench structure 511 may be omitted between such component regions, and the second deep trench isolation structure 521 and the second conductive material 62 are formed between different component regions. To this end, the second trench opening 520 and the third trench opening 530 that penetrate through the hard mask layer 4 are simultaneously formed in the hard mask layer 4, and the first trench opening 510 is not formed. In addition, the second trench 52 aligned with the second trench opening 520 and the third trench 53 aligned with the third trench opening 530 are formed in the semiconductor body 11, and the first trench 51 aligned with the first trench opening 510 is not formed. In this way, in a subsequent fabricating step, for example, in the step of forming the pad 7 shown in FIG. 12A and the step of forming the dielectric layer 8 shown in FIG. 12B, no operation is performed regarding the first trench 51, and the first deep trench structure 511 is not formed. In addition, subsequent steps of fabricating the first trench 51 and the first deep trench structure 511 may also be omitted. For example, the following steps may be omitted: the step of extending the second opening 54 to the pad 7 at the bottom of the first trench 51, and forming the first opening 71 aligned with the second opening 54 in the pad 7 at the bottom of the first trench 51 in FIG. 12C, and the step (if any) of forming the second doped region 9 in FIG. 12D; and the step of forming the first conductive material 61 in FIG. 12E. In such an embodiment, except that the first trench 51 and the first deep trench structure 511 are not formed, another fabricating step of the semiconductor device 100 is similar to the fabricating step of the semiconductor device 100 described with reference to FIG. 12A to FIG. 12L, and details are not described herein again.

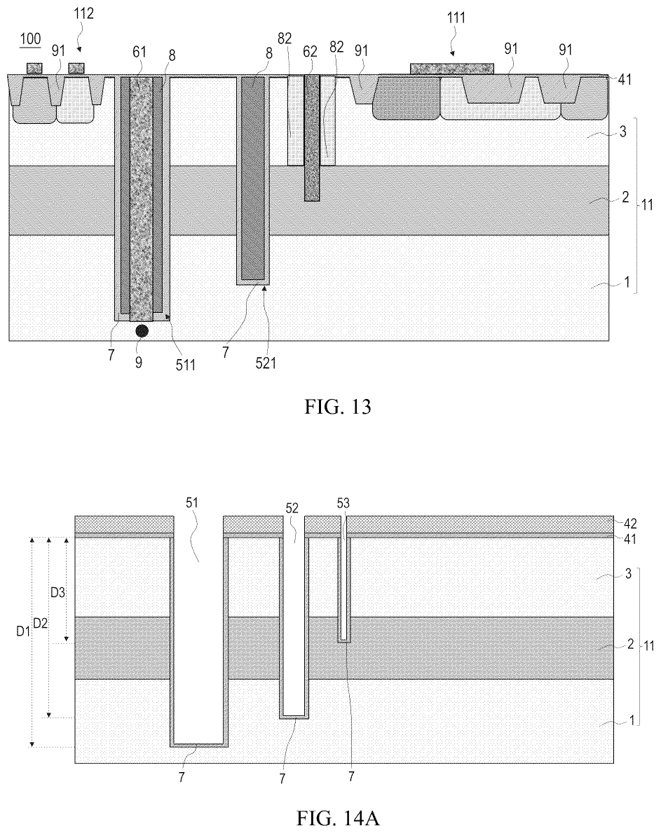

FIG. 13 illustratively shows a cross-sectional view of a semiconductor device 100 according to a thirteenth embodiment of the present disclosure. A structure of the semiconductor device 100 shown in FIG. 13 is similar to the structure of the semiconductor device 100 shown in FIG. 8. A difference lies in that a first doped region 82 is formed in the epitaxial layer 3 and near a sidewall of the third trench 53, and the first doped region 82 has a second doping type. With this arrangement, the second conductive material 62 and the first doped region 82 may jointly form a pickup structure of the buried layer 2. In addition, another structure of the semiconductor device 100 shown in FIG. 13 is similar to a structure of the semiconductor device 100 shown in FIG. 8, and details are not described herein again.

It should be understood that, in some embodiments, when the low voltage component region and the medium voltage component region are isolated, the second deep trench isolation structure 521 may be omitted, and the first deep trench structure 511, the second conductive material 62, and the first doped region 82 are disposed between different component regions. In such an embodiment, except that the second trench 52 and the second deep trench isolation structure 521 are not comprised, another structure of the semiconductor device 100 is similar to that of the semiconductor device 100 described with reference to FIG. 13, and details are not described herein again.

In addition, it should be understood that in some embodiments, only isolation between component regions and electrical connection of the buried layer 2 to the surface of the epitaxial layer 3 may need to be implemented between some component regions, without requiring a pickup structure of the substrate 1. The first deep trench structure 511 may be omitted between such component regions, and the second deep trench isolation structure 521, the second conductive material 62, and the first doped region 82 are disposed between different component regions. In such an embodiment, except that the first trench 51 and the first deep trench structure 511 are not comprised, another structure of the semiconductor device 100 is similar to that of the semiconductor device 100 described with reference to FIG. 13, and details are not described herein again.

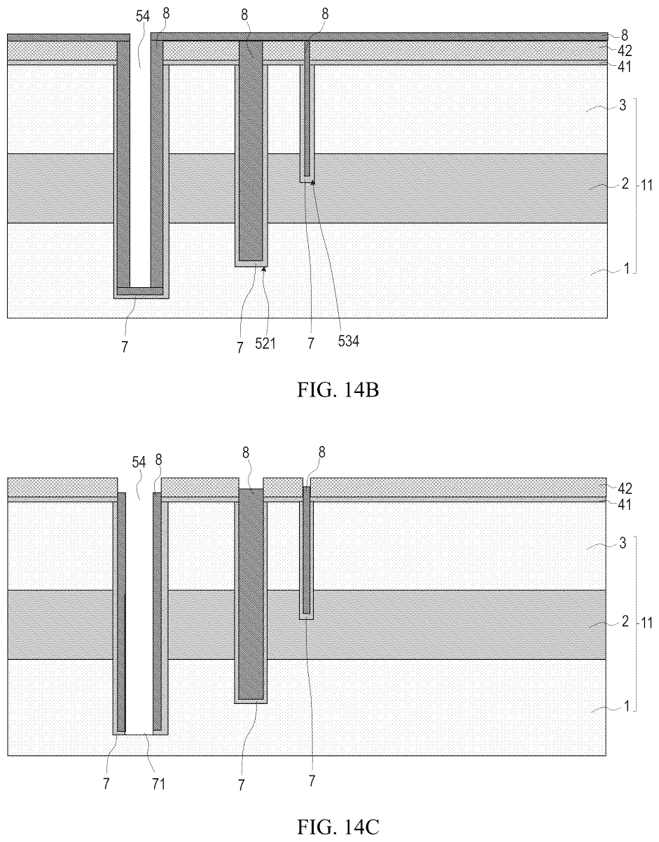

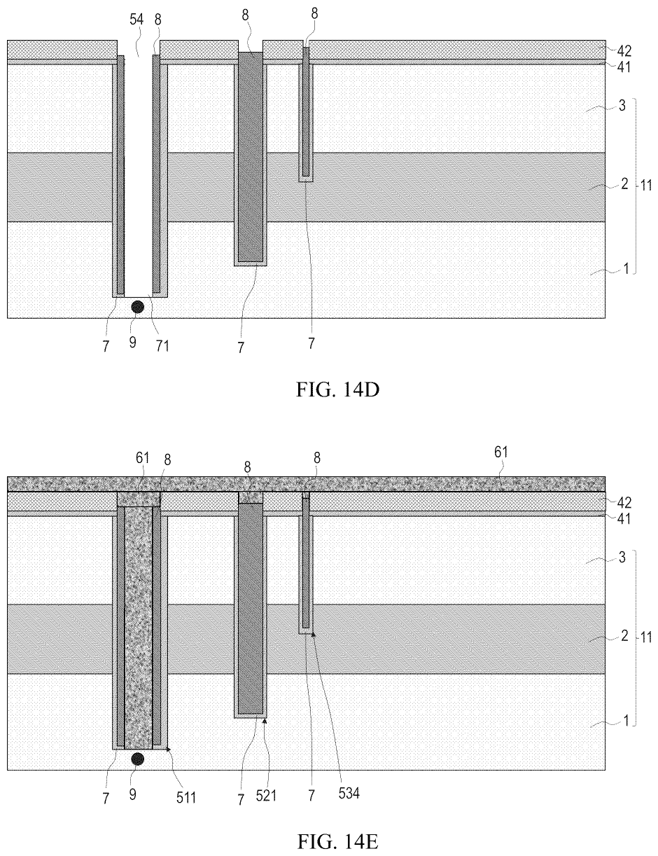

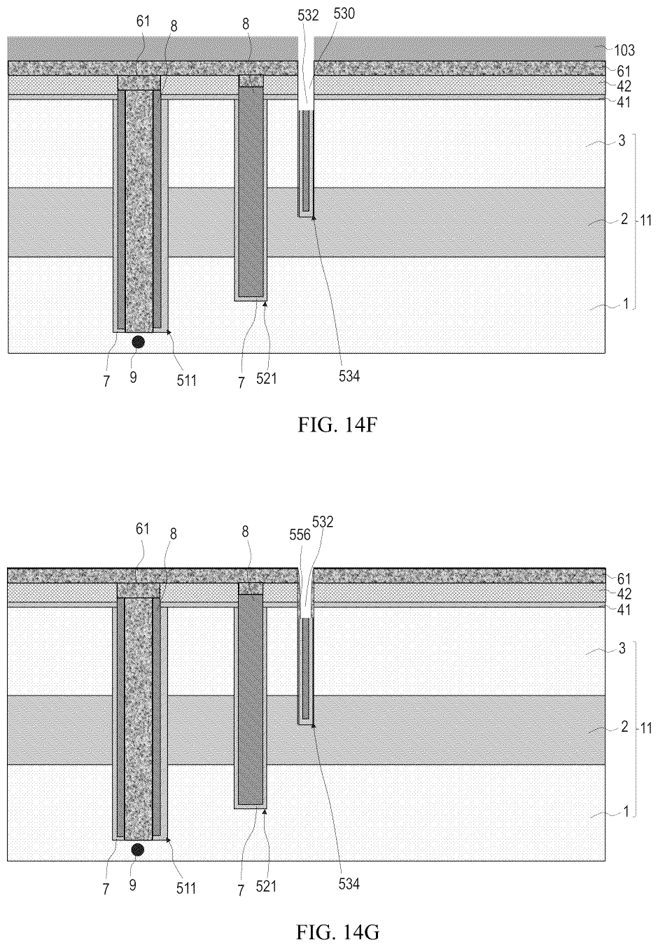

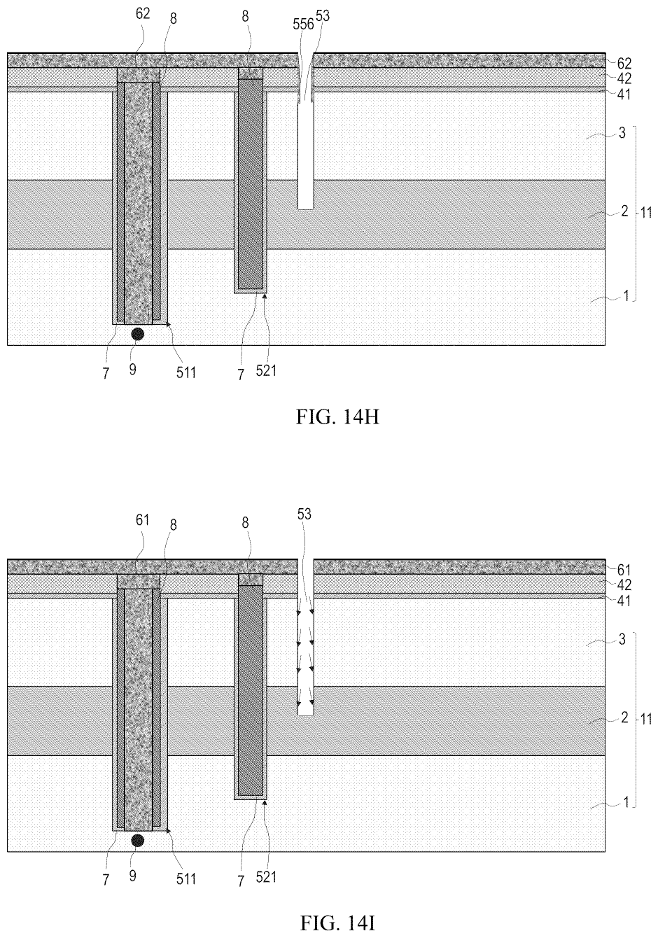

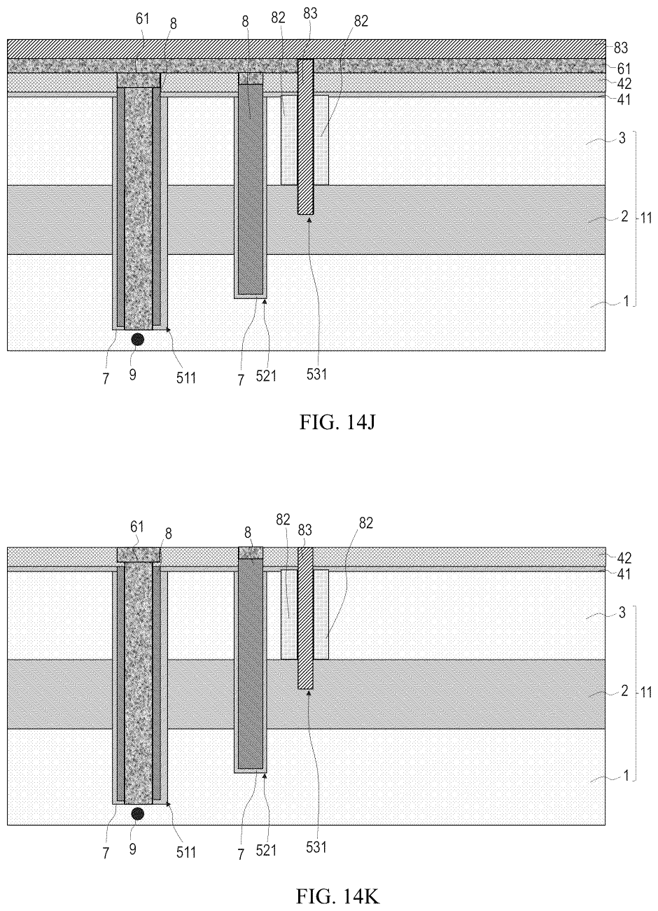

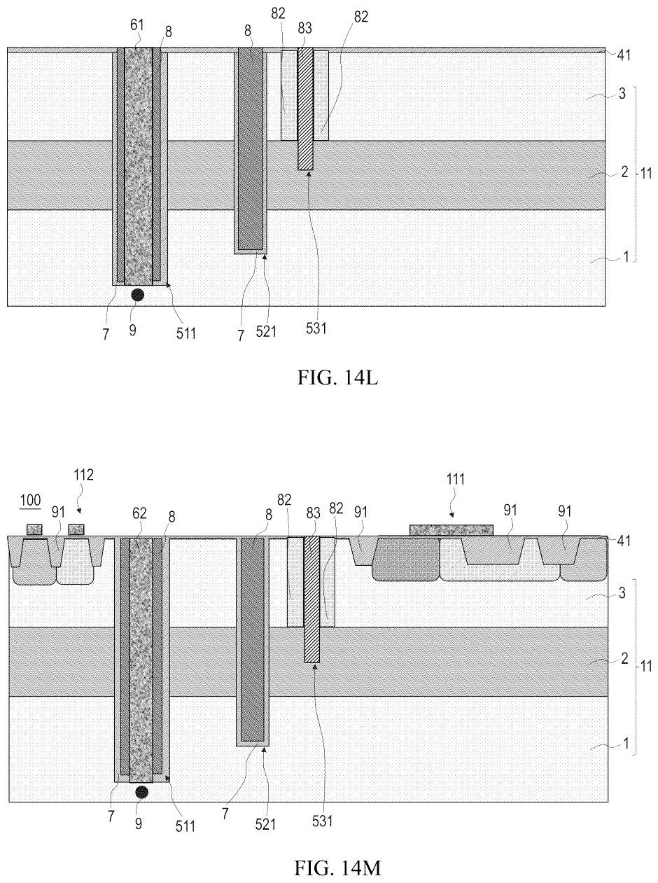

FIG. 14A to FIG. 14M show a process for fabricating a semiconductor device 100 according to a fourteenth embodiment of the present disclosure.

A structure shown in FIG. 14A is similar to the structure shown in FIG. 2I. A specific description of a formation process of the structure shown in FIG. 14A is omitted herein. For example steps, reference may be made to the descriptions with reference to FIG. 2A to FIG. 2I. For example, the hard mask layer 4 and the semiconductor body 11 may be etched by using a seventh soft mask layer (not shown) to simultaneously form the first trench 51, the second trench 52, and the third trench 53 in the semiconductor body 11. The first trench 51 extends from the top surface of the epitaxial layer 3 into the substrate 1 and has a first depth D1. The second trench 52 extends from the top surface of the epitaxial layer 3 into the substrate 1 and has a second depth D2 less than the first depth D1. The third trench 53 extends from the top surface of the epitaxial layer 3 into the buried layer 2 and has a third depth D3 less than the second depth D2. In addition, as shown in FIG. 14A, a pad 7 has been formed on a sidewall and a bottom of each of the first trench 51, the second trench 52, and the third trench 53.

As shown in FIG. 14B, the dielectric layer 8 is deposited so that the dielectric layer 8 forms, in the first trench 51, a second opening 54 that extends from the top surface of the epitaxial layer 3 toward the bottom of the first trench 51, and the dielectric layer 8 completely fills the second trench 52 and the third trench 53. In some embodiments, the dielectric layer 8 may partially fill the second trench 52. This can reduce stress on one hand, and reduce parasitic capacitance on the other hand. For example, an air gap may be formed in the dielectric layer 8 in the second trench 52. In an embodiment, the dielectric layer 8 comprises oxide such as silicon oxide. Another type of dielectric layer is also feasible. The pad 7 and the dielectric layer 8 in the second trench 52 form the second deep trench isolation structure 521, and the pad 7 and the dielectric layer 8 in the third trench 53 form the temporary deep trench structure 534.

As shown in FIG. 14C, anisotropic etching is performed on the dielectric layer 8 and the pad 7 to remove the dielectric layer 8 from a top surface of the nitride layer 42, and to extend the second opening 54 to the pad 7 at the bottom of the first trench 51, and to form a first opening 71 aligned with the second opening 54 in the pad 7 at the bottom of the first trench 51.

As shown in FIG. 14D, ion implantation is performed on the substrate 1 through the second opening 54 and the first opening 71 to form, in the substrate 1, a second doped region 9 near the bottom of the first trench 51. The second doped region 9 has the first doping type and has a doping concentration higher than that of the substrate 1. When the doping concentration of the substrate 1 is high, the second doped region 9 may be omitted. In addition, in some embodiments, before the anisotropic etching is performed on the dielectric layer 8 and the pad 7, ion implantation may be performed in the substrate 1 near the bottom of the first trench 51 to form the second doped region 9.

As shown in FIG. 14E, the first conductive material 61 is deposited so that the first conductive material 61 fills the first opening 71 and the second opening 54, and covers the top surface of the nitride layer 42. In an embodiment, the first conductive material 61 comprises polysilicon having the first doping type. Another type of first conductive material 61 is also feasible. The pad 7, the dielectric layer 8, and the first conductive material 61 in the first trench 51 may form the first deep trench structure 511. Because the first conductive material 61 extends from the top surface of the epitaxial layer 3 to the bottom of the first trench 51 and is in contact with the substrate 1, the first conductive material 61 can be used as a pickup structure of the substrate 1 to electrically connect the substrate 1 to the top surface of the epitaxial layer 3. In addition, because the pad 7 and the dielectric layer 8 that are disposed in the first trench 51 extend from the top surface of the epitaxial layer 3 to the bottom of the trench, different component regions can be isolated to some extent, thereby enhancing isolation performance.

As shown in FIG. 14F, the temporary deep trench structure 534 in the third trench 53 is etched by using the eighth soft mask layer 103 to remove a portion of the temporary deep trench structure 534 in the third trench 53, thereby forming a second shallow trench 532.

As shown in FIG. 14G, a sidewall spacer 556 is formed on a sidewall of each of a third trench opening 530 in the hard mask layer 4 and the second shallow trench 532. In an embodiment, the sidewall spacer 556 comprises nitride or polysilicon. Another type of sidewall spacer is feasible.

As shown in FIG. 14H, the remaining portion of the temporary deep trench structure 534 is etched to remove the remaining portion of the temporary deep trench structure 534 in the third trench 53. In the process of etching the remaining portion of the temporary deep trench structure 534, the sidewall spacer 556 may protect the first oxide layer 41 against etching. Subsequently, the sidewall spacer 556 may be removed through isotropic etching.

As shown in FIG. 14I, the dopant of the second doping type is obliquely implanted, in the third trench 53, into the semiconductor body 11.

Subsequently, as shown in FIG. 14J, thermal annealing is performed to form, in the epitaxial layer 3, the first doped region 82 having the second doping type near the sidewall of the third trench 53. The first doped region 82 extends from the top surface of the epitaxial layer 3 to the buried layer 2 to electrically connect the buried layer 2 to the top surface of the epitaxial layer 3. Because the first doped region 82 and the buried layer 2 have the same doping type, the first doped region 82 can be used as a pickup structure of the buried layer 2, so as to connect the buried layer 2 to the top surface of the epitaxial layer 3 at low resistivity. Subsequently, the third trench 53 is filled with a dielectric material 83 to form a third deep trench isolation structure 531. In an embodiment, the dielectric material 83 comprises oxide or undoped polysilicon. Another type of dielectric material is feasible.

As shown in FIG. 14K, an extra dielectric material 83 and the extra first conductive material 61 are removed by using a chemical mechanical polishing (CMP) process, and then an etch back process is performed. In some embodiments, CMP may not be performed, and the etch back process is directly performed.

As shown in FIG. 14L, the nitride layer 42 is stripped.

As shown in FIG. 14M, a plurality of component regions may be formed in the epitaxial layer 3. For purposes of illustration, a first component region 111 and a second component region 112 are shown in the epitaxial layer 3 shown in FIG. 14M. For example, the first component region 111 may be a high voltage (HV) component region of an HV component (such as an HV transistor). In an embodiment, an LDMOS transistor 140 may be formed in the first component region 111, and a plurality of isolation regions 91, such as STI regions, may be formed in the first component region 111 to isolate different doped regions in the epitaxial layer 3. The second component region 112 can be used as a low voltage (LV) or medium voltage (MV) component region. In an embodiment, a first transistor 112a and a second transistor 112b may be formed in the second component region 112, and a plurality of isolation regions 91, such as shallow trench isolation (STI) regions, may be formed in the second component region 112 to isolate the first transistor 112a from the second transistor 112b. Regarding the exemplary structures of the LDMOS transistor 140, the first transistor 112a, and the second transistor 112b, reference may be made to the foregoing description with reference to FIG. 1, FIG. 6, and FIG. 8, and details are not described herein again.

It should be understood that, in some embodiments, when the low voltage component region and the medium voltage component region are isolated, formation of the second deep trench isolation structure 521 may be omitted, and the first deep trench structure 511, the third deep trench isolation structure 531, and the first doped region 82 are formed between different component regions. To this end, the first trench opening 510 and the third trench opening 530 that penetrate through the hard mask layer 4 are simultaneously formed in the hard mask layer 4, and the second trench opening 520 is not formed. In addition, the first trench 51 aligned with the first trench opening 510 and the third trench 53 aligned with the third trench opening 530 are formed in the semiconductor body 11, and the second trench 52 aligned with the second trench opening 520 is not formed. In this way, in a subsequent fabricating step, for example, in the step of forming the pad 7 shown in FIG. 14A and the step of forming the dielectric layer 8 shown in FIG. 14B, no operation is performed regarding the second trench 52, and the second deep trench isolation structure 521 is not formed. In such an embodiment, except that the second trench 52 and the second deep trench isolation structure 521 are not formed, another fabricating step of the semiconductor device 100 is similar to the fabricating step of the semiconductor device 100 described with reference to FIG. 14A to FIG. 14M, and details are not described herein again.

In addition, it should be understood that in some embodiments, only isolation between component regions and electrical connection of the buried layer 2 to the surface of the epitaxial layer 3 may need to be implemented between some component regions, without requiring a pickup structure of the substrate 1. Formation of the first deep trench structure 511 may be omitted between such component regions, and the second deep trench isolation structure 521, the third deep trench isolation structure 531, and the first doped region 82 are formed between different component regions. To this end, the second trench opening 520 and the third trench opening 530 that penetrate through the hard mask layer 4 are simultaneously formed in the hard mask layer 4, and the first trench opening 510 is not formed. In addition, the second trench 52 aligned with the second trench opening 520 and the third trench 53 aligned with the third trench opening 530 are formed in the semiconductor body 11, and the first trench 51 aligned with the first trench opening 510 is not formed. In this way, in a subsequent fabricating step, for example, in the step of forming the pad 7 shown in FIG. 14A and the step of forming the dielectric layer 8 shown in FIG. 14B, no operation is performed regarding the first trench 51, and the first deep trench structure 511 is not formed. In addition, subsequent steps of fabricating the first trench 51 and the first deep trench structure 511 may also be omitted. For example, the following steps may be omitted: the step of extending the second opening 54 to the pad 7 at the bottom of the first trench 51, and forming the first opening 71 aligned with the second opening 54 in the pad 7 at the bottom of the first trench 51 in FIG. 14C, and the step (if any) of forming the second doped region 9 in FIG. 14D; and the step of forming the first conductive material 61 in FIG. 14E. In such an embodiment, except that the first trench 51 and the first deep trench structure 511 are not formed, another fabricating step of the semiconductor device 100 is similar to the fabricating step of the semiconductor device 100 described with reference to FIG. 14A to FIG. 14M, and details are not described herein again.

Exemplary embodiments of the present disclosure are further reflected in the following three sets of clauses.

### FIRST SET OF CLAUSES

1. A method for fabricating a semiconductor device (100), comprising:
providing a semiconductor body (11), wherein the semiconductor body (11) comprises a substrate (1), a buried layer (2) disposed on the substrate (1), and an epitaxial layer (3) disposed on the buried layer (2), the substrate (1) has a first doping type, and the buried layer (2) has a second doping type opposite to the first doping type;
forming a hard mask layer (4) on a top surface of the epitaxial layer (3);
etching the hard mask layer (4) and the semiconductor body (11) by using a single soft mask layer (10) to simultaneously form a first trench (51), a second trench (52), and a third trench (53) in the semiconductor body (11), wherein the first trench (51) extends from the top surface of the epitaxial layer (3) into the substrate (1) and has a first depth (D1), the second trench (52) extends from the top surface of the epitaxial layer (3) into the substrate (1) and has a second depth (D2), and the third trench (53) extends from the top surface of the epitaxial layer (3) into the buried layer (2) or to a position in the epitaxial layer (3) and near the buried layer (2) and has a third depth (D3) less than the second depth (D2);
forming, in the epitaxial layer (3), a first doped region (82) having the second doping type near a sidewall of the third trench (53), wherein the first doped region (82) extends from the top surface of the epitaxial layer (3) to the buried layer (2), and is configured to electrically connect the buried layer (2) to the top surface of the epitaxial layer (3);
forming a first deep trench structure (511) in the first trench (51), wherein the first deep trench structure (511) is configured to electrically connect the substrate (1) to the top surface of the epitaxial layer (3);
forming a second deep trench isolation structure (521) in the second trench (52), wherein the second deep trench isolation structure (521) is configured to isolate different component regions in the epitaxial layer (3); and forming a third deep trench isolation structure (531) in the third trench (53), wherein the third deep trench isolation structure (531) is configured to isolate different component regions in the epitaxial layer (3).

2. The method according to clause 1, wherein forming the hard mask layer (4) comprises:
growing a first oxide layer (41) on the top surface of the epitaxial layer (3);
depositing a nitride layer (42) on the first oxide layer (41); and
depositing a second oxide layer (43) on the nitride layer (42).

3. The method according to clause 1, wherein etching the hard mask layer (4) and the semiconductor body (11) by using the single soft mask layer (10) comprises:
performing first etching on the hard mask layer (4) by using the single soft mask layer (10) to simultaneously form, in the hard mask layer (4), a first trench opening (510), a second trench opening (520), and a third trench opening (530) that penetrate through the hard mask layer (4);
stripping the single soft mask layer (10); and
performing second etching on the semiconductor body (11) by using the hard mask layer (4) to form, in the semiconductor body (11), the first trench (51) aligned with the first trench opening (510), the second trench (52) aligned with the second trench opening (520), and the third trench (53) aligned with the third trench opening (530).

4. The method according to clause 1, wherein etching the hard mask layer (4) and the semiconductor body (11) by using the single soft mask layer (10) comprises:
performing first etching on the hard mask layer (4) and the epitaxial layer (3) by using the single soft mask layer (10) to simultaneously form, in the hard mask layer (4), a first trench opening (510), a second trench opening (520), and a third trench opening (530) that penetrate through the hard mask layer (4), and to form, in the epitaxial layer (3), a first shallow trench (555) aligned with each of the first trench opening (510), the second trench opening (520), and the third trench opening (530);
forming a sidewall spacer (556) on a sidewall of each of the first trench opening (510), the second trench opening (520), the third trench opening (530), and the first shallow trench (555); and
performing second etching on the semiconductor body (11) via the first shallow trench (555) to form, in the semiconductor body (11), the first trench (51) aligned with the first trench opening (510), the second trench (52) aligned with the second trench opening (520), and the third trench (53) aligned with the third trench opening (530).

5. The method according to clause 4, further comprising:
removing the sidewall spacer (556) through isotropic etching after the first doped region (82) is formed.

6. The method according to clause 4, wherein the sidewall spacer (556) comprises nitride.

7. The method according to clause 1, wherein etching the hard mask layer (4) and the semiconductor body (11) by using the single soft mask layer (10) comprises:
performing single etching on the hard mask layer (4) and the semiconductor body (11) by using the single soft mask layer (10) to simultaneously form, in the hard mask layer (4), a first trench opening (510), a second trench opening (520), and a third trench opening (530) that penetrate through the hard mask layer (4), and to simultaneously form, in the semiconductor body (11), the first trench (51) aligned with the first trench opening (510), the second trench (52) aligned with the second trench opening (520), and the third trench (53) aligned with the third trench opening (530).

8. The method according to clause 1, wherein forming the first deep trench structure (511) in the first trench (51) comprises:
forming a pad (7) on a sidewall and a bottom of the first trench (51);
forming a dielectric layer (8) inside the pad (7) in the first trench (51), wherein the dielectric layer (8) comprises a second opening (54) extending from the top surface of the epitaxial layer (3) toward the bottom of the first trench (51);
performing anisotropic etching on the dielectric layer (8) and the pad (7) in the first trench (51), so that the second opening (54) extends to the pad (7) at the bottom of the first trench (51), and a first opening (71) aligned with the second opening (54) is formed in the pad (7) at the bottom of the first trench (51); and
filling the first opening (71) and the second opening (54) with a first conductive material (61), wherein the first conductive material (61) is configured to electrically connect the substrate (1) to the top surface of the epitaxial layer (3).

9. The method according to clause 8, wherein the first conductive material (61) comprises polysilicon having the first doping type.

10. The method according to clause 8, further comprising:
forming a second doped region (9) in the substrate (1) near the bottom of the first trench (51), wherein the second doped region (9) has the first doping type and has a doping concentration higher than that of the substrate (1).

11. The method according to clause 1, wherein forming the second deep trench isolation structure (521) in the second trench (52) comprises:
forming a pad (7) on a sidewall and a bottom of the second trench (52); and
forming a dielectric layer (8) inside the pad (7) in the second trench (52), wherein the dielectric layer (8) completely or partially fills the second trench (52).

12. The method according to clause 1, wherein forming the third deep trench isolation structure (531) in the third trench (53) comprises:
forming a pad (7) on a sidewall and a bottom of the third trench (53); and
forming a dielectric layer (8) inside the pad (7) in the third trench (53), wherein the dielectric layer (8) completely fills the third trench (53).

13. The method according to clause 1, wherein forming, in the epitaxial layer (3), the first doped region (82) having the second doping type near the sidewall of the third trench (53) comprises:
depositing a diffusion material (81) in the third trench (53), wherein the diffusion material (81) comprises a dopant of the second doping type; and
performing thermal annealing on the diffusion material (81), so that the dopant is diffused into a region of the epitaxial layer (3) near the sidewall of the third trench (53) to form the first doped region (82).

14. The method according to clause 13, wherein the diffusion material (81) partially fills the third trench (53), and wherein forming the third deep trench isolation structure (531) in the third trench (53) comprises:
continuing to fill the third trench (53) with a dielectric material to seal the diffusion material (81), wherein the diffusion material (81) and the dielectric material jointly form the third deep trench isolation structure (531).

15. The method according to clause 13, wherein when the first doping type is a p-type, the diffusion material (81) comprises at least one of POCl3 glass and phosphate silicate glass, and the dopant is a phosphorus element; and
when the first doping type is an n-type, the diffusion material (81) comprises borosilicate glass, and the dopant is a boron element.

16. The method according to clause 13, wherein the first doped region (82) is formed near both sides of the third trench (53).

17. The method according to clause 13, wherein the diffusion material (81) completely or partially fills the third trench (53).

18. The method according to clause 17, wherein an air gap (810) is formed inside the diffusion material (81).

19. The method according to clause 13, further comprising:
etching the diffusion material (81) in the third trench (53) to remove the diffusion material (81).

20. The method according to clause 19, wherein the second depth (D2) is less than the first depth (D1), and the formation of the first deep trench structure (511), the second deep trench isolation structure (521), and the third deep trench isolation structure (531) comprises: forming a pad (7) on a sidewall and a bottom of each of the first trench (51), the second trench (52), and the third trench (53); and
forming a dielectric layer (8) inside the pad (7) in the first trench (51), the second trench (52), and the third trench (53), so that the dielectric layer (8) forms, in the first trench (51), a second opening (54) that extends from the top surface of the epitaxial layer (3) toward the bottom of the first trench (51), and the dielectric layer (8) completely fills the second trench (52) and the third trench (53), wherein the pad (7) and the dielectric layer (8) in the second trench (52) form the second deep trench isolation structure (521), and the pad (7) and the dielectric layer (8) in the third trench (53) form the third deep trench isolation structure (531).

21. The method according to clause 20, wherein the formation of the first deep trench structure (511) further comprises:
performing anisotropic etching on the dielectric layer (8) and the pad (7), so that the second opening (54) extends to the pad (7) at the bottom of the first trench (51), and a first opening (71) aligned with the second opening (54) is formed in the pad (7) at the bottom of the first trench (51);
performing ion implantation on the substrate (1) through the second opening (54) and the first opening (71) to form a second doped region (9) in the substrate (1) near the bottom of the first trench (51), wherein the second doped region (9) has the first doping type and has a doping concentration higher than that of the substrate (1); and filling the first opening (71) and the second opening (54) with a first conductive material (61) to form the first deep trench structure (511).

22. The method according to clause 1, further comprising: performing ion implantation on the substrate (1) near a bottom of the first trench (51) and/or a bottom of the second trench (52) to form a doped region, wherein the doped region has the first doping type and has a doping concentration higher than that of the substrate (1).

23. The method according to clause 22, further comprising: forming a thin protective layer in the first trench (51) and the second trench (52) and on an upper surface of the third trench (53) prior to the ion implantation.

24. The method according to clause 1, wherein forming, in the epitaxial layer (3), the first doped region (82) having the second doping type near the sidewall of the third trench (53) comprises:
forming the first doped region (82) by implanting, at an oblique angle, a dopant of the second doping type through the sidewall of the third trench (53).

25. The method according to clause 1, further comprising:
forming a shallow trench isolation region (91) in the epitaxial layer (3).

26. The method according to clause 1, further comprising:
forming at least one transistor in the epitaxial layer (3).

27. A method for fabricating a semiconductor device (100), comprising:
providing a semiconductor body (11), wherein the semiconductor body (11) comprises a substrate (1), a buried layer (2) disposed on the substrate (1), and an epitaxial layer (3) disposed on the buried layer (2), the substrate (1) has a first doping type, and the buried layer (2) has a second doping type opposite to the first doping type;
forming a hard mask layer (4) on a top surface of the epitaxial layer (3);
performing first etching on the hard mask layer (4) by using a first soft mask layer (101) to simultaneously form, in the hard mask layer (4), a first trench opening (510), a second trench opening (520), and a third trench opening (530) that penetrate through the hard mask layer (4);
stripping the first soft mask layer (101);
forming a second soft mask layer (102) on the hard mask layer (4), wherein the second soft mask layer (102) comprises a third opening (1021) and the third opening (1021) exposes one or more portions of the hard mask layer (4) near the third trench opening (530); implanting a dopant of the second doping type into the epitaxial layer (3) via the third opening (1021);
stripping the second soft mask layer (102);
performing second etching on the semiconductor body (11) by using the hard mask layer (4) to form, in the semiconductor body (11), a first trench (51) aligned with the first trench opening (510), a second trench (52) aligned with the second trench opening (520), and a third trench (53) aligned with the third trench opening (530);
performing thermal annealing on the dopant to form a first doped region (82) in a region of the epitaxial layer (3) near a sidewall of the third trench (53), wherein the first doped region (82) extends from the top surface of the epitaxial layer (3) to the buried layer (2), and is configured to electrically connect the buried layer (2) to the top surface of the epitaxial layer (3);
forming a first deep trench structure (511) in the first trench (51), wherein the first deep trench structure (511) is configured to electrically connect the substrate (1) to the top surface of the epitaxial layer (3);
forming a second deep trench isolation structure (521) in the second trench (52), wherein the second deep trench isolation structure (521) is configured to isolate different component regions in the epitaxial layer (3); and forming a third deep trench isolation structure (531) in the third trench (53), wherein the third deep trench isolation structure (531) is configured to isolate different component regions in the epitaxial layer (3).

28. The method according to clause 27, wherein when the first doping type is a p-type, the dopant is a phosphorus element; and when the first doping type is an n-type, the dopant is a boron element.

29. The method according to clause 27, wherein the first doped region (82) is formed only near one side of the third trench (53).

30. The method according to clause 29, wherein the first doped region (82) is formed between any two of the first trench (51), the second trench (52), and the third trench (53).

31. The method according to clause 27, wherein the second depth (D2) is less than the first depth (D1), and the formation of the first deep trench structure (511), the second deep trench isolation structure (521), and the third deep trench isolation structure (531) comprises:
forming a pad (7) on a sidewall and a bottom of each of the first trench (51), the second trench (52), and the third trench (53); and
forming a dielectric layer (8) inside the pad (7) in the first trench (51), the second trench (52), and the third trench (53), so that the dielectric layer (8) forms, in the first trench (51), a second opening (54) that extends from the top surface of the epitaxial layer (3) toward the bottom of the first trench (51), and the dielectric layer (8) completely fills the second trench (52) and the third trench (53), wherein the pad (7) and the dielectric layer (8) in the second trench (52) form the second deep trench isolation structure (521), and the pad (7) and the dielectric layer (8) in the third trench (53) form the third deep trench isolation structure (531).

32. The method according to clause 31, wherein the formation of the first deep trench structure (511) further comprises:
performing anisotropic etching on the dielectric layer (8) and the pad (7), so that the second opening (54) extends to the pad (7) at the bottom of the first trench (51), and a first opening (71) aligned with the second opening (54) is formed in the pad (7) at the bottom of the first trench (51);
performing ion implantation on the substrate (1) through the second opening (54) and the first opening (71) to form a second doped region (9) in the substrate (1) near the bottom of the first trench (51), wherein the second doped region (9) has the first doping type and has a doping concentration higher than that of the substrate (1); and
filling the first opening (71) and the second opening (54) with a first conductive material (61) to form the first deep trench structure (511).

33. The method according to clause 27, further comprising: performing ion implantation on the substrate (1) near a bottom of the first trench (51) and/or a bottom of the second trench (52) to form a doped region, wherein the doped region has the first doping type and has a doping concentration higher than that of the substrate (1).

34. The method according to clause 33, further comprising: forming a thin protective layer in the first trench (51) and the second trench (52) and on an upper surface of the third trench (53) prior to the ion implantation.

35. The method according to clause 27, wherein forming the hard mask layer (4) comprises:
growing a first oxide layer (41) on the top surface of the epitaxial layer (3);
depositing a nitride layer (42) on the first oxide layer (41); and
depositing a second oxide layer (43) on the nitride layer (42).

36. The method according to clause 27, wherein forming the first deep trench structure (511) in the first trench (51) comprises:
forming a pad (7) on a sidewall and a bottom of the first trench (51);
forming a dielectric layer (8) inside the pad (7) in the first trench (51), wherein the dielectric layer (8) comprises a second opening (54) extending from the top surface of the epitaxial layer (3) toward the bottom of the first trench (51);
performing anisotropic etching on the dielectric layer (8) and the pad (7) in the first trench (51), so that the second opening (54) extends to the pad (7) at the bottom of the first trench (51), and a first opening (71) aligned with the second opening (54) is formed in the pad (7) at the bottom of the first trench (51); and
filling the first opening (71) and the second opening (54) with a first conductive material (61), wherein the first conductive material (61) is configured to electrically connect the substrate (1) to the top surface of the epitaxial layer (3).

37. The method according to clause 36, wherein the first conductive material (61) comprises polysilicon having the first doping type.

38. The method according to clause 36, further comprising:
forming a second doped region (9) in the substrate (1) near the bottom of the first trench (51), wherein the second doped region (9) has the first doping type and has a doping concentration higher than that of the substrate (1).

39. The method according to clause 27, wherein forming the second deep trench isolation structure (521) in the second trench (52) comprises:
forming a pad (7) on a sidewall and a bottom of the second trench (52); and
forming a dielectric layer (8) inside the pad (7) in the second trench (52), wherein the dielectric layer (8) completely or partially fills the second trench (52).

40. The method according to clause 27, wherein forming the third deep trench isolation structure (531) in the third trench (53) comprises:
forming a pad (7) on a sidewall and a bottom of the third trench (53); and
forming a dielectric layer (8) inside the pad (7) in the third trench (53), wherein the dielectric layer (8) completely fills the third trench (53).

41. The method according to clause 27, further comprising:
forming a shallow trench isolation region (91) in the epitaxial layer (3).

42. The method according to clause 27, further comprising:
forming at least one transistor in the epitaxial layer (3).

43. A semiconductor device (100), comprising:
a semiconductor body (11), wherein the semiconductor body (11) comprises a substrate (1), a buried layer (2) disposed on the substrate (1), and an epitaxial layer (3) disposed on the buried layer (2), the substrate (1) has a first doping type, and the buried layer (2) has a second doping type opposite to the first doping type;
a first trench (51), extending from a top surface of the epitaxial layer (3) into the substrate (1) and having a first depth (D1);
a second trench (52), extending from the top surface of the epitaxial layer (3) into the substrate (1) and having a second depth (D2);
a third trench (53), extending from the top surface of the epitaxial layer (3) into the buried layer (2) and having a third depth (D3) less than the second depth (D2);
a first deep trench structure (511), disposed in the first trench (51) and configured to electrically connect the substrate (1) to the top surface of the epitaxial layer (3);
a second deep trench isolation structure (521), disposed in the second trench (52) and configured to isolate different component regions in the epitaxial layer (3);
a third deep trench isolation structure (531), disposed in the third trench (53) and configured to isolate different component regions in the epitaxial layer (3); and
a first doped region (82), formed in the epitaxial layer (3) near a sidewall of the third trench (53) and having the second doping type, wherein the first doped region (82) extends from the top surface of the epitaxial layer (3) to the buried layer (2), and is configured to electrically connect the buried layer (2) to the top surface of the epitaxial layer (3).

44. The semiconductor device (100) according to clause 43, wherein the second depth (D2) is less than the first depth (D1).

45. The semiconductor device (100) according to clause 43, wherein the first deep trench structure (511) comprises:
a pad (7), formed on a sidewall and at least a portion of a bottom of the first trench (51), and comprising a first opening (71) formed at the bottom of the first trench (51);
a dielectric layer (8), disposed inside the pad (7) in the first trench (51), and comprising a second opening (54) extending from the top surface of the epitaxial layer (3) to the pad (7) at the bottom of the first trench (51), wherein the second opening (54) is aligned with the first opening (71); and
a first conductive material (61), filling the first opening (71) and the second opening (54), and configured to electrically connect the substrate (1) to the top surface of the epitaxial layer (3).

46. The semiconductor device (100) according to clause 45, wherein the first conductive material (61) comprises polysilicon having the first doping type.

47. The semiconductor device (100) according to clause 43, wherein the second deep trench isolation structure (521) comprises:
a pad (7), disposed on a sidewall and a bottom of the second trench (52); and
a dielectric layer (8), disposed inside the pad (7) in the second trench (52).

48. The semiconductor device (100) according to clause 43, wherein the third deep trench isolation structure (531) comprises:
a pad (7), disposed on a sidewall and a bottom of the third trench (53); and
a dielectric layer (8), disposed inside the pad (7) in the third trench (53).

49. The semiconductor device (100) according to clause 43, wherein the third deep trench isolation structure (531) comprises:
a diffusion material (81), partially filling the third trench (53); and
a dielectric material, sealing the diffusion material (81) in the third trench (53), wherein the diffusion material (81) and the dielectric material jointly form the third deep trench isolation structure (531).

50. The semiconductor device (100) according to clause 43, wherein the third deep trench isolation structure (531) comprises oxide or undoped polysilicon.

51. The semiconductor device (100) according to clause 43, wherein the first doped region (82) is disposed near both sides of the third trench (53) or only near one side of the third trench (53).

52. The semiconductor device (100) according to clause 51, wherein the first doped region (82) is formed between any two of the first trench (51), the second trench (52), and the third trench (53).

53. The semiconductor device (100) according to clause 43, further comprising a second doped region (9), wherein the second doped region (9) is formed in the substrate (1) near a bottom of the first trench (51), and the second doped region (9) has the first doping type and has a doping concentration higher than that of the substrate (1).

54. The semiconductor device (100) according to clause 43, further comprising a third doped region, wherein the third doped region is formed in the substrate (1) near a bottom of the second trench (52), and the third doped region has the first doping type and has a doping concentration higher than that of the substrate (1).

55. The semiconductor device (100) according to clause 43, further comprising: a shallow trench isolation region (91), formed in the epitaxial layer (3).

56. The semiconductor device (100) according to clause 43, further comprising: at least one transistor, formed in the epitaxial layer (3).

57. A method for fabricating a semiconductor device (100), comprising:
providing a semiconductor body (11), wherein the semiconductor body (11) comprises a substrate (1), a buried layer (2) disposed on the substrate (1), and an epitaxial layer (3) disposed on the buried layer (2), the substrate (1) has a first doping type, and the buried layer (2) has a second doping type opposite to the first doping type;
forming a hard mask layer (4) on a top surface of the epitaxial layer (3);
etching the hard mask layer (4) and the semiconductor body (11) by using a third soft mask layer to form, in the hard mask layer (4), a third trench opening (530) that penetrates through the hard mask layer (4) and to form, in the semiconductor body (11), a third trench (53) aligned with the third trench opening (530), wherein the third trench (53) extends from the top surface of the epitaxial layer (3) into the buried layer (2) or to a position in the epitaxial layer (3) and near the buried layer (2) and has a third depth (D3); stripping the third soft mask layer;
filling the third trench opening (530) and the third trench (53) with a second conductive material (62);
etching the hard mask layer (4) and the semiconductor body (11) by using a fourth soft mask layer to form, in the hard mask layer (4), a first trench opening (510) and a second trench opening (520) that penetrate through the hard mask layer (4), and to form, in the semiconductor body (11), a first trench (51) aligned with the first trench opening (510) and a second trench (52) aligned with the second trench opening (520), wherein the second trench (52) extends from the top surface of the epitaxial layer (3) into the substrate (1) and has a second depth (D2) greater than the third depth (D3), and the first trench (51) extends from the top surface of the epitaxial layer (3) into the substrate (1) and has a first depth (D1); forming a first deep trench structure (511) in the first trench (51), wherein the first deep trench structure (511) is configured to electrically connect the substrate (1) to the top surface of the epitaxial layer (3); and forming a second deep trench isolation structure (521) in the second trench (52), wherein the second deep trench isolation structure (521) is configured to isolate different component regions in the epitaxial layer (3).

58. The method according to clause 57, wherein the second conductive material (62) comprises polysilicon having the second doping type.

59. The method according to clause 58, further comprising: performing thermal annealing on the polysilicon having the second doping type, so that a dopant in the polysilicon is diffused into a region of the epitaxial layer (3) near a sidewall of the third trench (53) to form a doped region, wherein the doped region extends from the top surface of the epitaxial layer (3) to the buried layer (2), and is configured to electrically connect the buried layer (2) to the top surface of the epitaxial layer (3) together with the polysilicon.

60. The method according to clause 57, wherein forming the hard mask layer (4) comprises:
growing a first oxide layer (41) on the top surface of the epitaxial layer (3);
depositing a nitride layer (42) on the first oxide layer (41); and
depositing a second oxide layer (43) on the nitride layer (42).

61. The method according to clause 57, wherein forming the first deep trench structure (511) in the first trench (51) comprises:
forming a pad (7) on a sidewall and a bottom of the first trench (51);
forming a dielectric layer (8) inside the pad (7) in the first trench (51), wherein the dielectric layer (8) comprises a second opening (54) extending from the top surface of the epitaxial layer (3) toward the bottom of the first trench (51);
performing anisotropic etching on the dielectric layer (8) and the pad (7) in the first trench (51), so that the second opening (54) extends to the pad (7) at the bottom of the first trench (51), and a first opening (71) aligned with the second opening (54) is formed in the pad (7) at the bottom of the first trench (51); and filling the first opening (71) and the second opening (54) with a first conductive material (61), wherein the first conductive material (61) is configured to electrically connect the substrate (1) to the top surface of the epitaxial layer (3).

62. The method according to clause 61, wherein the first conductive material (61) comprises polysilicon having the first doping type.

63. The method according to clause 61, further comprising:
forming a second doped region (9) in the substrate (1) near the bottom of the first trench (51), wherein the second doped region (9) has the first doping type and has a doping concentration higher than that of the substrate (1).

64. The method according to clause 57, wherein forming the second deep trench isolation structure (521) in the second trench (52) comprises:
forming a pad (7) on a sidewall and a bottom of the second trench (52); and
forming a dielectric layer (8) inside the pad (7) in the second trench (52), wherein the dielectric layer (8) completely or partially fills the second trench (52).

65. The method according to clause 57, wherein the second depth (D2) is less than the first depth (D1), and the formation of the first deep trench structure (511) and the second deep trench isolation structure (521) comprises:
forming a pad (7) on a sidewall and a bottom of each of the first trench (51) and the second trench (52); and
forming a dielectric layer (8) inside the pad (7) in the first trench (51) and the second trench (52), so that the dielectric layer (8) forms, in the first trench (51), a second opening (54) that extends from the top surface of the epitaxial layer (3) toward the bottom of the first trench (51), and the dielectric layer (8) completely or partially fills the second trench (52), wherein the pad (7) and the dielectric layer (8) in the second trench (52) form the second deep trench isolation structure (521).

66. The method according to clause 65, wherein the formation of the first deep trench structure (511) further comprises:
performing anisotropic etching on the dielectric layer (8) and the pad (7), so that the second opening (54) extends to the pad (7) at the bottom of the first trench (51), and a first opening (71) aligned with the second opening (54) is formed in the pad (7) at the bottom of the first trench (51);
performing ion implantation on the substrate (1) through the second opening (54) and the first opening (71) to form a second doped region (9) in the substrate (1) near the bottom of the first trench (51), wherein the second doped region (9) has the first doping type and has a doping concentration higher than that of the substrate (1); and filling the first opening (71) and the second opening (54) with a first conductive material (61) to form the first deep trench structure (511).

67. The method according to clause 57, further comprising: performing ion implantation on the substrate (1) near a bottom of the first trench (51) and/or a bottom of the second trench (52) to form a doped region, wherein the doped region has the first doping type and has a doping concentration higher than that of the substrate (1).

68. The method according to clause 67, further comprising: forming a thin protective layer in the first trench (51) and the second trench (52) and on an upper surface of the third trench (53) prior to the ion implantation.

69. The method according to clause 57, further comprising:
forming a shallow trench isolation region (91) in the epitaxial layer (3).

70. The method according to clause 57, further comprising:
forming at least one transistor in the epitaxial layer (3).

71. A method for fabricating a semiconductor device (100), comprising:
providing a semiconductor body (11), wherein the semiconductor body (11) comprises a substrate (1), a buried layer (2) disposed on the substrate (1), and an epitaxial layer (3) disposed on the buried layer (2), the substrate (1) has a first doping type, and the buried layer (2) has a second doping type opposite to the first doping type;
forming a hard mask layer (4) on a top surface of the epitaxial layer (3);
etching the hard mask layer (4) and the semiconductor body (11) by using a fifth soft mask layer to form, in the hard mask layer (4), a first trench opening (510) and a second trench opening (520) that penetrate through the hard mask layer (4), and to form, in the semiconductor body (11), a first trench (51) aligned with the first trench opening (510) and a second trench (52) aligned with the second trench opening (520), wherein the first trench (51) extends from the top surface of the epitaxial layer (3) into the substrate (1) and has a first depth (D1), and the second trench (52) extends from the top surface of the epitaxial layer (3) into the substrate (1) and has a second depth (D2);
stripping the fifth soft mask layer;
forming a first deep trench structure (511) in the first trench (51), wherein the first deep trench structure (511) is configured to electrically connect the substrate (1) to the top surface of the epitaxial layer (3);
forming a second deep trench isolation structure (521) in the second trench (52), wherein the second deep trench isolation structure (521) is configured to isolate different component regions in the epitaxial layer (3);
stripping the hard mask layer (4);
etching the semiconductor body (11) by using a sixth soft mask layer to form a third trench (53) in the semiconductor body (11), wherein the third trench (53) extends from the top surface of the epitaxial layer (3) into the buried layer (2) or to a position in the epitaxial layer (3) and near the buried layer (2) and has a third depth (D3) less than the second depth (D2); and
filling the third trench (53) with a second conductive material (62), wherein the second conductive material (62) is configured to electrically connect the buried layer (2) to the top surface of the epitaxial layer (3).

72. The method according to clause 71, wherein the second conductive material (62) comprises polysilicon having the second doping type.

73. The method according to clause 72, further comprising: performing thermal annealing on the polysilicon having the second doping type, so that a dopant in the polysilicon is diffused into a region of the epitaxial layer (3) near a sidewall of the third trench (53) to form a doped region, wherein the doped region extends from the top surface of the epitaxial layer (3) to the buried layer (2), and is configured to electrically connect the buried layer (2) to the top surface of the epitaxial layer (3) together with the polysilicon.

74. The method according to clause 71, wherein forming the hard mask layer (4) comprises:
growing a first oxide layer (41) on the top surface of the epitaxial layer (3);
depositing a nitride layer (42) on the first oxide layer (41); and
depositing a second oxide layer (43) on the nitride layer (42).

75. The method according to clause 71, wherein forming the first deep trench structure (511) in the first trench (51) comprises:
forming a pad (7) on a sidewall and a bottom of the first trench (51);
forming a dielectric layer (8) inside the pad (7) in the first trench (51), wherein the dielectric layer (8) comprises a second opening (54) extending from the top surface of the epitaxial layer (3) toward the bottom of the first trench (51);
performing anisotropic etching on the dielectric layer (8) and the pad (7) in the first trench (51), so that the second opening (54) extends to the pad (7) at the bottom of the first trench (51), and a first opening (71) aligned with the second opening (54) is formed in the pad (7) at the bottom of the first trench (51); and
filling the first opening (71) and the second opening (54) with a first conductive material (61), wherein the first conductive material (61) is configured to electrically connect the substrate (1) to the top surface of the epitaxial layer (3).

76. The method according to clause 75, wherein the first conductive material (61) comprises polysilicon having the first doping type.

77. The method according to clause 71, further comprising:
forming a second doped region (9) in the substrate (1) near the bottom of the first trench (51), wherein the second doped region (9) has the first doping type and has a doping concentration higher than that of the substrate (1).

78. The method according to clause 71, wherein forming the second deep trench isolation structure (521) in the second trench (52) comprises:
forming a pad (7) on a sidewall and a bottom of the second trench (52); and
forming a dielectric layer (8) inside the pad (7) in the second trench (52), wherein the dielectric layer (8) completely or partially fills the second trench (52).

79. The method according to clause 71, wherein the second depth (D2) is less than the first depth (D1), and the formation of the first deep trench structure (511) and the second deep trench isolation structure (521) comprises:
forming a pad (7) on a sidewall and a bottom of each of the first trench (51) and the second trench (52); and
forming a dielectric layer (8) inside the pad (7) in the first trench (51) and the second trench (52), so that the dielectric layer (8) forms, in the first trench (51), a second opening (54) that extends from the top surface of the epitaxial layer (3) toward the bottom of the first trench (51), and the dielectric layer (8) completely or partially fills the second trench (52), wherein the pad (7) and the dielectric layer (8) in the second trench (52) form the second deep trench isolation structure (521).

80. The method according to clause 79, wherein the formation of the first deep trench structure (511) further comprises:
performing anisotropic etching on the dielectric layer (8) and the pad (7), so that the second opening (54) extends to the pad (7) at the bottom of the first trench (51), and a first opening (71) aligned with the second opening (54) is formed in the pad (7) at the bottom of the first trench (51);
performing ion implantation on the substrate (1) through the second opening (54) and the first opening (71) to form a second doped region (9) in the substrate (1) near the bottom of the first trench (51), wherein the second doped region (9) has the first doping type and has a doping concentration higher than that of the substrate (1); and filling the first opening (71) and the second opening (54) with a first conductive material (61) to form the first deep trench structure (511).

81. The method according to clause 71, further comprising: performing ion implantation on the substrate (1) near a bottom of the first trench (51) and/or a bottom of the second trench (52) to form a doped region, wherein the doped region has the first doping type and has a doping concentration higher than that of the substrate (1).

82. The method according to clause 81, further comprising: forming a thin protective layer in the first trench (51) and the second trench (52) and on an upper surface of the third trench (53) prior to the ion implantation.

83. The method according to clause 71, further comprising:
forming a shallow trench isolation region (91) in the epitaxial layer (3) after the first deep trench structure (511) and the second deep trench isolation structure (521) are formed and before the third trench (53) is formed.

84. The method according to clause 71, further comprising:
forming at least one transistor in the epitaxial layer (3).

85. A method for fabricating a semiconductor device (100), comprising:
providing a semiconductor body (11), wherein the semiconductor body (11) comprises a substrate (1), a buried layer (2) disposed on the substrate (1), and an epitaxial layer (3) disposed on the buried layer (2), the substrate (1) has a first doping type, and the buried layer (2) has a second doping type opposite to the first doping type;
forming a hard mask layer (4) on a top surface of the epitaxial layer (3);
etching the hard mask layer (4) and the semiconductor body (11) by using a seventh soft mask layer to simultaneously form a first trench (51), a second trench (52), and a third trench (53) in the semiconductor body (11), wherein the first trench (51) extends from the top surface of the epitaxial layer (3) into the substrate (1) and has a first depth (D1), the second trench (52) extends from the top surface of the epitaxial layer (3) into the substrate (1) and has a second depth (D2), and the third trench (53) extends from the top surface of the epitaxial layer (3) into the buried layer (2) or to a position in the epitaxial layer (3) and near the buried layer (2) and has a third depth (D3) less than the second depth (D2);
forming a first deep trench structure (511) in the first trench (51), wherein the first deep trench structure (511) is configured to electrically connect the substrate (1) to the top surface of the epitaxial layer (3);
forming a second deep trench isolation structure (521) in the second trench (52), wherein the second deep trench isolation structure (521) is configured to isolate different component regions in the epitaxial layer (3);
forming a temporary deep trench structure (534) in the third trench (53);
etching the temporary deep trench structure (534) in the third trench (53) by using an eighth soft mask layer (103) to remove the temporary deep trench structure (534) in the third trench (53); and
filling the third trench (53) with a second conductive material (62), wherein the second conductive material (62) is configured to electrically connect the buried layer (2) to the top surface of the epitaxial layer (3).

86. The method according to clause 85, wherein the second conductive material (62) comprises polysilicon having the second doping type.

87. The method according to clause 86, further comprising: performing thermal annealing on the polysilicon having the second doping type, so that a dopant in the polysilicon is diffused into a region of the epitaxial layer (3) near a sidewall of the third trench (53) to form a doped region, wherein the doped region extends from the top surface of the epitaxial layer (3) to the buried layer (2), and is configured to electrically connect the buried layer (2) to the top surface of the epitaxial layer (3) together with the polysilicon.

88. The method according to clause 85, wherein forming the hard mask layer (4) comprises:
growing a first oxide layer (41) on the top surface of the epitaxial layer (3);
depositing a nitride layer (42) on the first oxide layer (41); and
depositing a second oxide layer (43) on the nitride layer (42).

89. The method according to clause 85, wherein forming the first deep trench structure (511) in the first trench (51) comprises:
forming a pad (7) on a sidewall and a bottom of the first trench (51);
forming a dielectric layer (8) inside the pad (7) in the first trench (51), wherein the dielectric layer (8) comprises a second opening (54) extending from the top surface of the epitaxial layer (3) toward the bottom of the first trench (51);
performing anisotropic etching on the dielectric layer (8) and the pad (7) in the first trench (51), so that the second opening (54) extends to the pad (7) at the bottom of the first trench (51), and a first opening (71) aligned with the second opening (54) is formed in the pad (7) at the bottom of the first trench (51); and
filling the first opening (71) and the second opening (54) with a first conductive material (61), wherein the first conductive material (61) is configured to electrically connect the substrate (1) to the top surface of the epitaxial layer (3).

90. The method according to clause 89, wherein the first conductive material (61) comprises polysilicon having the first doping type.

91. The method according to clause 89, further comprising:
forming a second doped region (9) in the substrate (1) near the bottom of the first trench (51), wherein the second doped region (9) has the first doping type and has a doping concentration higher than that of the substrate (1).

92. The method according to clause 85, wherein forming the second deep trench isolation structure (521) in the second trench (52) comprises:
forming a pad (7) on a sidewall and a bottom of the second trench (52); and
forming a dielectric layer (8) inside the pad (7) in the second trench (52), wherein the dielectric layer (8) completely or partially fills the second trench (52).

93. The method according to clause 85, wherein the second depth (D2) is less than the first depth (D1), and the formation of the first deep trench structure (511), the second deep trench isolation structure (521), and the temporary deep trench structure (534) comprises:
forming a pad (7) on a sidewall and a bottom of each of the first trench (51), the second trench (52), and the third trench (53); and
forming a dielectric layer (8) inside the pad (7) in the first trench (51), the second trench (52), and the third trench (53), so that the dielectric layer (8) forms, in the first trench (51), a second opening (54) that extends from the top surface of the epitaxial layer (3) toward the bottom of the first trench (51), and the dielectric layer (8) completely fills the second trench (52) and the third trench (53), wherein the pad (7) and the dielectric layer (8) in the second trench (52) form the second deep trench isolation structure (521), and the pad (7) and the dielectric layer (8) in the third trench (53) form the temporary deep trench structure (534).

94. The method according to clause 93, wherein the formation of the first deep trench structure (511) further comprises:
performing anisotropic etching on the dielectric layer (8) and the pad (7), so that the second opening (54) extends to the pad (7) at the bottom of the first trench (51), and a first opening (71) aligned with the second opening (54) is formed in the pad (7) at the bottom of the first trench (51);
performing ion implantation on the substrate (1) through the second opening (54) and the first opening (71) to form a second doped region (9) in the substrate (1) near the bottom of the first trench (51), wherein the second doped region (9) has the first doping type and has a doping concentration higher than that of the substrate (1); and
filling the first opening (71) and the second opening (54) with a first conductive material (61) to form the first deep trench structure (511).

95. The method according to clause 85, further comprising: performing ion implantation on the substrate (1) near a bottom of the first trench (51) and/or a bottom of the second trench (52) to form a doped region, wherein the doped region has the first doping type and has a doping concentration higher than that of the substrate (1).

96. The method according to clause 95, further comprising: forming a thin protective layer in the first trench (51) and the second trench (52) and on an upper surface of the third trench (53) prior to the ion implantation.

97. The method according to clause 85, wherein etching the temporary deep trench structure (534) in the third trench (53) by using the eighth soft mask layer (103) comprises:
etching the temporary deep trench structure (534) in the third trench (53) by using the eighth soft mask layer (103) to remove a portion of the temporary deep trench structure (534) in the third trench (53), thereby forming a second shallow trench (532);
forming a sidewall spacer (556) on a sidewall of each of a third trench opening (530) in the hard mask layer (4) and the second shallow trench (532); and
removing the remaining portion of the temporary deep trench structure (534) in the third trench (53).

98. The method according to clause 85, further comprising:
forming a shallow trench isolation region (91) in the epitaxial layer (3).

99. The method according to clause 85, further comprising:
forming at least one transistor in the epitaxial layer (3).

100. A method for fabricating a semiconductor device (100), comprising:
providing a semiconductor body (11), wherein the semiconductor body (11) comprises a substrate (1), a buried layer (2) disposed on the substrate (1), and an epitaxial layer (3) disposed on the buried layer (2), the substrate (1) has a first doping type, and the buried layer (2) has a second doping type opposite to the first doping type;
forming a hard mask layer (4) on a top surface of the epitaxial layer (3);
etching the hard mask layer (4) and the semiconductor body (11) by using a seventh soft mask layer to simultaneously form a first trench (51), a second trench (52), and a third trench (53) in the semiconductor body (11), wherein the first trench (51) extends from the top surface of the epitaxial layer (3) into the substrate (1) and has a first depth (D1), the second trench (52) extends from the top surface of the epitaxial layer (3) into the substrate (1) and has a second depth (D2), and the third trench (53) extends from the top surface of the epitaxial layer (3) into the buried layer (2) or to a position in the epitaxial layer (3) and near the buried layer (2) and has a third depth (D3) less than the second depth (D2);
forming a first deep trench structure (511) in the first trench (51), wherein the first deep trench structure (511) is configured to electrically connect the substrate (1) to the top surface of the epitaxial layer (3);
forming a second deep trench isolation structure (521) in the second trench (52), wherein the second deep trench isolation structure (521) is configured to isolate different component regions in the epitaxial layer (3);
forming a temporary deep trench structure (534) in the third trench (53);
etching the temporary deep trench structure (534) in the third trench (53) by using an eighth soft mask layer (103) to remove the temporary deep trench structure (534) in the third trench (53);
obliquely implanting, in the third trench (53), a dopant of the second doping type into the semiconductor body (11) to form, in the epitaxial layer (3), a first doped region (82) having the second doping type near a sidewall of the third trench (53), wherein the first doped region (82) extends from the top surface of the epitaxial layer (3) to the buried layer (2), and is configured to electrically connect the buried layer (2) to the top surface of the epitaxial layer (3); and
filling the third trench (53) with a dielectric material (83) to form a third deep trench isolation structure (531).

101. The method according to clause 100, wherein the second depth (D2) is less than the first depth (D1), and the formation of the first deep trench structure (511), the second deep trench isolation structure (521), and the temporary deep trench structure (534) comprises:
forming a pad (7) on a sidewall and a bottom of each of the first trench (51), the second trench (52), and the third trench (53); and
forming a dielectric layer (8) inside the pad (7) in the first trench (51), the second trench (52), and the third trench (53), so that the dielectric layer (8) forms, in the first trench (51), a second opening (54) that extends from the top surface of the epitaxial layer (3) toward the bottom of the first trench (51), and the dielectric layer (8) completely fills the second trench (52) and the third trench (53), wherein the pad (7) and the dielectric layer (8) in the second trench (52) form the second deep trench isolation structure (521), and the pad (7) and the dielectric layer (8) in the third trench (53) form the temporary deep trench structure (534).

102. The method according to clause 101, wherein the formation of the first deep trench structure (511) further comprises:
performing anisotropic etching on the dielectric layer (8) and the pad (7), so that the second opening (54) extends to the pad (7) at the bottom of the first trench (51), and a first opening (71) aligned with the second opening (54) is formed in the pad (7) at the bottom of the first trench (51);
performing ion implantation on the substrate (1) through the second opening (54) and the first opening (71) to form a second doped region (9) in the substrate (1) near the bottom of the first trench (51), wherein the second doped region (9) has the first doping type and has a doping concentration higher than that of the substrate (1); and
filling the first opening (71) and the second opening (54) with a first conductive material (61) to form the first deep trench structure (511).

103. The method according to clause 100, further comprising: performing ion implantation on the substrate (1) near a bottom of the first trench (51) and/or a bottom of the second trench (52) to form a doped region, wherein the doped region has the first doping type and has a doping concentration higher than that of the substrate (1).

104. The method according to clause 103, further comprising: forming a thin protective layer in the first trench (51) and the second trench (52) and on an upper surface of the third trench (53) prior to the ion implantation.

105. The method according to clause 100, wherein etching the temporary deep trench structure (534) in the third trench (53) by using the eighth soft mask layer (103) comprises:
etching the temporary deep trench structure (534) in the third trench (53) by using the eighth soft mask layer (103) to remove a portion of the temporary deep trench structure (534) in the third trench (53), thereby forming a second shallow trench (532);
forming a sidewall spacer (556) on a sidewall of each of a third trench opening (530) in the hard mask layer (4) and the second shallow trench (532); and
removing the remaining portion of the temporary deep trench structure (534) in the third trench (53).

106. The method according to clause 100, wherein the dielectric material (83) comprises oxide or undoped polysilicon.

107. A semiconductor device (100), comprising:
a semiconductor body (11), wherein the semiconductor body (11) comprises a substrate (1), a buried layer (2) disposed on the substrate (1), and an epitaxial layer (3) disposed on the buried layer (2), the substrate (1) has a first doping type, and the buried layer (2) has a second doping type opposite to the first doping type;
a first trench (51), extending from a top surface of the epitaxial layer (3) into the substrate (1) and having a first depth (D1);
a second trench (52), extending from the top surface of the epitaxial layer (3) into the substrate (1) and having a second depth (D2);
a third trench (53), extending from the top surface of the epitaxial layer (3) into the buried layer (2) and having a third depth (D3) less than the second depth (D2);
a first deep trench structure (511), disposed in the first trench (51) and configured to electrically connect the substrate (1) to the top surface of the epitaxial layer (3);
a second deep trench isolation structure (521), disposed in the second trench (52) and configured to isolate different component regions in the epitaxial layer (3); and
a second conductive material (62), filling the third trench (53), and configured to electrically connect the buried layer (2) to the top surface of the epitaxial layer (3).

108. The semiconductor device (100) according to clause 107, wherein the second depth (D2) is less than the first depth (D1).

109. The semiconductor device (100) according to clause 107, wherein the first deep trench structure (511) comprises:
a pad (7), formed on a sidewall and at least a portion of a bottom of the first trench (51), and comprising a first opening (71) formed at the bottom of the first trench (51);
a dielectric layer (8), disposed inside the pad (7) in the first trench (51), and comprising a second opening (54) extending from the top surface of the epitaxial layer (3) to the pad (7) at the bottom of the first trench (51), wherein the second opening (54) is aligned with the first opening (71); and
a first conductive material (61), filling the first opening (71) and the second opening (54), and configured to electrically connect the substrate (1) to the top surface of the epitaxial layer (3).

110. The semiconductor device (100) according to clause 109, wherein the first conductive material (61) comprises polysilicon having the first doping type.

111. The semiconductor device (100) according to clause 107, wherein the second deep trench isolation structure (521) comprises:
a pad (7), disposed on a sidewall and a bottom of the second trench (52); and
a dielectric layer (8), disposed inside the pad (7) in the second trench (52).

112. The semiconductor device (100) according to clause 107, wherein the second conductive material (62) comprises polysilicon having the second doping type.

113. The semiconductor device (100) according to clause 107, further comprising:
a first doped region (82), formed in the epitaxial layer (3) near a sidewall of the third trench (53) and having the second doping type, wherein the first doped region (82) extends from the top surface of the epitaxial layer (3) to the buried layer (2), and is configured to electrically connect the buried layer (2) to the top surface of the epitaxial layer (3) together with the second conductive material (62).

114. The semiconductor device (100) according to clause 107, further comprising a second doped region (9), wherein the second doped region (9) is formed in the substrate (1) near a bottom of the first trench (51), and the second doped region (9) has the first doping type and has a doping concentration higher than that of the substrate (1).

115. The semiconductor device (100) according to clause 107, further comprising:
a shallow trench isolation region (91), formed in the epitaxial layer (3).

116. The semiconductor device (100) according to clause 107, further comprising:
at least one transistor, formed in the epitaxial layer (3).

117. The semiconductor device (100) according to clause 107, further comprising a third doped region, wherein the third doped region is formed in the substrate (1) near a bottom of the second trench (52), and the third doped region has the first doping type and has a doping concentration higher than that of the substrate (1).

### SECOND SET OF CLAUSES

1. A method for fabricating a semiconductor device (100), comprising:
providing a semiconductor body (11), wherein the semiconductor body (11) comprises a substrate (1), a buried layer (2) disposed on the substrate (1), and an epitaxial layer (3) disposed on the buried layer (2), the substrate (1) has a first doping type, and the buried layer (2) has a second doping type opposite to the first doping type;
forming a hard mask layer (4) on a top surface of the epitaxial layer (3);
etching the hard mask layer (4) and the semiconductor body (11) by using a single soft mask layer (10) to simultaneously form a first trench (51) and a third trench (53) in the semiconductor body (11), wherein the first trench (51) extends from the top surface of the epitaxial layer (3) into the substrate (1) and has a first depth (D1), and the third trench (53) extends from the top surface of the epitaxial layer (3) into the buried layer (2) or to a position in the epitaxial layer (3) and near the buried layer (2) and has a third depth (D3) less than the first depth (D1);
forming, in the epitaxial layer (3), a first doped region (82) having the second doping type near a sidewall of the third trench (53), wherein the first doped region (82) extends from the top surface of the epitaxial layer (3) to the buried layer (2), and is configured to electrically connect the buried layer (2) to the top surface of the epitaxial layer (3);
forming a first deep trench structure (511) in the first trench (51), wherein the first deep trench structure (511) is configured to electrically connect the substrate (1) to the top surface of the epitaxial layer (3); and
forming a third deep trench isolation structure (531) in the third trench (53), wherein the third deep trench isolation structure (531) is configured to isolate different component regions in the epitaxial layer (3).

2. The method according to clause 1, wherein forming the hard mask layer (4) comprises:
growing a first oxide layer (41) on the top surface of the epitaxial layer (3);
depositing a nitride layer (42) on the first oxide layer (41); and
depositing a second oxide layer (43) on the nitride layer (42).

3. The method according to clause 1, wherein etching the hard mask layer (4) and the semiconductor body (11) by using the single soft mask layer (10) comprises:
performing first etching on the hard mask layer (4) by using the single soft mask layer (10) to simultaneously form, in the hard mask layer (4), a first trench opening (510) and a third trench opening (530) that penetrate through the hard mask layer (4);
stripping the single soft mask layer (10); and performing second etching on the semiconductor body (11) by using the hard mask layer (4) to form, in the semiconductor body (11), the first trench (51) aligned with the first trench opening (510) and the third trench (53) aligned with the third trench opening (530).

4. The method according to clause 1, wherein etching the hard mask layer (4) and the semiconductor body (11) by using the single soft mask layer (10) comprises:
performing first etching on the hard mask layer (4) and the epitaxial layer (3) by using the single soft mask layer (10) to simultaneously form, in the hard mask layer (4), a first trench opening (510) and a third trench opening (530) that penetrate through the hard mask layer (4), and to form, in the epitaxial layer (3), a first shallow trench (555) aligned with each of the first trench opening (510) and the third trench opening (530);
forming a sidewall spacer (556) on a sidewall of each of the first trench opening (510), the third trench opening (530), and the first shallow trench (555); and
performing second etching on the semiconductor body (11) via the first shallow trench (555) to form, in the semiconductor body (11), the first trench (51) aligned with the first trench opening (510) and the third trench (53) aligned with the third trench opening (530).

5. The method according to clause 4, further comprising:
removing the sidewall spacer (556) through isotropic etching after the first doped region (82) is formed.

6. The method according to clause 4, wherein the sidewall spacer (556) comprises nitride.

7. The method according to clause 1, wherein etching the hard mask layer (4) and the semiconductor body (11) by using the single soft mask layer (10) comprises:
performing single etching on the hard mask layer (4) and the semiconductor body (11) by using the single soft mask layer (10) to simultaneously form, in the hard mask layer (4), a first trench opening (510) and a third trench opening (530) that penetrate through the hard mask layer (4), and to simultaneously form, in the semiconductor body (11), the first trench (51) aligned with the first trench opening (510) and the third trench (53) aligned with the third trench opening (530).

8. The method according to clause 1, wherein forming the first deep trench structure (511) in the first trench (51) comprises:
forming a pad (7) on a sidewall and a bottom of the first trench (51);
forming a dielectric layer (8) inside the pad (7) in the first trench (51), wherein the dielectric layer (8) comprises a second opening (54) extending from the top surface of the epitaxial layer (3) toward the bottom of the first trench (51);
performing anisotropic etching on the dielectric layer (8) and the pad (7) in the first trench (51), so that the second opening (54) extends to the pad (7) at the bottom of the first trench (51), and a first opening (71) aligned with the second opening (54) is formed in the pad (7) at the bottom of the first trench (51); and
filling the first opening (71) and the second opening (54) with a first conductive material (61), wherein the first conductive material (61) is configured to electrically connect the substrate (1) to the top surface of the epitaxial layer (3).

9. The method according to clause 8, wherein the first conductive material (61) comprises polysilicon having the first doping type.

10. The method according to clause 8, further comprising:
forming a second doped region (9) in the substrate (1) near the bottom of the first trench (51), wherein the second doped region (9) has the first doping type and has a doping concentration higher than that of the substrate (1).

11. The method according to clause 1, wherein forming the third deep trench isolation structure (531) in the third trench (53) comprises:
forming a pad (7) on a sidewall and a bottom of the third trench (53); and
forming a dielectric layer (8) inside the pad (7) in the third trench (53), wherein the dielectric layer (8) completely fills the third trench (53).

12. The method according to clause 1, wherein forming, in the epitaxial layer (3), the first doped region (82) having the second doping type near the sidewall of the third trench (53) comprises:
depositing a diffusion material (81) in the third trench (53), wherein the diffusion material (81) comprises a dopant of the second doping type; and
performing thermal annealing on the diffusion material (81), so that the dopant is diffused into a region of the epitaxial layer (3) near the sidewall of the third trench (53) to form the first doped region (82).

13. The method according to clause 12, wherein the diffusion material (81) partially fills the third trench (53), and wherein forming the third deep trench isolation structure (531) in the third trench (53) comprises:
continuing to fill the third trench (53) with a dielectric material to seal the diffusion material (81), wherein the diffusion material (81) and the dielectric material jointly form the third deep trench isolation structure (531).

14. The method according to clause 12, wherein when the first doping type is a p-type, the diffusion material (81) comprises at least one of POCl3 glass and phosphate silicate glass, and the dopant is a phosphorus element; and
when the first doping type is an n-type, the diffusion material (81) comprises borosilicate glass, and the dopant is a boron element.

15. The method according to clause 12, wherein the first doped region (82) is formed near both sides of the third trench (53).

16. The method according to clause 12, wherein the diffusion material (81) completely or partially fills the third trench (53).

17. The method according to clause 16, wherein an air gap (810) is formed inside the diffusion material (81).

18. The method according to clause 12, further comprising:
etching the diffusion material (81) in the third trench (53) to remove the diffusion material (81).

19. The method according to clause 18, wherein the formation of the first deep trench structure (511) and the third deep trench isolation structure (531) comprises:
forming a pad (7) on a sidewall and a bottom of each of the first trench (51) and the third trench (53); and
forming a dielectric layer (8) inside the pad (7) in the first trench (51) and the third trench (53), so that the dielectric layer (8) forms, in the first trench (51), a second opening (54) that extends from the top surface of the epitaxial layer (3) toward the bottom of the first trench (51), and the dielectric layer (8) completely fills the third trench (53), wherein the pad (7) and the dielectric layer (8) in the third trench (53) form the third deep trench isolation structure (531).

20. The method according to clause 19, wherein the formation of the first deep trench structure (511) further comprises:
performing anisotropic etching on the dielectric layer (8) and the pad (7), so that the second opening (54) extends to the pad (7) at the bottom of the first trench (51), and a first opening (71) aligned with the second opening (54) is formed in the pad (7) at the bottom of the first trench (51);
performing ion implantation on the substrate (1) through the second opening (54) and the first opening (71) to form a second doped region (9) in the substrate (1) near the bottom of the first trench (51), wherein the second doped region (9) has the first doping type and has a doping concentration higher than that of the substrate (1); and
filling the first opening (71) and the second opening (54) with a first conductive material (61) to form the first deep trench structure (511).

21. The method according to clause 1, further comprising: performing ion implantation on the substrate (1) near a bottom of the first trench (51) to form a doped region, wherein the doped region has the first doping type and has a doping concentration higher than that of the substrate (1).

22. The method according to clause 21, further comprising: forming a thin protective layer in the first trench (51) and on an upper surface of the third trench (53) prior to the ion implantation.

23. The method according to clause 1, wherein forming, in the epitaxial layer (3), the first doped region (82) having the second doping type near the sidewall of the third trench (53) comprises:

forming the first doped region (82) by implanting, at an oblique angle, a dopant of the second doping type through the sidewall of the third trench (53).

24. The method according to clause 1, further comprising:
forming a shallow trench isolation region (91) in the epitaxial layer (3).

25. The method according to clause 1, further comprising:
forming at least one transistor in the epitaxial layer (3).

26. A method for fabricating a semiconductor device (100), comprising:
providing a semiconductor body (11), wherein the semiconductor body (11) comprises a substrate (1), a buried layer (2) disposed on the substrate (1), and an epitaxial layer (3) disposed on the buried layer (2), the substrate (1) has a first doping type, and the buried layer (2) has a second doping type opposite to the first doping type;
forming a hard mask layer (4) on a top surface of the epitaxial layer (3);
performing first etching on the hard mask layer (4) by using a first soft mask layer (101) to simultaneously form, in the hard mask layer (4), a first trench opening (510) and a third trench opening (530) that penetrate through the hard mask layer (4);
stripping the first soft mask layer (101);
forming a second soft mask layer (102) on the hard mask layer (4), wherein the second soft mask layer (102) comprises a third opening (1021) and the third opening (1021) exposes one or more portions of the hard mask layer (4) near the third trench opening (530);
implanting a dopant of the second doping type into the epitaxial layer (3) via the third opening (1021);
stripping the second soft mask layer (102);
performing second etching on the semiconductor body (11) by using the hard mask layer (4) to form, in the semiconductor body (11), a first trench (51) aligned with the first trench opening (510) and a third trench (53) aligned with the third trench opening (530);
performing thermal annealing on the dopant to form a first doped region (82) in a region of the epitaxial layer (3) near a sidewall of the third trench (53), wherein the first doped region (82) extends from the top surface of the epitaxial layer (3) to the buried layer (2), and is configured to electrically connect the buried layer (2) to the top surface of the epitaxial layer (3);
forming a first deep trench structure (511) in the first trench (51), wherein the first deep trench structure (511) is configured to electrically connect the substrate (1) to the top surface of the epitaxial layer (3); and
forming a third deep trench isolation structure (531) in the third trench (53), wherein the third deep trench isolation structure (531) is configured to isolate different component regions in the epitaxial layer (3).

27. The method according to clause 26, wherein when the first doping type is a p-type, the dopant is a phosphorus element; and when the first doping type is an n-type, the dopant is a boron element.

28. The method according to clause 26, wherein the first doped region (82) is formed only near one side of the third trench (53).

29. The method according to clause 28, wherein the first doped region (82) is formed between the first trench (51) and the third trench (53).

30. The method according to clause 26, wherein the formation of the first deep trench structure (511) and the third deep trench isolation structure (531) comprises:
forming a pad (7) on a sidewall and a bottom of each of the first trench (51) and the third trench (53); and
forming a dielectric layer (8) inside the pad (7) in the first trench (51) and the third trench (53), so that the dielectric layer (8) forms, in the first trench (51), a second opening (54) that extends from the top surface of the epitaxial layer (3) toward the bottom of the first trench (51), and the dielectric layer (8) completely fills the third trench (53), wherein the pad (7) and the dielectric layer (8) in the third trench (53) form the third deep trench isolation structure (531).

31. The method according to clause 30, wherein the formation of the first deep trench structure (511) further comprises:
performing anisotropic etching on the dielectric layer (8) and the pad (7), so that the second opening (54) extends to the pad (7) at the bottom of the first trench (51), and a first opening (71) aligned with the second opening (54) is formed in the pad (7) at the bottom of the first trench (51);
performing ion implantation on the substrate (1) through the second opening (54) and the first opening (71) to form a second doped region (9) in the substrate (1) near the bottom of the first trench (51), wherein the second doped region (9) has the first doping type and has a doping concentration higher than that of the substrate (1); and filling the first opening (71) and the second opening (54) with a first conductive material (61) to form the first deep trench structure (511).

32. The method according to clause 26, further comprising: performing ion implantation on the substrate (1) near a bottom of the first trench (51) to form a doped region, wherein the doped region has the first doping type and has a doping concentration higher than that of the substrate (1).

33. The method according to clause 32, further comprising: forming a thin protective layer in the first trench (51) and on an upper surface of the third trench (53) prior to the ion implantation.

34. The method according to clause 26, wherein forming the hard mask layer (4) comprises:
growing a first oxide layer (41) on the top surface of the epitaxial layer (3);
depositing a nitride layer (42) on the first oxide layer (41); and
depositing a second oxide layer (43) on the nitride layer (42).

35. The method according to clause 26, wherein forming the first deep trench structure (511) in the first trench (51) comprises:
forming a pad (7) on a sidewall and a bottom of the first trench (51);
forming a dielectric layer (8) inside the pad (7) in the first trench (51), wherein the dielectric layer (8) comprises a second opening (54) extending from the top surface of the epitaxial layer (3) toward the bottom of the first trench (51);
performing anisotropic etching on the dielectric layer (8) and the pad (7) in the first trench (51), so that the second opening (54) extends to the pad (7) at the bottom of the first trench (51), and a first opening (71) aligned with the second opening (54) is formed in the pad (7) at the bottom of the first trench (51); and
filling the first opening (71) and the second opening (54) with a first conductive material (61), wherein the first conductive material (61) is configured to electrically connect the substrate (1) to the top surface of the epitaxial layer (3).

36. The method according to clause 35, wherein the first conductive material (61) comprises polysilicon having the first doping type.

37. The method according to clause 35, further comprising:
forming a second doped region (9) in the substrate (1) near the bottom of the first trench (51), wherein the second doped region (9) has the first doping type and has a doping concentration higher than that of the substrate (1).

38. The method according to clause 26, wherein forming the third deep trench isolation structure (531) in the third trench (53) comprises:
forming a pad (7) on a sidewall and a bottom of the third trench (53); and
forming a dielectric layer (8) inside the pad (7) in the third trench (53), wherein the dielectric layer (8) completely fills the third trench (53).

39. The method according to clause 26, further comprising:
forming a shallow trench isolation region (91) in the epitaxial layer (3).

40. The method according to clause 26, further comprising:
forming at least one transistor in the epitaxial layer (3).

41. A semiconductor device (100), comprising:
a semiconductor body (11), wherein the semiconductor body (11) comprises a substrate (1), a buried layer (2) disposed on the substrate (1), and an epitaxial layer (3) disposed on the buried layer (2), the substrate (1) has a first doping type, and the buried layer (2) has a second doping type opposite to the first doping type;
a first trench (51), extending from a top surface of the epitaxial layer (3) into the substrate (1) and having a first depth (D1);
a third trench (53), extending from the top surface of the epitaxial layer (3) into the buried layer (2) and having a third depth (D3) less than the first depth (D1);
a first deep trench structure (511), disposed in the first trench (51) and configured to electrically connect the substrate (1) to the top surface of the epitaxial layer (3);
a third deep trench isolation structure (531), disposed in the third trench (53) and configured to isolate different component regions in the epitaxial layer (3); and
a first doped region (82), formed in the epitaxial layer (3) near a sidewall of the third trench (53) and having the second doping type, wherein the first doped region (82) extends from the top surface of the epitaxial layer (3) to the buried layer (2), and is configured to electrically connect the buried layer (2) to the top surface of the epitaxial layer (3).

42. The semiconductor device (100) according to clause 41, wherein the first deep trench structure (511) comprises:
a pad (7), formed on a sidewall and at least a portion of a bottom of the first trench (51), and comprising a first opening (71) formed at the bottom of the first trench (51);
a dielectric layer (8), disposed inside the pad (7) in the first trench (51), and comprising a second opening (54) extending from the top surface of the epitaxial layer (3) to the pad (7) at the bottom of the first trench (51), wherein the second opening (54) is aligned with the first opening (71); and
a first conductive material (61), filling the first opening (71) and the second opening (54), and configured to electrically connect the substrate (1) to the top surface of the epitaxial layer (3).

43. The semiconductor device (100) according to clause 42, wherein the first conductive material (61) comprises polysilicon having the first doping type.

44. The semiconductor device (100) according to clause 41, wherein the third deep trench isolation structure (531) comprises:
a pad (7), disposed on a sidewall and a bottom of the third trench (53); and
a dielectric layer (8), disposed inside the pad (7) in the third trench (53).

45. The semiconductor device (100) according to clause 41, wherein the third deep trench isolation structure (531) comprises:
a diffusion material (81), partially filling the third trench (53); and
a dielectric material, sealing the diffusion material (81) in the third trench (53), wherein the diffusion material (81) and the dielectric material jointly form the third deep trench isolation structure (531).

46. The semiconductor device (100) according to clause 41, wherein the third deep trench isolation structure (531) comprises oxide or undoped polysilicon.

47. The semiconductor device (100) according to clause 41, wherein the first doped region (82) is disposed near both sides of the third trench (53) or only near one side of the third trench (53).

48. The semiconductor device (100) according to clause 47, wherein the first doped region (82) is formed between the first trench (51) and the third trench (53).

49. The semiconductor device (100) according to clause 41, further comprising a second doped region (9), wherein the second doped region (9) is formed in the substrate (1) near a bottom of the first trench (51), and the second doped region (9) has the first doping type and has a doping concentration higher than that of the substrate (1).

50. The semiconductor device (100) according to clause 41, further comprising:
a shallow trench isolation region (91), formed in the epitaxial layer (3).

51. The semiconductor device (100) according to clause 41, further comprising: at least one transistor, formed in the epitaxial layer (3).

52. A method for fabricating a semiconductor device (100), comprising:
providing a semiconductor body (11), wherein the semiconductor body (11) comprises a substrate (1), a buried layer (2) disposed on the substrate (1), and an epitaxial layer (3) disposed on the buried layer (2), the substrate (1) has a first doping type, and the buried layer (2) has a second doping type opposite to the first doping type;
forming a hard mask layer (4) on a top surface of the epitaxial layer (3);
etching the hard mask layer (4) and the semiconductor body (11) by using a third soft mask layer to form, in the hard mask layer (4), a third trench opening (530) that penetrates through the hard mask layer (4) and to form, in the semiconductor body (11), a third trench (53) aligned with the third trench opening (530), wherein the third trench (53) extends from the top surface of the epitaxial layer (3) into the buried layer (2) or to a position in the epitaxial layer (3) and near the buried layer (2) and has a third depth (D3);
stripping the third soft mask layer;
filling the third trench opening (530) and the third trench (53) with a second conductive material (62);
etching the hard mask layer (4) and the semiconductor body (11) by using a fourth soft mask layer to form, in the hard mask layer (4), a first trench opening (510) that penetrates through the hard mask layer (4), and to form, in the semiconductor body (11), a first trench (51) aligned with the first trench opening (510), wherein the first trench (51) extends from the top surface of the epitaxial layer (3) into the substrate (1) and has a first depth (D1); and
forming a first deep trench structure (511) in the first trench (51), wherein the first deep trench structure (511) is configured to electrically connect the substrate (1) to the top surface of the epitaxial layer (3).

53. The method according to clause 52, wherein the second conductive material (62) comprises polysilicon having the second doping type.

54. The method according to clause 53, further comprising: performing thermal annealing on the polysilicon having the second doping type, so that a dopant in the polysilicon is diffused into a region of the epitaxial layer (3) near a sidewall of the third trench (53) to form a doped region, wherein the doped region extends from the top surface of the epitaxial layer (3) to the buried layer (2), and is configured to electrically connect the buried layer (2) to the top surface of the epitaxial layer (3) together with the polysilicon.

55. The method according to clause 52, wherein forming the hard mask layer (4) comprises:
growing a first oxide layer (41) on the top surface of the epitaxial layer (3);
depositing a nitride layer (42) on the first oxide layer (41); and
depositing a second oxide layer (43) on the nitride layer (42).

56. The method according to clause 52, wherein forming the first deep trench structure (511) in the first trench (51) comprises:
forming a pad (7) on a sidewall and a bottom of the first trench (51);
forming a dielectric layer (8) inside the pad (7) in the first trench (51), wherein the dielectric layer (8) comprises a second opening (54) extending from the top surface of the epitaxial layer (3) toward the bottom of the first trench (51);
performing anisotropic etching on the dielectric layer (8) and the pad (7) in the first trench (51), so that the second opening (54) extends to the pad (7) at the bottom of the first trench (51), and a first opening (71) aligned with the second opening (54) is formed in the pad (7) at the bottom of the first trench (51); and
filling the first opening (71) and the second opening (54) with a first conductive material (61), wherein the first conductive material (61) is configured to electrically connect the substrate (1) to the top surface of the epitaxial layer (3).

57. The method according to clause 56, wherein the first conductive material (61) comprises polysilicon having the first doping type.

58. The method according to clause 56, further comprising:
forming a second doped region (9) in the substrate (1) near the bottom of the first trench (51), wherein the second doped region (9) has the first doping type and has a doping concentration higher than that of the substrate (1).

59. The method according to clause 52, wherein the formation of the first deep trench structure (511) comprises:
forming a pad (7) on a sidewall and a bottom of the first trench (51); and
forming a dielectric layer (8) inside the pad (7) in the first trench (51), so that the dielectric layer (8) forms, in the first trench (51), a second opening (54) that extends from the top surface of the epitaxial layer (3) toward the bottom of the first trench (51).

60. The method according to clause 59, wherein the formation of the first deep trench structure (511) further comprises:
performing anisotropic etching on the dielectric layer (8) and the pad (7), so that the second opening (54) extends to the pad (7) at the bottom of the first trench (51), and a first opening (71) aligned with the second opening (54) is formed in the pad (7) at the bottom of the first trench (51);
performing ion implantation on the substrate (1) through the second opening (54) and the first opening (71) to form a second doped region (9) in the substrate (1) near the bottom of the first trench (51), wherein the second doped region (9) has the first doping type and has a doping concentration higher than that of the substrate (1); and
filling the first opening (71) and the second opening (54) with a first conductive material (61) to form the first deep trench structure (511).

61. The method according to clause 52, further comprising: performing ion implantation on the substrate (1) near a bottom of the first trench (51) to form a doped region, wherein the doped region has the first doping type and has a doping concentration higher than that of the substrate (1).

62. The method according to clause 61, further comprising: forming a thin protective layer in the first trench (51) and on an upper surface of the third trench (53) prior to the ion implantation.

63. The method according to clause 52, further comprising:
forming a shallow trench isolation region (91) in the epitaxial layer (3).

64. The method according to clause 52, further comprising:
forming at least one transistor in the epitaxial layer (3).

65. A method for fabricating a semiconductor device (100), comprising:
providing a semiconductor body (11), wherein the semiconductor body (11) comprises a substrate (1), a buried layer (2) disposed on the substrate (1), and an epitaxial layer (3) disposed on the buried layer (2), the substrate (1) has a first doping type, and the buried layer (2) has a second doping type opposite to the first doping type;
forming a hard mask layer (4) on a top surface of the epitaxial layer (3);
etching the hard mask layer (4) and the semiconductor body (11) by using a fifth soft mask layer to form, in the hard mask layer (4), a first trench opening (510) that penetrates through the hard mask layer (4), and to form, in the semiconductor body (11), a first trench (51) aligned with the first trench opening (510), wherein the first trench (51) extends from the top surface of the epitaxial layer (3) into the substrate (1) and has a first depth (D1);
stripping the fifth soft mask layer;
forming a first deep trench structure (511) in the first trench (51), wherein the first deep trench structure (511) is configured to electrically connect the substrate (1) to the top surface of the epitaxial layer (3);
stripping the hard mask layer (4);
etching the semiconductor body (11) by using a sixth soft mask layer to form a third trench (53) in the semiconductor body (11), wherein the third trench (53) extends from the top surface of the epitaxial layer (3) into the buried layer (2) or to a position in the epitaxial layer (3) and near the buried layer (2) and has a third depth (D3) less than the first depth (D1); and
filling the third trench (53) with a second conductive material (62), wherein the second conductive material (62) is configured to electrically connect the buried layer (2) to the top surface of the epitaxial layer (3).

66. The method according to clause 65, wherein the second conductive material (62) comprises polysilicon having the second doping type.

67. The method according to clause 66, further comprising: performing thermal annealing on the polysilicon having the second doping type, so that a dopant in the polysilicon is diffused into a region of the epitaxial layer (3) near a sidewall of the third trench (53) to form a doped region, wherein the doped region extends from the top surface of the epitaxial layer (3) to the buried layer (2), and is configured to electrically connect the buried layer (2) to the top surface of the epitaxial layer (3) together with the polysilicon.

68. The method according to clause 65, wherein forming the hard mask layer (4) comprises:
growing a first oxide layer (41) on the top surface of the epitaxial layer (3);
depositing a nitride layer (42) on the first oxide layer (41); and
depositing a second oxide layer (43) on the nitride layer (42).

69. The method according to clause 65, wherein forming the first deep trench structure (511) in the first trench (51) comprises:
forming a pad (7) on a sidewall and a bottom of the first trench (51);
forming a dielectric layer (8) inside the pad (7) in the first trench (51), wherein the dielectric layer (8) comprises a second opening (54) extending from the top surface of the epitaxial layer (3) toward the bottom of the first trench (51);
performing anisotropic etching on the dielectric layer (8) and the pad (7) in the first trench (51), so that the second opening (54) extends to the pad (7) at the bottom of the first trench (51), and a first opening (71) aligned with the second opening (54) is formed in the pad (7) at the bottom of the first trench (51); and
filling the first opening (71) and the second opening (54) with a first conductive material (61), wherein the first conductive material (61) is configured to electrically connect the substrate (1) to the top surface of the epitaxial layer (3).

70. The method according to clause 69, wherein the first conductive material (61) comprises polysilicon having the first doping type.

71. The method according to clause 65, further comprising:
forming a second doped region (9) in the substrate (1) near the bottom of the first trench (51), wherein the second doped region (9) has the first doping type and has a doping concentration higher than that of the substrate (1).

72. The method according to clause 65, wherein the formation of the first deep trench structure (511) comprises:
forming a pad (7) on a sidewall and a bottom of the first trench (51); and
forming a dielectric layer (8) inside the pad (7) in the first trench (51), so that the dielectric layer (8) forms, in the first trench (51), a second opening (54) that extends from the top surface of the epitaxial layer (3) toward the bottom of the first trench (51).

73. The method according to clause 72, wherein the formation of the first deep trench structure (511) further comprises:
performing anisotropic etching on the dielectric layer (8) and the pad (7), so that the second opening (54) extends to the pad (7) at the bottom of the first trench (51), and a first opening (71) aligned with the second opening (54) is formed in the pad (7) at the bottom of the first trench (51);
performing ion implantation on the substrate (1) through the second opening (54) and the first opening (71) to form a second doped region (9) in the substrate (1) near the bottom of the first trench (51), wherein the second doped region (9) has the first doping type and has a doping concentration higher than that of the substrate (1); and
filling the first opening (71) and the second opening (54) with a first conductive material (61) to form the first deep trench structure (511).

74. The method according to clause 65, further comprising: performing ion implantation on the substrate (1) near a bottom of the first trench (51) to form a doped region, wherein the doped region has the first doping type and has a doping concentration higher than that of the substrate (1).

75. The method according to clause 74, further comprising: forming a thin protective layer in the first trench (51) and on an upper surface of the third trench (53) prior to the ion implantation.

76. The method according to clause 65, further comprising:
forming a shallow trench isolation region (91) in the epitaxial layer (3) after the first deep trench structure (511) is formed and before the third trench (53) is formed.

77. The method according to clause 65, further comprising:
forming at least one transistor in the epitaxial layer (3).

78. A method for fabricating a semiconductor device (100), comprising:
providing a semiconductor body (11), wherein the semiconductor body (11) comprises a substrate (1), a buried layer (2) disposed on the substrate (1), and an epitaxial layer (3) disposed on the buried layer (2), the substrate (1) has a first doping type, and the buried layer (2) has a second doping type opposite to the first doping type;
forming a hard mask layer (4) on a top surface of the epitaxial layer (3);
etching the hard mask layer (4) and the semiconductor body (11) by using a seventh soft mask layer to simultaneously form a first trench (51) and a third trench (53) in the semiconductor body (11), wherein the first trench (51) extends from the top surface of the epitaxial layer (3) into the substrate (1) and has a first depth (D1), and the third trench (53) extends from the top surface of the epitaxial layer (3) into the buried layer (2) or to a position in the epitaxial layer (3) and near the buried layer (2) and has a third depth (D3) less than the first depth (D1);
forming a first deep trench structure (511) in the first trench (51), wherein the first deep trench structure (511) is configured to electrically connect the substrate (1) to the top surface of the epitaxial layer (3);
forming a temporary deep trench structure (534) in the third trench (53);
etching the temporary deep trench structure (534) in the third trench (53) by using an eighth soft mask layer (103) to remove the temporary deep trench structure (534) in the third trench (53); and
filling the third trench (53) with a second conductive material (62), wherein the second conductive material (62) is configured to electrically connect the buried layer (2) to the top surface of the epitaxial layer (3).

79. The method according to clause 78, wherein the second conductive material (62) comprises polysilicon having the second doping type.

80. The method according to clause 79, further comprising: performing thermal annealing on the polysilicon having the second doping type, so that a dopant in the polysilicon is diffused into a region of the epitaxial layer (3) near a sidewall of the third trench (53) to form a doped region, wherein the doped region extends from the top surface of the epitaxial layer (3) to the buried layer (2), and is configured to electrically connect the buried layer (2) to the top surface of the epitaxial layer (3) together with the polysilicon.

81. The method according to clause 78, wherein forming the hard mask layer (4) comprises:
growing a first oxide layer (41) on the top surface of the epitaxial layer (3);
depositing a nitride layer (42) on the first oxide layer (41); and
depositing a second oxide layer (43) on the nitride layer (42).

82. The method according to clause 78, wherein forming the first deep trench structure (511) in the first trench (51) comprises:
forming a pad (7) on a sidewall and a bottom of the first trench (51);
forming a dielectric layer (8) inside the pad (7) in the first trench (51), wherein the dielectric layer (8) comprises a second opening (54) extending from the top surface of the epitaxial layer (3) toward the bottom of the first trench (51);
performing anisotropic etching on the dielectric layer (8) and the pad (7) in the first trench (51), so that the second opening (54) extends to the pad (7) at the bottom of the first trench (51), and a first opening (71) aligned with the second opening (54) is formed in the pad (7) at the bottom of the first trench (51); and
filling the first opening (71) and the second opening (54) with a first conductive material (61), wherein the first conductive material (61) is configured to electrically connect the substrate (1) to the top surface of the epitaxial layer (3).

83. The method according to clause 82, wherein the first conductive material (61) comprises polysilicon having the first doping type.

84. The method according to clause 82, further comprising:
forming a second doped region (9) in the substrate (1) near the bottom of the first trench (51), wherein the second doped region (9) has the first doping type and has a doping concentration higher than that of the substrate (1).

85. The method according to clause 78, wherein the formation of the first deep trench structure (511) and the temporary deep trench structure (534) comprises:
forming a pad (7) on a sidewall and a bottom of each of the first trench (51) and the third trench (53); and
forming a dielectric layer (8) inside the pad (7) in the first trench (51) and the third trench (53), so that the dielectric layer (8) forms, in the first trench (51), a second opening (54) that extends from the top surface of the epitaxial layer (3) toward the bottom of the first trench (51), and the dielectric layer (8) completely fills the third trench (53), wherein the pad (7) and the dielectric layer (8) in the third trench (53) form the temporary deep trench structure (534).

86. The method according to clause 85, wherein the formation of the first deep trench structure (511) further comprises:
performing anisotropic etching on the dielectric layer (8) and the pad (7), so that the second opening (54) extends to the pad (7) at the bottom of the first trench (51), and a first opening (71) aligned with the second opening (54) is formed in the pad (7) at the bottom of the first trench (51);
performing ion implantation on the substrate (1) through the second opening (54) and the first opening (71) to form a second doped region (9) in the substrate (1) near the bottom of the first trench (51), wherein the second doped region (9) has the first doping type and has a doping concentration higher than that of the substrate (1); and
filling the first opening (71) and the second opening (54) with a first conductive material (61) to form the first deep trench structure (511).

87. The method according to clause 78, further comprising: performing ion implantation on the substrate (1) near a bottom of the first trench (51) to form a doped region, wherein the doped region has the first doping type and has a doping concentration higher than that of the substrate (1).

88. The method according to clause 87, further comprising: forming a thin protective layer in the first trench (51) and on an upper surface of the third trench (53) prior to the ion implantation.

89. The method according to clause 78, wherein etching the temporary deep trench structure (534) in the third trench (53) by using the eighth soft mask layer (103) comprises:
etching the temporary deep trench structure (534) in the third trench (53) by using the eighth soft mask layer (103) to remove a portion of the temporary deep trench structure (534) in the third trench (53), thereby forming a second shallow trench (532);
forming a sidewall spacer (556) on a sidewall of each of a third trench opening (530) in the hard mask layer (4) and the second shallow trench (532); and
removing the remaining portion of the temporary deep trench structure (534) in the third trench (53).

90. The method according to clause 78, further comprising:
forming a shallow trench isolation region (91) in the epitaxial layer (3).

91. The method according to clause 78, further comprising:
forming at least one transistor in the epitaxial layer (3).

92. A method for fabricating a semiconductor device (100), comprising:
providing a semiconductor body (11), wherein the semiconductor body (11) comprises a substrate (1), a buried layer (2) disposed on the substrate (1), and an epitaxial layer (3) disposed on the buried layer (2), the substrate (1) has a first doping type, and the buried layer (2) has a second doping type opposite to the first doping type;
forming a hard mask layer (4) on a top surface of the epitaxial layer (3);
etching the hard mask layer (4) and the semiconductor body (11) by using a seventh soft mask layer to simultaneously form a first trench (51) and a third trench (53) in the semiconductor body (11), wherein the first trench (51) extends from the top surface of the epitaxial layer (3) into the substrate (1) and has a first depth (D1), and the third trench (53) extends from the top surface of the epitaxial layer (3) into the buried layer (2) or to a position in the epitaxial layer (3) and near the buried layer (2) and has a third depth (D3) less than the first depth (D1);
forming a first deep trench structure (511) in the first trench (51), wherein the first deep trench structure (511) is configured to electrically connect the substrate (1) to the top surface of the epitaxial layer (3);
forming a temporary deep trench structure (534) in the third trench (53);
etching the temporary deep trench structure (534) in the third trench (53) by using an eighth soft mask layer (103) to remove the temporary deep trench structure (534) in the third trench (53);
obliquely implanting, in the third trench (53), a dopant of the second doping type into the semiconductor body (11) to form, in the epitaxial layer (3), a first doped region (82) having the second doping type near a sidewall of the third trench (53), wherein the first doped region (82) extends from the top surface of the epitaxial layer (3) to the buried layer (2), and is configured to electrically connect the buried layer (2) to the top surface of the epitaxial layer (3); and
filling the third trench (53) with a dielectric material (83) to form a third deep trench isolation structure (531).

93. The method according to clause 92, wherein the formation of the first deep trench structure (511) and the temporary deep trench structure (534) comprises:
forming a pad (7) on a sidewall and a bottom of each of the first trench (51) and the third trench (53); and
forming a dielectric layer (8) inside the pad (7) in the first trench (51) and the third trench (53), so that the dielectric layer (8) forms, in the first trench (51), a second opening (54) that extends from the top surface of the epitaxial layer (3) toward the bottom of the first trench (51), and the dielectric layer (8) completely fills the third trench (53), wherein the pad (7) and the dielectric layer (8) in the third trench (53) form the temporary deep trench structure (534).

94. The method according to clause 93, wherein the formation of the first deep trench structure (511) further comprises:
performing anisotropic etching on the dielectric layer (8) and the pad (7), so that the second opening (54) extends to the pad (7) at the bottom of the first trench (51), and a first opening (71) aligned with the second opening (54) is formed in the pad (7) at the bottom of the first trench (51);
performing ion implantation on the substrate (1) through the second opening (54) and the first opening (71) to form a second doped region (9) in the substrate (1) near the bottom of the first trench (51), wherein the second doped region (9) has the first doping type and has a doping concentration higher than that of the substrate (1); and
filling the first opening (71) and the second opening (54) with a first conductive material (61) to form the first deep trench structure (511).

95. The method according to clause 92, further comprising: performing ion implantation on the substrate (1) near a bottom of the first trench (51) to form a doped region, wherein the doped region has the first doping type and has a doping concentration higher than that of the substrate (1).

96. The method according to clause 95, further comprising: forming a thin protective layer in the first trench (51) and on an upper surface of the third trench (53) prior to the ion implantation.

97. The method according to clause 92, wherein etching the temporary deep trench structure (534) in the third trench (53) by using the eighth soft mask layer (103) comprises: etching the temporary deep trench structure (534) in the third trench (53) by using the eighth soft mask layer (103) to remove a portion of the temporary deep trench structure (534) in the third trench (53), thereby forming a second shallow trench (532);
forming a sidewall spacer (556) on a sidewall of each of a third trench opening (530) in the hard mask layer (4) and the second shallow trench (532); and
removing the remaining portion of the temporary deep trench structure (534) in the third trench (53).

98. The method according to clause 92, wherein the dielectric material (83) comprises oxide or undoped polysilicon.

99. A semiconductor device (100), comprising:
a semiconductor body (11), wherein the semiconductor body (11) comprises a substrate (1), a buried layer (2) disposed on the substrate (1), and an epitaxial layer (3) disposed on the buried layer (2), the substrate (1) has a first doping type, and the buried layer (2) has a second doping type opposite to the first doping type;
a first trench (51), extending from a top surface of the epitaxial layer (3) into the substrate (1) and having a first depth (D1);
a third trench (53), extending from the top surface of the epitaxial layer (3) into the buried layer (2) and having a third depth (D3) less than the first depth (D1);
a first deep trench structure (511), disposed in the first trench (51) and configured to electrically connect the substrate (1) to the top surface of the epitaxial layer (3); and
a second conductive material (62), filling the third trench (53), and configured to electrically connect the buried layer (2) to the top surface of the epitaxial layer (3).

100. The semiconductor device (100) according to clause 99, wherein the first deep trench structure (511) comprises:
a pad (7), formed on a sidewall and at least a portion of a bottom of the first trench (51), and comprising a first opening (71) formed at the bottom of the first trench (51);
a dielectric layer (8), disposed inside the pad (7) in the first trench (51), and comprising a second opening (54) extending from the top surface of the epitaxial layer (3) to the pad (7) at the bottom of the first trench (51), wherein the second opening (54) is aligned with the first opening (71); and
a first conductive material (61), filling the first opening (71) and the second opening (54), and configured to electrically connect the substrate (1) to the top surface of the epitaxial layer (3).

101. The semiconductor device (100) according to clause 100, wherein the first conductive material (61) comprises polysilicon having the first doping type.

102. The semiconductor device (100) according to clause 99, wherein the second conductive material (62) comprises polysilicon having the second doping type.

103. The semiconductor device (100) according to clause 99, further comprising:
a first doped region (82), formed in the epitaxial layer (3) near a sidewall of the third trench (53) and having the second doping type, wherein the first doped region (82) extends from the top surface of the epitaxial layer (3) to the buried layer (2), and is configured to electrically connect the buried layer (2) to the top surface of the epitaxial layer (3) together with the second conductive material (62).

104. The semiconductor device (100) according to clause 99, further comprising a second doped region (9), wherein the second doped region (9) is formed in the substrate (1) near a bottom of the first trench (51), and the second doped region (9) has the first doping type and has a doping concentration higher than that of the substrate (1).

105. The semiconductor device (100) according to clause 99, further comprising:
a shallow trench isolation region (91), formed in the epitaxial layer (3).

106. The semiconductor device (100) according to clause 99, further comprising: at least one transistor, formed in the epitaxial layer (3).

### THIRD SET OF CLAUSES

1. A method for fabricating a semiconductor device (100), comprising:
providing a semiconductor body (11), wherein the semiconductor body (11) comprises a substrate (1), a buried layer (2) disposed on the substrate (1), and an epitaxial layer (3) disposed on the buried layer (2), the substrate (1) has a first doping type, and the buried layer (2) has a second doping type opposite to the first doping type;
forming a hard mask layer (4) on a top surface of the epitaxial layer (3);
etching the hard mask layer (4) and the semiconductor body (11) by using a single soft mask layer (10) to simultaneously form a second trench (52) and a third trench (53) in the semiconductor body (11), wherein the second trench (52) extends from the top surface of the epitaxial layer (3) into the substrate (1) and has a second depth (D2), and the third trench (53) extends from the top surface of the epitaxial layer (3) into the buried layer (2) or to a position in the epitaxial layer (3) and near the buried layer (2) and has a third depth (D3) less than the second depth (D2);
forming, in the epitaxial layer (3), a first doped region (82) having the second doping type near a sidewall of the third trench (53), wherein the first doped region (82) extends from the top surface of the epitaxial layer (3) to the buried layer (2), and is configured to electrically connect the buried layer (2) to the top surface of the epitaxial layer (3);
forming a second deep trench isolation structure (521) in the second trench (52), wherein the second deep trench isolation structure (521) is configured to isolate different component regions in the epitaxial layer (3); and
forming a third deep trench isolation structure (531) in the third trench (53), wherein the third deep trench isolation structure (531) is configured to isolate different component regions in the epitaxial layer (3).

2. The method according to clause 1, wherein forming the hard mask layer (4) comprises:
growing a first oxide layer (41) on the top surface of the epitaxial layer (3);
depositing a nitride layer (42) on the first oxide layer (41); and
depositing a second oxide layer (43) on the nitride layer (42).

3. The method according to clause 1, wherein etching the hard mask layer (4) and the semiconductor body (11) by using the single soft mask layer (10) comprises:
performing first etching on the hard mask layer (4) by using the single soft mask layer (10) to simultaneously form, in the hard mask layer (4) a second trench opening (520) and a third trench opening (530) that penetrate through the hard mask layer (4);
stripping the single soft mask layer (10); and
performing second etching on the semiconductor body (11) by using the hard mask layer (4) to form, in the semiconductor body (11), the second trench (52) aligned with the second trench opening (520) and the third trench (53) aligned with the third trench opening (530).

4. The method according to clause 1, wherein etching the hard mask layer (4) and the semiconductor body (11) by using the single soft mask layer (10) comprises:
performing first etching on the hard mask layer (4) and the epitaxial layer (3) by using the single soft mask layer (10) to simultaneously form, in the hard mask layer (4) a second trench opening (520) and a third trench opening (530) that penetrate through the hard mask layer (4), and to form, in the epitaxial layer (3), a first shallow trench (555) aligned with each of the second trench opening (520) and the third trench opening (530);
forming a sidewall spacer (556) on a sidewall of each of the second trench opening (520), the third trench opening (530), and the first shallow trench (555); and
performing second etching on the semiconductor body (11) via the first shallow trench (555) to form, in the semiconductor body (11), the second trench (52) aligned with the second trench opening (520) and the third trench (53) aligned with the third trench opening (530).

5. The method according to clause 4, further comprising:
removing the sidewall spacer (556) through isotropic etching after the first doped region (82) is formed.

6. The method according to clause 4, wherein the sidewall spacer (556) comprises nitride.

7. The method according to clause 1, wherein etching the hard mask layer (4) and the semiconductor body (11) by using the single soft mask layer (10) comprises:
performing single etching on the hard mask layer (4) and the semiconductor body (11) by using the single soft mask layer (10) to simultaneously form, in the hard mask layer (4) a second trench opening (520) and a third trench opening (530) that penetrate through the hard mask layer (4), and to simultaneously form, in the semiconductor body (11), the second trench (52) aligned with the second trench opening (520) and the third trench (53) aligned with the third trench opening (530).

8. The method according to clause 1, wherein forming the second deep trench isolation structure (521) in the second trench (52) comprises:
forming a pad (7) on a sidewall and a bottom of the second trench (52); and
forming a dielectric layer (8) inside the pad (7) in the second trench (52), wherein the dielectric layer (8) completely or partially fills the second trench (52).

9. The method according to clause 1, wherein forming the third deep trench isolation structure (531) in the third trench (53) comprises:
forming a pad (7) on a sidewall and a bottom of the third trench (53); and
forming a dielectric layer (8) inside the pad (7) in the third trench (53), wherein the dielectric layer (8) completely fills the third trench (53).

10. The method according to clause 1, wherein forming, in the epitaxial layer (3), the first doped region (82) having the second doping type near the sidewall of the third trench (53) comprises:
depositing a diffusion material (81) in the third trench (53), wherein the diffusion material (81) comprises a dopant of the second doping type; and
performing thermal annealing on the diffusion material (81), so that the dopant is diffused into a region of the epitaxial layer (3) near the sidewall of the third trench (53) to form the first doped region (82).

11. The method according to clause 10, wherein the diffusion material (81) partially fills the third trench (53), and wherein forming the third deep trench isolation structure (531) in the third trench (53) comprises:
continuing to fill the third trench (53) with a dielectric material to seal the diffusion material (81), wherein the diffusion material (81) and the dielectric material jointly form the third deep trench isolation structure (531).

12. The method according to clause 10, wherein when the first doping type is a p-type, the diffusion material (81) comprises at least one of POCl3 glass and phosphate silicate glass, and the dopant is a phosphorus element; and
when the first doping type is an n-type, the diffusion material (81) comprises borosilicate glass, and the dopant is a boron element.

13. The method according to clause 10, wherein the first doped region (82) is formed near both sides of the third trench (53).

14. The method according to clause 10, wherein the diffusion material (81) completely or partially fills the third trench (53).

15. The method according to clause 14, wherein an air gap (810) is formed inside the diffusion material (81).

16. The method according to clause 10, further comprising:
etching the diffusion material (81) in the third trench (53) to remove the diffusion material (81).

17. The method according to clause 16, wherein the formation of the second deep trench isolation structure (521) and the third deep trench isolation structure (531) comprises:
forming a pad (7) on a sidewall and a bottom of each of the second trench (52) and the third trench (53); and
forming a dielectric layer (8) inside the pad (7) in the second trench (52) and the third trench (53), so that the dielectric layer (8) completely fills the second trench (52) and the third trench (53), wherein the pad (7) and the dielectric layer (8) in the second trench (52) form the second deep trench isolation structure (521), and the pad (7) and the dielectric layer (8) in the third trench (53) form the third deep trench isolation structure (531).

18. The method according to clause 1, further comprising: performing ion implantation on the substrate (1) near a bottom of the second trench (52) to form a doped region, wherein the doped region has the first doping type and has a doping concentration higher than that of the substrate (1).

19. The method according to clause 18, further comprising: forming a thin protective layer in the second trench (52) and on an upper surface of the third trench (53) prior to the ion implantation.

20. The method according to clause 1, wherein forming, in the epitaxial layer (3), the first doped region (82) having the second doping type near the sidewall of the third trench (53) comprises:
forming the first doped region (82) by implanting, at an oblique angle, a dopant of the second doping type through the sidewall of the third trench (53).

21. The method according to clause 1, further comprising:
forming a shallow trench isolation region (91) in the epitaxial layer (3).

22. The method according to clause 1, further comprising:
forming at least one transistor in the epitaxial layer (3).

23. A method for fabricating a semiconductor device (100), comprising:
providing a semiconductor body (11), wherein the semiconductor body (11) comprises a substrate (1), a buried layer (2) disposed on the substrate (1), and an epitaxial layer (3) disposed on the buried layer (2), the substrate (1) has a first doping type, and the buried layer (2) has a second doping type opposite to the first doping type;
forming a hard mask layer (4) on a top surface of the epitaxial layer (3);
performing first etching on the hard mask layer (4) by using a first soft mask layer (101) to simultaneously form, in the hard mask layer (4), a second trench opening (520) and a third trench opening (530) that penetrate through the hard mask layer (4);
stripping the first soft mask layer (101);
forming a second soft mask layer (102) on the hard mask layer (4), wherein the second soft mask layer (102) comprises a third opening (1021) and the third opening (1021) exposes one or more portions of the hard mask layer (4) near the third trench opening (530);
implanting a dopant of the second doping type into the epitaxial layer (3) via the third opening (1021);
stripping the second soft mask layer (102);
performing second etching on the semiconductor body (11) by using the hard mask layer (4) to form, in the semiconductor body (11), a second trench (52) aligned with the second trench opening (520) and a third trench (53) aligned with the third trench opening (530);
performing thermal annealing on the dopant to form a first doped region (82) in a region of the epitaxial layer (3) near a sidewall of the third trench (53), wherein the first doped region (82) extends from the top surface of the epitaxial layer (3) to the buried layer (2), and is configured to electrically connect the buried layer (2) to the top surface of the epitaxial layer (3);
forming a second deep trench isolation structure (521) in the second trench (52), wherein the second deep trench isolation structure (521) is configured to isolate different component regions in the epitaxial layer (3); and
forming a third deep trench isolation structure (531) in the third trench (53), wherein the third deep trench isolation structure (531) is configured to isolate different component regions in the epitaxial layer (3).

24. The method according to clause 23, wherein when the first doping type is a p-type, the dopant is a phosphorus element; and when the first doping type is an n-type, the dopant is a boron element.

25. The method according to clause 23, wherein the first doped region (82) is formed only near one side of the third trench (53).

26. The method according to clause 25, wherein the first doped region (82) is formed between the second trench (52) and the third trench (53).

27. The method according to clause 23, wherein the formation of the second deep trench isolation structure (521) and the third deep trench isolation structure (531) comprises:
forming a pad (7) on a sidewall and a bottom of each of the second trench (52) and the third trench (53); and
forming a dielectric layer (8) inside the pad (7) in the second trench (52) and the third trench (53), so that the dielectric layer (8) completely fills the second trench (52) and the third trench (53), wherein the pad (7) and the dielectric layer (8) in the second trench (52) form the second deep trench isolation structure (521), and the pad (7) and the dielectric layer (8) in the third trench (53) form the third deep trench isolation structure (531).

28. The method according to clause 23, further comprising: performing ion implantation on the substrate (1) near a bottom of the second trench (52) to form a doped region, wherein the doped region has the first doping type and has a doping concentration higher than that of the substrate (1).

29. The method according to clause 28, further comprising: forming a thin protective layer in the second trench (52) and on an upper surface of the third trench (53) prior to the ion implantation.

30. The method according to clause 23, wherein forming the hard mask layer (4) comprises:
growing a first oxide layer (41) on the top surface of the epitaxial layer (3);
depositing a nitride layer (42) on the first oxide layer (41); and
depositing a second oxide layer (43) on the nitride layer (42).

31. The method according to clause 23, wherein forming the second deep trench isolation structure (521) in the second trench (52) comprises:
forming a pad (7) on a sidewall and a bottom of the second trench (52); and
forming a dielectric layer (8) inside the pad (7) in the second trench (52), wherein the dielectric layer (8) completely or partially fills the second trench (52).

32. The method according to clause 23, wherein forming the third deep trench isolation structure (531) in the third trench (53) comprises:
forming a pad (7) on a sidewall and a bottom of the third trench (53); and
forming a dielectric layer (8) inside the pad (7) in the third trench (53), wherein the dielectric layer (8) completely fills the third trench (53).

33. The method according to clause 23, further comprising:
forming a shallow trench isolation region (91) in the epitaxial layer (3).

34. The method according to clause 23, further comprising:
forming at least one transistor in the epitaxial layer (3).

35. A semiconductor device (100), comprising:
a semiconductor body (11), wherein the semiconductor body (11) comprises a substrate (1), a buried layer (2) disposed on the substrate (1), and an epitaxial layer (3) disposed on the buried layer (2), the substrate (1) has a first doping type, and the buried layer (2) has a second doping type opposite to the first doping type;
a second trench (52), extending from the top surface of the epitaxial layer (3) into the substrate (1) and having a second depth (D2);
a third trench (53), extending from the top surface of the epitaxial layer (3) into the buried layer (2) and having a third depth (D3) less than the second depth (D2);
a second deep trench isolation structure (521), disposed in the second trench (52) and configured to isolate different component regions in the epitaxial layer (3);
a third deep trench isolation structure (531), disposed in the third trench (53) and configured to isolate different component regions in the epitaxial layer (3); and
a first doped region (82), formed in the epitaxial layer (3) near a sidewall of the third trench (53) and having the second doping type, wherein the first doped region (82) extends from the top surface of the epitaxial layer (3) to the buried layer (2), and is configured to electrically connect the buried layer (2) to the top surface of the epitaxial layer (3).

36. The semiconductor device (100) according to clause 35, wherein the second deep trench isolation structure (521) comprises:
a pad (7), disposed on a sidewall and a bottom of the second trench (52); and
a dielectric layer (8), disposed inside the pad (7) in the second trench (52).

37. The semiconductor device (100) according to clause 35, wherein the third deep trench isolation structure (531) comprises:
a pad (7), disposed on a sidewall and a bottom of the third trench (53); and
a dielectric layer (8), disposed inside the pad (7) in the third trench (53).

38. The semiconductor device (100) according to clause 35, wherein the third deep trench isolation structure (531) comprises:
a diffusion material (81), partially filling the third trench (53); and
a dielectric material, sealing the diffusion material (81) in the third trench (53), wherein the diffusion material (81) and the dielectric material jointly form the third deep trench isolation structure (531).

39. The semiconductor device (100) according to clause 35, wherein the third deep trench isolation structure (531) comprises oxide or undoped polysilicon.

40. The semiconductor device (100) according to clause 35, wherein the first doped region (82) is disposed near both sides of the third trench (53) or only near one side of the third trench (53).

41. The semiconductor device (100) according to clause 40, wherein the first doped region (82) is formed between the second trench (52) and the third trench (53).

42. The semiconductor device (100) according to clause 35, further comprising a third doped region, wherein the third doped region is formed in the substrate (1) near a bottom of the second trench (52), and the third doped region has the first doping type and has a doping concentration higher than that of the substrate (1).

43. The semiconductor device (100) according to clause 35, further comprising:
a shallow trench isolation region (91), formed in the epitaxial layer (3).

44. The semiconductor device (100) according to clause 35, further comprising:
at least one transistor, formed in the epitaxial layer (3).

45. A method for fabricating a semiconductor device (100), comprising:
providing a semiconductor body (11), wherein the semiconductor body (11) comprises a substrate (1), a buried layer (2) disposed on the substrate (1), and an epitaxial layer (3) disposed on the buried layer (2), the substrate (1) has a first doping type, and the buried layer (2) has a second doping type opposite to the first doping type;
forming a hard mask layer (4) on a top surface of the epitaxial layer (3);
etching the hard mask layer (4) and the semiconductor body (11) by using a third soft mask layer to form, in the hard mask layer (4), a third trench opening (530) that penetrates through the hard mask layer (4) and to form, in the semiconductor body (11), a third trench (53) aligned with the third trench opening (530), wherein the third trench (53) extends from the top surface of the epitaxial layer (3) into the buried layer (2) or to a position in the epitaxial layer (3) and near the buried layer (2) and has a third depth (D3);
stripping the third soft mask layer;
filling the third trench opening (530) and the third trench (53) with a second conductive material (62);
etching the hard mask layer (4) and the semiconductor body (11) by using a fourth soft mask layer to form, in the hard mask layer (4), a second trench opening (520) that penetrate through the hard mask layer (4), and to form, in the semiconductor body (11), a second trench (52) aligned with the second trench opening (520), wherein the second trench (52) extends from the top surface of the epitaxial layer (3) into the substrate (1) and has a second depth (D2) greater than the third depth (D3); and
forming a second deep trench isolation structure (521) in the second trench (52), wherein the second deep trench isolation structure (521) is configured to isolate different component regions in the epitaxial layer (3).

46. The method according to clause 45, wherein the second conductive material (62) comprises polysilicon having the second doping type.

47. The method according to clause 46, further comprising: performing thermal annealing on the polysilicon having the second doping type, so that a dopant in the polysilicon is diffused into a region of the epitaxial layer (3) near a sidewall of the third trench (53) to form a doped region, wherein the doped region extends from the top surface of the epitaxial layer (3) to the buried layer (2), and is configured to electrically connect the buried layer (2) to the top surface of the epitaxial layer (3) together with the polysilicon.

48. The method according to clause 45, wherein forming the hard mask layer (4) comprises:
growing a first oxide layer (41) on the top surface of the epitaxial layer (3);
depositing a nitride layer (42) on the first oxide layer (41); and
depositing a second oxide layer (43) on the nitride layer (42).

49. The method according to clause 45, wherein forming the second deep trench isolation structure (521) in the second trench (52) comprises:
forming a pad (7) on a sidewall and a bottom of the second trench (52); and
forming a dielectric layer (8) inside the pad (7) in the second trench (52), wherein the dielectric layer (8) completely or partially fills the second trench (52).

50. The method according to clause 45, wherein the formation of the second deep trench isolation structure (521) comprises:
forming a pad (7) on a sidewall and a bottom of the second trench (52); and
forming a dielectric layer (8) inside the pad (7) in the second trench (52), so that the dielectric layer (8) completely or partially fills the second trench (52), wherein the pad (7) and the dielectric layer (8) in the second trench (52) form the second deep trench isolation structure (521).

51. The method according to clause 45, further comprising: performing ion implantation on the substrate (1) near a bottom of the second trench (52) to form a doped region, wherein the doped region has the first doping type and has a doping concentration higher than that of the substrate (1).

52. The method according to clause 51, further comprising: forming a thin protective layer in the second trench (52) and on an upper surface of the third trench (53) prior to the ion implantation.

53. The method according to clause 45, further comprising:
forming a shallow trench isolation region (91) in the epitaxial layer (3).

54. The method according to clause 45, further comprising:
forming at least one transistor in the epitaxial layer (3).

55. A method for fabricating a semiconductor device (100), comprising:
providing a semiconductor body (11), wherein the semiconductor body (11) comprises a substrate (1), a buried layer (2) disposed on the substrate (1), and an epitaxial layer (3) disposed on the buried layer (2), the substrate (1) has a first doping type, and the buried layer (2) has a second doping type opposite to the first doping type;
forming a hard mask layer (4) on a top surface of the epitaxial layer (3);
etching the hard mask layer (4) and the semiconductor body (11) by using a fifth soft mask layer to form, in the hard mask layer (4), a second trench opening (520) that penetrates through the hard mask layer (4), and to form, in the semiconductor body (11), a second trench (52) aligned with the second trench opening (520), wherein the second trench (52) extends from the top surface of the epitaxial layer (3) into the substrate (1) and has a second depth (D2);
stripping the fifth soft mask layer;
forming a second deep trench isolation structure (521) in the second trench (52), wherein the second deep trench isolation structure (521) is configured to isolate different component regions in the epitaxial layer (3);
stripping the hard mask layer (4);
etching the semiconductor body (11) by using a sixth soft mask layer to form a third trench (53) in the semiconductor body (11), wherein the third trench (53) extends from the top surface of the epitaxial layer (3) into the buried layer (2) or to a position in the epitaxial layer (3) and near the buried layer (2) and has a third depth (D3) less than the second depth (D2); and
filling the third trench (53) with a second conductive material (62), wherein the second conductive material (62) is configured to electrically connect the buried layer (2) to the top surface of the epitaxial layer (3).

56. The method according to clause 55, wherein the second conductive material (62) comprises polysilicon having the second doping type.

57. The method according to clause 56, further comprising: performing thermal annealing on the polysilicon having the second doping type, so that a dopant in the polysilicon is diffused into a region of the epitaxial layer (3) near a sidewall of the third trench (53) to form a doped region, wherein the doped region extends from the top surface of the epitaxial layer (3) to the buried layer (2), and is configured to electrically connect the buried layer (2) to the top surface of the epitaxial layer (3) together with the polysilicon.

58. The method according to clause 55, wherein forming the hard mask layer (4) comprises:
growing a first oxide layer (41) on the top surface of the epitaxial layer (3);
depositing a nitride layer (42) on the first oxide layer (41); and
depositing a second oxide layer (43) on the nitride layer (42).

59. The method according to clause 55, wherein forming the second deep trench isolation structure (521) in the second trench (52) comprises:
forming a pad (7) on a sidewall and a bottom of the second trench (52); and
forming a dielectric layer (8) inside the pad (7) in the second trench (52), wherein the dielectric layer (8) completely or partially fills the second trench (52).

60. The method according to clause 55, wherein the formation of the second deep trench isolation structure (521) comprises:
forming a pad (7) on a sidewall and a bottom of the second trench (52); and
forming a dielectric layer (8) inside the pad (7) in the second trench (52), so that the dielectric layer (8) completely or partially fills the second trench (52), wherein the pad (7) and the dielectric layer (8) in the second trench (52) form the second deep trench isolation structure (521).

61. The method according to clause 55, further comprising: performing ion implantation on the substrate (1) near a bottom of the second trench (52) to form a doped region, wherein the doped region has the first doping type and has a doping concentration higher than that of the substrate (1).

62. The method according to clause 61, further comprising: forming a thin protective layer in the second trench (52) and on an upper surface of the third trench (53) prior to the ion implantation.

63. The method according to clause 55, further comprising:
forming a shallow trench isolation region (91) in the epitaxial layer (3) after the second deep trench isolation structure (521) is formed and before the third trench (53) is formed.

64. The method according to clause 55, further comprising:
forming at least one transistor in the epitaxial layer (3).

65. A method for fabricating a semiconductor device (100), comprising:
providing a semiconductor body (11), wherein the semiconductor body (11) comprises a substrate (1), a buried layer (2) disposed on the substrate (1), and an epitaxial layer (3) disposed on the buried layer (2), the substrate (1) has a first doping type, and the buried layer (2) has a second doping type opposite to the first doping type;
forming a hard mask layer (4) on a top surface of the epitaxial layer (3);
etching the hard mask layer (4) and the semiconductor body (11) by using a seventh soft mask layer to simultaneously form a second trench (52) and a third trench (53) in the semiconductor body (11), wherein the second trench (52) extends from the top surface of the epitaxial layer (3) into the substrate (1) and has a second depth (D2), and the third trench (53) extends from the top surface of the epitaxial layer (3) into the buried layer (2) or to a position in the epitaxial layer (3) and near the buried layer (2) and has a third depth (D3) less than the second depth (D2);
forming a second deep trench isolation structure (521) in the second trench (52), wherein the second deep trench isolation structure (521) is configured to isolate different component regions in the epitaxial layer (3);
forming a temporary deep trench structure (534) in the third trench (53);
etching the temporary deep trench structure (534) in the third trench (53) by using an eighth soft mask layer (103) to remove the temporary deep trench structure (534) in the third trench (53); and
filling the third trench (53) with a second conductive material (62), wherein the second conductive material (62) is configured to electrically connect the buried layer (2) to the top surface of the epitaxial layer (3).

66. The method according to clause 65, wherein the second conductive material (62) comprises polysilicon having the second doping type.

67. The method according to clause 66, further comprising: performing thermal annealing on the polysilicon having the second doping type, so that a dopant in the polysilicon is diffused into a region of the epitaxial layer (3) near a sidewall of the third trench (53) to form a doped region, wherein the doped region extends from the top surface of the epitaxial layer (3) to the buried layer (2), and is configured to electrically connect the buried layer (2) to the top surface of the epitaxial layer (3) together with the polysilicon.

68. The method according to clause 65, wherein forming the hard mask layer (4) comprises:
growing a first oxide layer (41) on the top surface of the epitaxial layer (3);
depositing a nitride layer (42) on the first oxide layer (41); and depositing a second oxide layer (43) on the nitride layer (42).

69. The method according to clause 65, wherein forming the second deep trench isolation structure (521) in the second trench (52) comprises:
forming a pad (7) on a sidewall and a bottom of the second trench (52); and
forming a dielectric layer (8) inside the pad (7) in the second trench (52), wherein the dielectric layer (8) completely or partially fills the second trench (52).

70. The method according to clause 65, wherein the formation of the second deep trench isolation structure (521) and the temporary deep trench structure (534) comprises:
forming a pad (7) on a sidewall and a bottom of each of the second trench (52) and the third trench (53); and
forming a dielectric layer (8) inside the pad (7) in the second trench (52) and the third trench (53), so that the dielectric layer (8) completely fills the second trench (52) and the third trench (53), wherein the pad (7) and the dielectric layer (8) in the second trench (52) form the second deep trench isolation structure (521), and the pad (7) and the dielectric layer (8) in the third trench (53) form the temporary deep trench structure (534).

71. The method according to clause 65, further comprising: performing ion implantation on the substrate (1) near a bottom of the second trench (52) to form a doped region, wherein the doped region has the first doping type and has a doping concentration higher than that of the substrate (1).

72. The method according to clause 71, further comprising: forming a thin protective layer in the second trench (52) and on an upper surface of the third trench (53) prior to the ion implantation.

73. The method according to clause 65, wherein etching the temporary deep trench structure (534) in the third trench (53) by using the eighth soft mask layer (103) comprises:
etching the temporary deep trench structure (534) in the third trench (53) by using the eighth soft mask layer (103) to remove a portion of the temporary deep trench structure (534) in the third trench (53), thereby forming a second shallow trench (532);
forming a sidewall spacer (556) on a sidewall of each of a third trench opening (530) in the hard mask layer (4) and the second shallow trench (532); and
removing the remaining portion of the temporary deep trench structure (534) in the third trench (53).

74. The method according to clause 65, further comprising:
forming a shallow trench isolation region (91) in the epitaxial layer (3).

75. The method according to clause 65, further comprising:
forming at least one transistor in the epitaxial layer (3).

76. A method for fabricating a semiconductor device (100), comprising:
providing a semiconductor body (11), wherein the semiconductor body (11) comprises a substrate (1), a buried layer (2) disposed on the substrate (1), and an epitaxial layer (3) disposed on the buried layer (2), the substrate (1) has a first doping type, and the buried layer (2) has a second doping type opposite to the first doping type;
forming a hard mask layer (4) on a top surface of the epitaxial layer (3);
etching the hard mask layer (4) and the semiconductor body (11) by using a seventh soft mask layer to simultaneously form a second trench (52) and a third trench (53) in the semiconductor body (11), wherein the second trench (52) extends from the top surface of the epitaxial layer (3) into the substrate (1) and has a second depth (D2), and the third trench (53) extends from the top surface of the epitaxial layer (3) into the buried layer (2) or to a position in the epitaxial layer (3) and near the buried layer (2) and has a third depth (D3) less than the second depth (D2);
forming a second deep trench isolation structure (521) in the second trench (52), wherein the second deep trench isolation structure (521) is configured to isolate different component regions in the epitaxial layer (3);
forming a temporary deep trench structure (534) in the third trench (53);
etching the temporary deep trench structure (534) in the third trench (53) by using an eighth soft mask layer (103) to remove the temporary deep trench structure (534) in the third trench (53);
obliquely implanting, in the third trench (53), a dopant of the second doping type into the semiconductor body (11) to form, in the epitaxial layer (3), a first doped region (82) having the second doping type near a sidewall of the third trench (53), wherein the first doped region (82) extends from the top surface of the epitaxial layer (3) to the buried layer (2), and is configured to electrically connect the buried layer (2) to the top surface of the epitaxial layer (3); and
filling the third trench (53) with a dielectric material (83) to form a third deep trench isolation structure (531).

77. The method according to clause 76, wherein the formation of the second deep trench isolation structure (521) and the temporary deep trench structure (534) comprises:
forming a pad (7) on a sidewall and a bottom of each of the second trench (52) and the third trench (53); and
forming a dielectric layer (8) inside the pad (7) in the second trench (52) and the third trench (53), so that the dielectric layer (8) completely fills the second trench (52) and the third trench (53), wherein the pad (7) and the dielectric layer (8) in the second trench (52) form the second deep trench isolation structure (521), and the pad (7) and the dielectric layer (8) in the third trench (53) form the temporary deep trench structure (534).

78. The method according to clause 76, further comprising: performing ion implantation on the substrate (1) near a bottom of the second trench (52) to form a doped region, wherein the doped region has the first doping type and has a doping concentration higher than that of the substrate (1).

79. The method according to clause 78, further comprising: forming a thin protective layer in the second trench (52) and on an upper surface of the third trench (53) prior to the ion implantation.

80. The method according to clause 76, wherein etching the temporary deep trench structure (534) in the third trench (53) by using the eighth soft mask layer (103) comprises:
etching the temporary deep trench structure (534) in the third trench (53) by using the eighth soft mask layer (103) to remove a portion of the temporary deep trench structure (534) in the third trench (53), thereby forming a second shallow trench (532);
forming a sidewall spacer (556) on a sidewall of each of a third trench opening (530) in the hard mask layer (4) and the second shallow trench (532); and
removing the remaining portion of the temporary deep trench structure (534) in the third trench (53).

81. The method according to clause 76, wherein the dielectric material (83) comprises oxide or undoped polysilicon.

82. A semiconductor device (100), comprising:
a semiconductor body (11), wherein the semiconductor body (11) comprises a substrate (1), a buried layer (2) disposed on the substrate (1), and an epitaxial layer (3) disposed on the buried layer (2), the substrate (1) has a first doping type, and the buried layer (2) has a second doping type opposite to the first doping type;
a second trench (52), extending from the top surface of the epitaxial layer (3) into the substrate (1) and having a second depth (D2);
a third trench (53), extending from the top surface of the epitaxial layer (3) into the buried layer (2) and having a third depth (D3) less than the second depth (D2);
a second deep trench isolation structure (521), disposed in the second trench (52) and configured to isolate different component regions in the epitaxial layer (3); and
a second conductive material (62), filling the third trench (53), and configured to electrically connect the buried layer (2) to the top surface of the epitaxial layer (3).

83. The semiconductor device (100) according to clause 82, wherein the second deep trench isolation structure (521) comprises:
a pad (7), disposed on a sidewall and a bottom of the second trench (52); and
a dielectric layer (8), disposed inside the pad (7) in the second trench (52).

84. The semiconductor device (100) according to clause 82, wherein the second conductive material (62) comprises polysilicon having the second doping type.

85. The semiconductor device (100) according to clause 82, further comprising:
a first doped region (82), formed in the epitaxial layer (3) near a sidewall of the third trench (53) and having the second doping type, wherein the first doped region (82) extends from the top surface of the epitaxial layer (3) to the buried layer (2), and is configured to electrically connect the buried layer (2) to the top surface of the epitaxial layer (3) together with the second conductive material (62).

86. The semiconductor device (100) according to clause 82, further comprising:
a shallow trench isolation region (91), formed in the epitaxial layer (3).

87. The semiconductor device (100) according to clause 82, further comprising:
at least one transistor, formed in the epitaxial layer (3).

88. The semiconductor device (100) according to clause 82, further comprising a third doped region, wherein the third doped region is formed in the substrate (1) near a bottom of the second trench (52), and the third doped region has the first doping type and has a doping concentration higher than that of the substrate (1).

The foregoing has described the embodiments of the present disclosure. The foregoing description is exemplary, is not exhaustive, and is not limited to the disclosed embodiments. Without departing from the scope and spirit of the described embodiments, many modifications and changes are obvious to a person of ordinary skill in the art. Selection of term s used in this specification is intended to best explain the principles, practical applications, or technical improvements in the market of the embodiments, or to enable a person of ordinary skill in the art to understand the embodiments disclosed in this specification.

1. A method for fabricating a semiconductor device (100), comprising:
providing a semiconductor body (11), wherein the semiconductor body (11) comprises a substrate (1), a buried layer (2) disposed on the substrate (1), and an epitaxial layer (3) disposed on the buried layer (2), the substrate (1) has a first doping type, and the buried layer (2) has a second doping type opposite to the first doping type;
forming a hard mask layer (4) on a top surface of the epitaxial layer (3);
etching the hard mask layer (4) and the semiconductor body (11) by using a single soft mask layer (10) to simultaneously form a first trench (51), a second trench (52), and a third trench (53) in the semiconductor body (11), wherein the first trench (51) extends from the top surface of the epitaxial layer (3) into the substrate (1) and has a first depth (D1), the second trench (52) extends from the top surface of the epitaxial layer (3) into the substrate (1) and has a second depth (D2), and the third trench (53) extends from the top surface of the epitaxial layer (3) into the buried layer (2) or to a position in the epitaxial layer (3) and near the buried layer (2) and has a third depth (D3) less than the second depth (D2);
forming, in the epitaxial layer (3), a first doped region (82) having the second doping type near a sidewall of the third trench (53), wherein the first doped region (82) extends from the top surface of the epitaxial layer (3) to the buried layer (2), and is configured to electrically connect the buried layer (2) to the top surface of the epitaxial layer (3);
forming a first deep trench structure (511) in the first trench (51), wherein the first deep trench structure (511) is configured to electrically connect the substrate (1) to the top surface of the epitaxial layer (3);
forming a second deep trench isolation structure (521) in the second trench (52), wherein the second deep trench isolation structure (521) is configured to isolate different component regions in the epitaxial layer (3); and
forming a third deep trench isolation structure (531) in the third trench (53), wherein the third deep trench isolation structure (531) is configured to isolate different component regions in the epitaxial layer (3).

2-3. (canceled)

4. The method according to claim 1, wherein etching the hard mask layer (4) and the semiconductor body (11) by using the single soft mask layer (10) comprises:
performing first etching on the hard mask layer (4) and the epitaxial layer (3) by using the single soft mask layer (10) to simultaneously form, in the hard mask layer (4), a first trench opening (510), a second trench opening (520), and a third trench opening (530) that penetrate through the hard mask layer (4), and to form, in the epitaxial layer (3), a first shallow trench (555) aligned with each of the first trench opening (510), the second trench opening (520), and the third trench opening (530);
forming a sidewall spacer (556) on a sidewall of each of the first trench opening (510), the second trench opening (520), the third trench opening (530), and the first shallow trench (555); and
performing second etching on the semiconductor body (11) via the first shallow trench (555) to form, in the semiconductor body (11), the first trench (51) aligned with the first trench opening (510), the second trench (52) aligned with the second trench opening (520), and the third trench (53) aligned with the third trench opening (530).

5-7. (canceled)

8. The method according to claim 1, wherein forming the first deep trench structure (511) in the first trench (51) comprises:
forming a pad (7) on a sidewall and a bottom of the first trench (51);
forming a dielectric layer (8) inside the pad (7) in the first trench (51), wherein the dielectric layer (8) comprises a second opening (54) extending from the top surface of the epitaxial layer (3) toward the bottom of the first trench (51);
performing anisotropic etching on the dielectric layer (8) and the pad (7) in the first trench (51), so that the second opening (54) extends to the pad (7) at the bottom of the first trench (51), and a first opening (71) aligned with the second opening (54) is formed in the pad (7) at the bottom of the first trench (51); and
filling the first opening (71) and the second opening (54) with a first conductive material (61), wherein the first conductive material (61) is configured to electrically connect the substrate (1) to the top surface of the epitaxial layer (3).

9-10. (canceled)

11. The method according to claim 1, wherein forming the second deep trench isolation structure (521) in the second trench (52) comprises:
forming a pad (7) on a sidewall and a bottom of the second trench (52); and
forming a dielectric layer (8) inside the pad (7) in the second trench (52), wherein the dielectric layer (8) completely or partially fills the second trench (52).

12. The method according to claim 1, wherein forming the third deep trench isolation structure (531) in the third trench (53) comprises:
forming a pad (7) on a sidewall and a bottom of the third trench (53); and
forming a dielectric layer (8) inside the pad (7) in the third trench (53), wherein the dielectric layer (8) completely fills the third trench (53).

13. (canceled)

14. The method according to claim 1,
wherein forming, in the epitaxial layer (3), the first doped region (82) having the second doping type near the sidewall of the third trench (53) comprises:
depositing a diffusion material (81) in the third trench (53), wherein the diffusion material (81) comprises a dopant of the second doping type, and wherein the diffusion material (81) partially fills the third trench (53); and
performing thermal annealing on the diffusion material (81), so that the dopant is diffused into a region of the epitaxial layer (3) near the sidewall of the third trench (53) to form the first doped region (82);
and wherein forming the third deep trench isolation structure (531) in the third trench (53) comprises:
continuing to fill the third trench (53) with a dielectric material to seal the diffusion material (81), wherein the diffusion material (81) and the dielectric material jointly form the third deep trench isolation structure (531).

15-17. (canceled)

18. The method according to claim 1, wherein forming, in the epitaxial layer (3), the first doped region (82) having the second doping type near the sidewall of the third trench (53) comprises:
depositing a diffusion material (81) in the third trench (53), wherein the diffusion material (81) comprises a dopant of the second doping type, and wherein an air gap (810) is formed inside the diffusion material (81) or the diffusion material (81) completely fills the third trench (53); and
performing thermal annealing on the diffusion material (81), so that the dopant is diffused into a region of the epitaxial layer (3) near the sidewall of the third trench (53) to form the first doped region (82).

19. (canceled)

20. The method according to claim 1, wherein the second depth (D2) is less than the first depth (D1), and wherein forming, in the epitaxial layer (3), the first doped region (82) having the second doping type near the sidewall of the third trench (53) comprises:
depositing a diffusion material (81) in the first trench (51), the second trench (52) and the third trench (53), wherein the diffusion material (81) comprises a dopant of the second doping type;
removing the diffusion material (81) in the first trench (51) and the second trench (52); and
performing thermal annealing on the diffusion material (81) in the third trench (53), so that the dopant is diffused into a region of the epitaxial layer (3) near the sidewall of the third trench (53) to form the first doped region (82);
and the formation of the first deep trench structure (511), the second deep trench isolation structure (521), and the third deep trench isolation structure (531) comprises:
forming a pad (7) on a sidewall and a bottom of each of the first trench (51), the second trench (52), and the third trench (53); and
forming a dielectric layer (8) inside the pad (7) in the first trench (51), the second trench (52), and the third trench (53), so that the dielectric layer (8) forms, in the first trench (51), a second opening (54) that extends from the top surface of the epitaxial layer (3) toward the bottom of the first trench (51), and the dielectric layer (8) completely fills the second trench (52) and the third trench (53), wherein the pad (7) and the dielectric layer (8) in the second trench (52) form the second deep trench isolation structure (521), and the pad (7) and the dielectric layer (8) in the third trench (53) form the third deep trench isolation structure (531).

21. The method according to claim 20, wherein the formation of the first deep trench structure (511) further comprises:
performing anisotropic etching on the dielectric layer (8) and the pad (7), so that the second opening (54) extends to the pad (7) at the bottom of the first trench (51), and a first opening (71) aligned with the second opening (54) is formed in the pad (7) at the bottom of the first trench (51);
performing ion implantation on the substrate (1) through the second opening (54) and the first opening (71) to form a second doped region (9) in the substrate (1) near the bottom of the first trench (51), wherein the second doped region (9) has the first doping type and has a doping concentration higher than that of the substrate (1); and
filling the first opening (71) and the second opening (54) with a first conductive material (61) to form the first deep trench structure (511).

22-44. (canceled)

45. A method for fabricating a semiconductor device (100), comprising:
providing a semiconductor body (11), wherein the semiconductor body (11) comprises a substrate (1), a buried layer (2) disposed on the substrate (1), and an epitaxial layer (3) disposed on the buried layer (2), the substrate (1) has a first doping type, and the buried layer (2) has a second doping type opposite to the first doping type;
forming a hard mask layer (4) on a top surface of the epitaxial layer (3);
etching the hard mask layer (4) and the semiconductor body (11) by using a seventh soft mask layer to simultaneously form a first trench (51), a second trench (52), and a third trench (53) in the semiconductor body (11), wherein the first trench (51) extends from the top surface of the epitaxial layer (3) into the substrate (1) and has a first depth (D1), the second trench (52) extends from the top surface of the epitaxial layer (3) into the substrate (1) and has a second depth (D2), and the third trench (53) extends from the top surface of the epitaxial layer (3) into the buried layer (2) or to a position in the epitaxial layer (3) and near the buried layer (2) and has a third depth (D3) less than the second depth (D2);
forming a first deep trench structure (511) in the first trench (51), wherein the first deep trench structure (511) is configured to electrically connect the substrate (1) to the top surface of the epitaxial layer (3);
forming a second deep trench isolation structure (521) in the second trench (52), wherein the second deep trench isolation structure (521) is configured to isolate different component regions in the epitaxial layer (3);
forming a temporary deep trench structure (534) in the third trench (53);
etching the temporary deep trench structure (534) in the third trench (53) by using an eighth soft mask layer (103) to remove the temporary deep trench structure (534) in the third trench (53);
obliquely implanting, in the third trench (53), a dopant of the second doping type into the semiconductor body (11) to form, in the epitaxial layer (3), a first doped region (82) having the second doping type near a sidewall of the third trench (53), wherein the first doped region (82) extends from the top surface of the epitaxial layer (3) to the buried layer (2), and is configured to electrically connect the buried layer (2) to the top surface of the epitaxial layer (3); and
filling the third trench (53) with a dielectric material (83) to form a third deep trench isolation structure (531).

46-72. (canceled)

73. The method according to claim 14, wherein the dielectric material is filled after the diffusion material (81) is deposited in the third trench (53), and thermal annealing is performed on the diffusion material (81) after the dielectric material is filled.

74. The method according to claim 1,
wherein etching the hard mask layer (4) and the semiconductor body (11) by using the single soft mask layer (10) comprises:
performing first etching on the hard mask layer (4) and the epitaxial layer (3) by using the single soft mask layer (10) to simultaneously form, in the hard mask layer (4), a first trench opening (510), a second trench opening (520), and a third trench opening (530) that penetrate through the hard mask layer (4), and to form, in the epitaxial layer (3), a first shallow trench (555) aligned with each of the first trench opening (510), the second trench opening (520), and the third trench opening (530);
forming a sidewall spacer (556) on a sidewall of each of the first trench opening (510), the second trench opening (520), the third trench opening (530), and the first shallow trench (555); and
performing second etching on the semiconductor body (11) via the first shallow trench (555) to form, in the semiconductor body (11), the first trench (51) aligned with the first trench opening (510), the second trench (52) aligned with the second trench opening (520), and the third trench (53) aligned with the third trench opening (530);
wherein forming, in the epitaxial layer (3), the first doped region (82) having the second doping type near the sidewall of the third trench (53) comprises:
depositing a diffusion material (81) in the third trench (53), wherein the diffusion material (81) comprises a dopant of the second doping type; and
performing thermal annealing on the diffusion material (81), so that the dopant is diffused into a region of the epitaxial layer (3) near the sidewall of the third trench (53) to form the first doped region (82); and
wherein the method for fabricating the semiconductor device (100) further comprises:
etching the diffusion material (81) in the third trench (53) to remove the diffusion material (81); and
removing the sidewall spacer (556) through isotropic etching after removing the diffusion material (81).

75. The method according to claim 74, wherein the sidewall spacer (556) comprises nitride, and the hard mask layer (4) comprises a first oxide layer (41) on the top surface of the epitaxial layer (3) and a nitride layer (42) on the first oxide layer (41).

76. A method for fabricating a semiconductor device (100), comprising steps a to j:
a. providing a semiconductor body (11), wherein the semiconductor body (11) comprises a substrate (1), a buried layer (2) disposed on the substrate (1), and an epitaxial layer (3) disposed on the buried layer (2), the substrate (1) has a first doping type, and the buried layer (2) has a second doping type opposite to the first doping type;
b. forming a hard mask layer (4) on a top surface of the epitaxial layer (3);
c, etching the hard mask layer (4) and the semiconductor body (11) by using a single soft mask layer (10) to simultaneously form a first trench (51), a second trench (52), and a third trench (53) in the semiconductor body (11), wherein the first trench (51) extends from the top surface of the epitaxial layer (3) into the substrate (1) and has a first depth (D1), the second trench (52) extends from the top surface of the epitaxial layer (3) into the substrate (1) and has a second depth (D2), and the third trench (53) extends from the top surface of the epitaxial layer (3) into the buried layer (2) or to a position in the epitaxial layer (3) and near the buried layer (2) and has a third depth (D3) less than the second depth (D2);
d. depositing a diffusion material (81) in the first trench (51), the second trench (52) and the third trench (53), wherein the diffusion material (81) comprises a dopant of the second doping type;
e. removing the diffusion material (81) in the first trench (51) and the second trench (52);
f. performing thermal annealing on the diffusion material (81) in the third trench (53), so that the dopant is diffused into a region of the epitaxial layer (3) near the sidewall of the third trench (53) to form the first doped region (82);
g. forming a pad (7) on a sidewall and a bottom of the first trench (51) and the second trench (52);
h. forming a dielectric layer (8) inside the pad (7) in the first trench (51) and the second trench (52), so that the dielectric layer (8) comprises a second opening (54) extending from the top surface of the epitaxial layer (3) toward the bottom of the first trench (51), and the dielectric layer (8) completely fills the second trench (52);
i. performing anisotropic etching on the dielectric layer (8) and the pad (7), so that the second opening (54) extends to the pad (7) at the bottom of the first trench (51), and a first opening (71) aligned with the second opening (54) is formed in the pad (7) at the bottom of the first trench (51); and
j. filling the first opening (71) and the second opening (54) with a first conductive material (61) to form the first deep trench structure (511).

77. The method according to claim 76, further comprising a step k between step f and step g: removing the diffusion material (81) in the third trench (53);
the method further comprising:
in step g, forming the pad (7) on a sidewall and a bottom of the third trench (53) while forming the pad (7) on the sidewall and the bottom of the third trench (53) of the first trench (51) and the second trench (52); and in step h, forming the dielectric layer (8) inside the pad (7) in the third trench (53) while forming the dielectric layer (8) inside the pad (7) in the first trench (51) and the second trench (52), wherein the dielectric layer (8) completely fills the third trench (53).

78. The method according to claim 76, wherein the method is performed in an order of steps a to j.

79. The method according to claim 45, wherein the second depth (D2) is less than the first depth (D1), and the formation of the first deep trench structure (511), the second deep trench isolation structure (521), and the temporary deep trench structure (534) comprises:
forming a pad (7) on a sidewall and a bottom of each of the first trench (51), the second trench (52), and the third trench (53); and
forming a dielectric layer (8) inside the pad (7) in the first trench (51), the second trench (52), and the third trench (53), so that the dielectric layer (8) forms, in the first trench (51), a second opening (54) that extends from the top surface of the epitaxial layer (3) toward the bottom of the first trench (51), and the dielectric layer (8) completely fills the second trench (52) and the third trench (53), wherein the pad (7) and the dielectric layer (8) in the second trench (52) form the second deep trench isolation structure (521), and the pad (7) and the dielectric layer (8) in the third trench (53) form the temporary deep trench structure (534).

80. The method according to claim 79, wherein the formation of the first deep trench structure (511) further comprises:
performing anisotropic etching on the dielectric layer (8) and the pad (7), so that the second opening (54) extends to the pad (7) at the bottom of the first trench (51), and a first opening (71) aligned with the second opening (54) is formed in the pad (7) at the bottom of the first trench (51);
performing ion implantation on the substrate (1) through the second opening (54) and the first opening (71) to form a second doped region (9) in the substrate (1) near the bottom of the first trench (51), wherein the second doped region (9) has the first doping type and has a doping concentration higher than that of the substrate (1); and
filling the first opening (71) and the second opening (54) with a first conductive material (61) to form the first deep trench structure (511).

81. The method according to claim 45, wherein etching the temporary deep trench structure (534) in the third trench (53) by using the eighth soft mask layer (103) comprises:
etching the temporary deep trench structure (534) in the third trench (53) by using the eighth soft mask layer (103) to remove a portion of the temporary deep trench structure (534) in the third trench (53), thereby forming a second shallow trench (532);
forming a sidewall spacer (556) on a sidewall of each of a third trench opening (530) in the hard mask layer (4) and the second shallow trench (532); and
removing the remaining portion of the temporary deep trench structure (534) in the third trench (53); and
removing the sidewall spacer (556) through isotropic etching after removing the remaining portion of the temporary deep trench structure (534).

82. The method according to claim 81, wherein the sidewall spacer (556) comprises nitride, and the hard mask layer (4) comprises a first oxide layer (41) on the top surface of the epitaxial layer (3) and a nitride layer (42) on the first oxide layer (41).
